(19) United States
(12) Patent Application Publication
(10) Pub. No.: US 2026/0196867 A1
(43) Pub. Date: Jul. 9, 2026

(54) Dynamic Power Management of Sensors and Devices Using Predicted Behaviors, Contexts, Triggers, Associated Risks, Machine Learning, and/or Artificial Intelligence (AI)

(71) Applicant: Conquer Your Addiction LLC, Kirkwood, MO (US)

(72) Inventor: David H. WILLIAMS, Kirkwood, MO (US)

(21) Appl. No.: 19/381,793

(22) Filed: Nov. 6, 2025

Related U.S. Application Data
(60) Provisional application No. 63/742,311, filed on Jan. 6, 2025.

(51) Int. Cl. H02J 13/00; G01R 21/133

(52) U.S. Cl. CPC H02J 13/12; G01R 21/1333; H02J 2103/30

(57) ABSTRACT

The present disclosure generally relates to dynamic power management of sensors and devices using predicted behaviors, contexts, triggers, associated risks, machine learning, and/or artificial intelligence (AI). For example, exemplary embodiments are disclosed of systems and methods for using (a) context(s), (b) context(s) and location(s), (c) trigger(s), and/or (d) behavior(s) and associated risk(s) for dynamic sensors etc. power management. In exemplary embodiments, a system/method may include or be configured to be operable for using predictive analytics, artificial intelligence (AI), and/or machine learning (ML) for future dynamic power management based on (a) context(s), (b) context(s) and location(s), (c) trigger(s), and/or (d) behavior(s) and associated risk(s). In exemplary embodiments, the system/method optimizes power consumption for data collection and usage from sensors, devices, networks, and systems to predict current/future behaviors and contexts, formulate/implement actions to improve behaviors (potentially using said sensors/devices), while dynamically managing power based on predicted risks, recharge likelihood, and data utility.

### CROSS-REFERENCE TO RELATED APPLICATIONS

This application claims priority to and the benefit of U.S. Provisional Application No. 63/742,311 filed Jan. 6, 2025. This application is also related to the following:
U.S. patent application Ser. No. 18/885,300 filed Sep. 13, 2024
U.S. patent application Ser. No. 18/885,307 filed Sep. 13, 2024
U.S. patent application Ser. No. 17/541,707 filed Dec. 3, 2021 (published as US2022/0116736 on Apr. 14, 2022 and issued as U.S. Pat. No. 12,096,308 on Sep. 17, 2024)
U.S. Provisional Patent Application No. 63/120,834 filed Dec. 3, 2020
U.S. patent application Ser. No. 18/211,999 filed Jun. 20, 2023 (published as US2023/0353983 on Nov. 2, 2023)
U.S. Provisional Patent Application No. 63/460,523 filed Apr. 19, 2023
U.S. Provisional Patent Application No. 63/441,569 filed Jan. 27, 2023
U.S. Provisional Patent Application Ser. No. 63/344,976 filed May 23, 2022
U.S. patent application Ser. No. 17/903,419 filed Sep. 16, 2022 (published as US2023/0007439 on Jan. 5, 2023)
U.S. Provisional Patent Application Ser. No. 63/316,277 filed Mar. 3, 2022
U.S. Provisional Patent Application Ser. No. 63/294,815 filed Dec. 29, 2021
U.S. Provisional Patent Application Ser. No. 63/275,300 filed Nov. 3, 2021
U.S. patent application Ser. No. 18/372,544 filed Sep. 25, 2023 (published as US2024/0040336 on Feb. 1, 2024)
U.S. patent application Ser. No. 17/882,061 filed Aug. 5, 2022 (published as US2022/0386080 on Dec. 1, 2022)
U.S. patent application Ser. No. 17/861,559 filed Jul. 11, 2022 (published as US2022/0353632 on Nov. 3, 2022)
U.S. patent application Ser. No. 18/090,047 filed Dec. 28, 2022 (published as US2023/0179955 on Jun. 8, 2023)
U.S. patent application Ser. No. 16/700,601 filed Dec. 2, 2019 (published as US2020/0107155 on Apr. 2, 2020, issued as U.S. Pat. No. 11,388,546 on Jul. 12, 2022)
U.S. patent application Ser. No. 17/104,136 filed Nov. 25, 2020 (published as US2021/0084451 on Mar. 18, 2021, issued as U.S. Pat. No. 11,412,353 on Aug. 9, 2022)
U.S. patent application Ser. No. 17/192,381 filed Mar. 4, 2021 (published as US2021/0202067 on Jul. 1, 2021 and issued as U.S. Pat. No. 11,636,941 on Apr. 25, 2023)
U.S. patent application Ser. No. 15/840,775 filed Dec. 13, 2017 (published as US2018/0173866 on Jun. 21, 2018 and issued as U.S. Pat. No. 10,555,112 on Feb. 4, 2020)
U.S. Provisional Patent Application No. 62/435,042 filed Dec. 15, 2016
U.S. Provisional Patent Application No. 62/480,206 filed Mar. 31, 2017
U.S. patent application Ser. No. 16/654,708 filed Oct. 16, 2019 (published as US2020/0051189 on Feb. 13, 2020 and issued as U.S. Pat. No. 10,853,897 on Dec. 1, 2020)
U.S. Provisional Patent Application No. 62/986,382 filed Mar. 6, 2020
U.S. Provisional Patent Application No. 63/011,949 filed Apr. 17, 2020
U.S. Provisional Patent Application No. 62/746,330 filed Oct. 16, 2018
U.S. patent application Ser. No. 16/516,822 filed Jul. 19, 2019 (published as US2019/0340906 on Nov. 7, 2019 and issues as U.S. Pat. No. 10,497,242 on Dec. 3, 2019)
U.S. patent application Ser. No. 15/840,762 filed Dec. 13, 2017 (published as US2018/0176727 on Jun. 21, 2018 and issued as U.S. Pat. No. 10,477,342 on Nov. 12, 2019)
U.S. Provisional Patent Application No. 62/701,252 filed Jul. 20, 2018
   The entire disclosures of the above patents and patent applications are incorporated herein by reference.

### FIELD

The present disclosure generally relates to dynamic power management of sensors and devices using predicted behaviors, contexts, triggers, associated risks, machine learning, and/or artificial intelligence (AI).

### BACKGROUND

This section provides background information related to the present disclosure which is not necessarily prior art.

Various attempts have been made to address power usage issues. But balancing usefulness of data with power consumed to obtain the data has only had varying degrees of success. Conventional techniques include low-power protocols (e.g., BLE, Zigbee), sleep modes, event-triggered activation, duty cycling, power gating, DVFS, adaptive battery management, and adaptive power scaling (APS). However, these focus on historical device/app usage or static contexts, not dynamic entity-specific behaviors, triggers, and contexts for predictive power management in behavior modification use cases.

### DRAWINGS

The drawings described herein are for illustrative purposes only of selected embodiments and not all possible implementations and are not intended to limit the scope of the present disclosure.

FIG. 1 illustrates an example system according to an exemplary embodiment including sensors, sensor arrays, devices, systems, communication networks, etc. that are in communication with (e.g., a mesh network, etc.) multiple engines and multiple location determination technologies or sources 101. The multiple engines may include, but are not limited to, a Data Source(s) Detection/Management Engine, a Speech (verbal and written), Facial Analysis Engine, a Behavior(s) and/or Trigger(s) and/or Context(s) Detection/Determination Engine, a Trigger Analysis Engine, a Substance (Ab) Use Inference Engine, a Motivation (Dis) Incentive Analysis Engine, a Support Resource Management Engine, a Contextual Analysis Engine, a Trigger and/or Behavior Risk Determination Engine, an Action/Support Resources/User Interface (UI) Engine, and one or more Learning Engines.

FIG. 2 illustrates an example system according to an exemplary embodiment in process for achieving power savings. For all of the categories shown in FIG. 2, there are at least some exemplary embodiments that would include, at least in part, reduction of power needed and/or used by their components/component parts due to decreased (or no) usage of memory, storage, processor(s) and/or controllers, communications (with other components or even internal to a component), peripherals and accessories.

FIG. 3 includes a table with examples of power reduction for various sensors etc. for an Anger trigger.

FIG. 4 includes a table showing some examples of contexts-within-contexts, and how “actual” contexts can be perceived differently by different people, particularly when viewed through a trigger and/or behavioral perspective.

FIG. 5 includes a table showing example options for managing sensors etc. for behavior and context tracking for various Anger risk levels.

### DETAILED DESCRIPTION

Example embodiments will now be described more fully with reference to the accompanying drawings.

As recognized herein, the ability (or lack thereof) to manage power capacity and usage of sensors, sensor arrays, devices, systems and networks (including related/associated components) particularly those that are mobile in nature and even more those that utilize batteries and/or high cost power sources, has been one of the thorniest problems in the mobile use case world. In short, the ideal situation is to (1) use power to enable data collection, processing, and usage when such data is really useful, (2) minimize power usage for data collection, processing, and usage when it is not useful, and (3) in-between balancing such power usage and data collection appropriately when it is partially or somewhat useful.

Various attempts have been made to address power usage issues. But balancing usefulness of data with power consumed to obtain the data has only had varying degrees of success. Some of the conventional techniques to address power usage issues include:
Low-Power Wireless Communication Protocols-Optimizing communication protocols (like Bluetooth Low Energy (BLE), Zigbee, Low Rank Adaptation (LoRa), and Narrowband Internet of Things (NB-IoT)) to minimize power usage during data transmission.
Sleep and other Low-Power Modes, such as Bluetooth Low Energy (BLE)—e.g., sensors, devices, etc. entering a low-power, idle state, or greatly reduced frequency use when not actively in use, thus conserving energy by turning off or reducing power to various components.
Event-Triggered Power Management-Using sensors or certain conditions to activate the device only when certain events or thresholds are detected. Examples include motion detection, temperature change, occupancy detection, geofencing, etc. Also includes entering/exiting/approaching geofences, e.g., within 5 miles of home therefore ramp up the A/C to cool the house down before arrival.
Less Accurate Modes—e.g., for some sensor measurement types, such as for some location determination, there is a correlation between greater power consumption and increased accuracy, e.g., various Android location accuracy based methods that have different power usage.
Timing-Based Methods, such as Duty Cycling—Alternating between active and inactive (sleep) states at set intervals or based on certain conditions). Enablers include scheduling based systems or other time-based cycling.
Power Gating—Selectively powering off certain components or circuits within a device when they are not needed.
Battery Management Systems (BMS), Adaptive Battery—BMS are systems that monitor battery health, voltage, and charge/discharge cycles to optimize performance and longevity. Adaptive battery techniques are a version of this, using app usage patterns to prioritize frequently used apps, allowing the frequency used prioritized apps to run in the background while limiting the use/power use of infrequently used apps.
Dynamic Voltage and Frequency Scaling (DVFS)—Adjusting the voltage and frequency of a device's processor based on current workload demands.
Adaptive Power Scaling (APS)—Dynamically adjusting power allocation based on real-time needs and usage patterns. APS also uses DVFS, Adaptive Battery, and Sleep modes as part of its APS techniques/processes.

As further recognized herein, there are also various types of sensors, etc. that can be designed from scratch with Low-Power Components and Circuit Design, e.g., using energy-efficient components and designing circuits that consume minimal power.

Conventional adaptive power scaling (“APS”) involves dynamically adjusting power allocation based on real-time needs and usage patterns. Generally, adaptive power scaling enables devices to scale down power when activity is low or scale up when high performance is needed. Adaptive power scaling is used in smartphones and wearables that use predictive algorithms to conserve power based on user activity patterns. Power usage can also be scaled on an app-by-app basis or within an app such as by using less accurate (and less power using) location determination methods to conserve power.

But the “predictive algorithms” used with adaptive power scaling are conventionally based on historical usage of devices and/or apps often of a particular person, perhaps coupled with location, not the context(s) or context and location, behavior(s), and trigger(s) of the person. Further, such existing algorithms are used with adaptive power scaling to manage the current/real-time power usage of the device/apps. The existing algorithms of adaptive power scaling are not used to proactively plan the usage and associate power usage of sensor(s), etc. potentially needed in the future given an entity(ies) (e.g., person(s), etc.) likely/potential trigger(s), behavior(s), and associated context(s) in the future. The present invention addresses this gap by tying power management to predicted behaviors, contexts, triggers, and risks for behavior-related modification actions, optimizing for data utility in predicting/improving behaviors while considering recharge likelihood and battery constraints.

Generally, existing methods/techniques/technologies may work adequately for many use cases when the associated use cases are relatively static (e.g., do not change frequently over time) are well defined and have an established historical record of associated power usage. Further, these existing power management techniques are used when the context is either inconsequential, is well known, or the context or what the context is used for does not vary or vary much from entity to entity, or the context does not change frequently, or changes in expected manners, e.g., highly dynamic contexts. At best, some algorithms take location into account for some of their power management needs, such as use of a geofence to turn on/off/up/down various devices, etc. Otherwise, most power savings concepts are tied to usage intensity, e.g., go to sleep modes after a certain period of time of no activity, wake up when some sort of related activity occurs, and so forth.

But both context (e.g., who, what, when, why, how) and location are not used or only used so rarely and not in highly dynamic contexts. To the extent some form of context (or context and location) is used for power management, the existing techniques do not also tie the predictive algorithms to a person's historical, current, and potential future behavior(s) and/or associated context(s), nor do the existing techniques tie the context(s) and behavior(s) to particular trigger(s) of “bad” or otherwise undesirable behavior(s), as disclosed in exemplary embodiments of this invention. This means that the above existing techniques do not work well in a variety of types of use cases, particularly when contexts: a) are dynamic (e.g., are unpredictable or can change frequently), b) have not occurred historically for an entity or have not occurred very often, or occurred only for other use case types, and c) can be important/useful sometimes and not important/useful other times depending on various factors (e.g., an entity's triggers, behaviors). Power management for use cases involving triggers and behaviors, and their associated contexts, for various entities, including humans, are particularly problematic because of their extremely dynamic nature. An entity such as a human can have multiple triggers in general that can have very serious ramifications if the trigger is activated and/or a certain threshold or level and/or set of conditions reached, such as reaching a certain Anger or Anxiety level that in turn causes domestic violence and/or an addictive substance or activity relapse. Changing in potential impact and risk from moment to moment, such triggers can have related triggers that can increase and/or influence the risk of primary triggers being activated etc. and the behaviors that can cause and/or be caused by any/some/all of the triggers, such as becoming Angry can cause substance use or violence, or small disagreements can escalate to full-blown anger.

Patents and patent applications listed above in the Cross-Reference to Related Application section (and incorporated by reference herein) draw heavily on various sensors, sensor arrays, devices, systems, and/or networks, and their related components, to provide data needed to assess the risk of a potential trigger event, formulate a variety of possible actions to reduce risk by modifying behaviors and associated contexts/locations, implement the most likely successful action, monitor the results, and incorporate the results into ongoing data sets related to the entity(ies), trigger(s), behavior(s), and contexts/locations involved and used for learning purposes in future action formulation activities and improvement in their effectiveness for a given trigger, behavior(s), and/or context(s).

The following is description of deficiencies with existing art. While there is some existing art that address various aspects of using predictive algorithms for power management as well as context-related battery management, this existing art does not address the needs described herein. To the extent the existing art deals with with context, it mostly with respect to a general, generic, static context applicable to multiple users, not a specific context of a particular user (and especially not a specific context to a specific user associated with a particular trigger(s) and/or behavior(s)), nor dynamic context(s) that may change frequently, even very rapidly.

For example, using the weather (e.g., it is hot) at a baseball game at an outdoor ballpark starting in the early afternoon in August, humid with a chance of rain, can be applicable to not just one attendee but to all attendees of the game as well as other people outside the park and even in the city where the ballpark is located. But what is considered “hot” may depend on whether a person is actually in the sun or in a shaded part of the seating area. What is considered “hot” may also depend on whether it is sunny at all, or if the person is actually seated at that time, vs having gone to the refreshment area that is shaded. Further, different people have different experiences, tolerances, and preferences with resoect to heat, humidity, etc., and one person's “hot/humid/uncomfortable” may be another person's “cozy/comfy.” For example, someone who is thin and from Houston (“cozy/comfy country”) may have a very different contextual perspective than an overweight person from Minnesota (“hot/humid/uncomfortable”) for exactly the same weather, seating, and other “real” (versus perceived) contextual conditions. Indeed, embodiments of this invention can draw on a person's (or even type of person as defined by a wide variety of “types) historical, environmental, and physiological contextual factors in determining such different “perceived” contexts vs. actual physical contexts. Such perceived contexts can be supplemental and/or associated with the physical context(s), and/or can be “subsets” or “contexts within contexts,” discussed more shortly.

Further, how people react behavioraly to those contexts can be different for the same actual (or “real” as defined by objective measures, such as the temperature) context vs. Perceived context. Some (indeed many) people get more irritable when they are in (a perceived) hot/humid/uncomfortable context (e.g., our Minnesota example), whereas others find it delightful (the Houston person). Thus the Minnesotian may start to exhibit associated behaviors like fidgeting, snapping at people, removing clothing, and drinking (a lot of) beer, whereas the Houstonian may not show any change in behavior, perceiving it to be perfectly pleasant. Thus, even if two people have the same exact triggers, such as Anger, the perceived behaviors and associated contexts (or vice versa, e.g., contexts and associated behaviors), their impact (or not) on the risk a person's Anger trigger being activated or thresholds being neared, can be very, very different. Another contrasting example is in the result of the being at the ball game. The Houstonian may get extremely upset at a blown call, perhaps rooted in their view of “fairness” or “justice,” whereas the Minnesotian, even despite being uncomfortable, views it as “just a game” and exhibits no change at all in their behavior-especially if their perception of their context is very different.

While such conventional context-related power management capabilities are adequate for an individual static or relatively static contexts, they do little in use cases where the determination of the applicable specifics and use of the context depends on the trigger(s) and/or behavior(s) involved. Further, such conventional context-related power management capabilities are not useful where the specifics of the context is defined may vary greatly-being very different depending on the trigger(s) and/or behavior(s) involved even if the underlying contextual elements themselves are static or relatively static.

Context can change very quickly. Indeed, for different people, different contexts can be derived/perceived by different people each experiencing or exposed to the same contextual elements. Depending on the person and the trigger(s) potentially at risk, there can be multiple real and percieved contexts occurring at the same time for the same person.

An example includes a group of people going to a baseball game starting late afternoon. The people attending as a group are Joe, Joe's spouse Jane, Jane's parents Mike and Mary, and Joe and Jane's teenage daughter Jenny. The time range of various contexts may be defined in this example as one hour before Joe (and Jane and Jenny) leave their house to pick up Mike and Mary in Joe/Jane's (small) car. Initially, there are some common contextual elements—referred to as “real” or “actual” contexts or contextual elements. All the parties are going to the same game, at the same time, in essentially the same seats (seats very close to each other, equally exposed to the weather, the sun, the crowd, and people also seated with them in their company box). For most of the trip going to and from the game, all of the party will be in the same car, experiencing the same internal (car) conditions (car comfort, temperature, music, etc.), in the same traffic. They will be parking at the same spot and going to/into the ballpark together. The game will involve the same teams, and the game experience (in or out of the sun, temperature, humidity, experience of the game play, etc.) will in general be the same for everyone in Joe's party.

But there will be numerous differences in perceived context by each individual person in the party over the course of our time range. Let's start simple with the weather. While the real or actual ambient temperature and humidity will be the same for each person in the party, how that temperature and humidity is perceived or even actually experienced can be very different. Joe spent much of the early afternoon cutting his grass, and was all sweaty and hot before getting into his car. Joe cooled off somewhat, but not completely (e.g., to his skin and body temperature was before he went outside his house to cut the grass), so he may be (depending on his physiology) more sensitive to heat/humidity, or—alternatively—perhaps he is already acclimated to today's climate conditions. Jane, however, hates heat and humidity so anything above 75 degrees and 40% humidity is increasing uncomfortable for her. Jenny hates being outdoors-seemingly at any climate context and for any reason-so she has her own “environmental context” issues. Mary and Mike, being retired farmers, could care less about the weather/environmental conditions, and make it a point to make fun of people highly sensitive to non-perfected conditions. Thus, the instant the party gets out of the care at the parking lot, each of the persons in the party has different perceived “environmental contexts,” despite having many “real” or “actual” (or “commonly perceived”) contexts/contextual elements common across the party up to that point.

But there are many more potential contexts that can be perceived/experienced by the individual persons in the parties, some more important than others depending on the person. To start with, it is going to be progressively hotter and more humid as the game starts and continues, with a warm front moving in—each person will experience/perceive this differently. There is even an increasing chance of rain as the front approaches. This possibility doesn't affect Mary and Mike in any way—in fact they are mildly excited at the prospect; Jane is worried about her clothes and hair, and Jenny that she might not be able to use her phone if rain occurs (or she will go to the sheltered refreshment area). Joe though is worried that the game might be cancelled, and even if that doesn't happen he is worrying about the impact of rain on the return traffic. In other words, the same climate condtions—a subset/type of environmental conditions—while the “same” for each of the parties, is perceived very differently.

Further, there are going to be tens of thousands of people at the game. Joe, sometimes mildly claustraphobic, thinks this will be (or at least “feel”) very crowded, Jane feels similar though somewhat less so, Jenny only cares about other people her age (e.g., could care less about how many people are at the game), and while Mike and Mary also think it will be crowded, they view it as an exciting positive (unlike Joe who can get claustrophobic in certain conditions, including crowds).

But even getting to the ball park results in different perceived/experienced contexts. A general description of the context might be “car ride to ballpark” but in reality the context not only depends on the perspective of the individual experiencing “the ride” and in particular different aspects of “the ride” context. For example, more focused, alternative actual and perceived context descriptions, particularly as they relate to different triggers (and detection of key “upstream” behaviors) could be much more useful in the preempting a rising risk related to or the “activation” of a trigger. For example, if Anger is a big problem/trigger for Joe (for various possible reasons, such as leading to substance (ab) use, domestic violence, or just a key aspect of his personality that he has problems with and wants to control, particularly in social settings where in the past he has embarrassed himself with Anger outbursts), and has key related triggers such as Frustration, being able to break down in more detailed fashion various parts and/or focused perspectives making up the context “car ride to ball game” can be important, potentially even critically so.

Understanding which context(s) related to “car ride to ball game” can be dependent on personal characteristics and their particular behaviors, especially as they relate to triggers of concern. For example, key behaviors for Joe that can occur that are upstream of the Anger trigger (that Joe worries about because it may result in him embarrassing himself and/or drinking too much in general, and in a “driving in a car” context possibly result in a traffic ticket for speeding or reckless driving, which has happened before) being activated include becoming more aggressive which (in a vehicle-related context where he is driving could include speeding, sudden acceleration, harsh braking, sudden movements, detected by leveraging vehicle telematics sensors or phone motion-type sensors), and changes in his speech characteristics and patterns such as Yelling, becoming strangely silent, use of profanity, increased (or decreased) volume from normal patterns, or talking faster, as well as increases in skin temperature or blood pressure (using various body devices such as rings or watches with appropriate sensors) or changes in facial expressions (using drive cams or phone cameras). As described in patents and patent applications listed above in the Cross-Reference to Related Application section (and incorporated by reference herein), it can be essential to appropriately understand the context(s) within which the measurements (and hence potential behavior determination/interpretation) are made. And since such measurements—of behaviors, contexts (or contexts and locations, as used in the claims), and potential updating of risk calculations—may be power-intensive, the measurements need to be done in the most efficient and effective way—balancing the need for data and information with effective use of constrained resources, e.g., battery power, high cost wired power, etc. So, instead of taking frequent, ongoing measurements of all possibly useful sensors associated with the persons in the ballgame party 24/7, continually or nearly so the entire timeframe of potential concern (in this case from an hour before Joe/Jane/Jenny leave the house to go to Mike/Mary and then the ballgame, and then later an hour after arriving home from the game), it is important to breakdown the various contexts in more detail, not just general ones like “prepare to go to ball game,” “ride to ballgame,” “attend game,” ride home from ball game,” and “unwind from ball game” or something similar, but more granular, personalized actual and particular “perceived” contexts.

Back to driving to the game scenario, all the parties were going to go to the game in the same car, with Joe driving. Driving time from Joe/Jane's house (with Jenny in tow) to Mary/Mike's home was typically 30 minutes, and then another hour before they can get a parking space, a mile from the entrance to the stadium. Joe has already had a tiring day, so the trip is wearying on him, and he is dreading the drive home already. Various sensors geared towards detecting Anger-related behaviors show his level of irritability slowly but steadily driving. For Jane the trip seems short, as she is catching up on the latest news from her parents Mike and Mary-a relaxing activity for her. Jenny is on her phone the whole time; the only time she looks up from her phone is to complain about what's on the radio-she is doing this enough to start to irritate Joe more as the trip goes on. For Mike and Mary the drive is a delight, catching up with their daughter and granddaughter. They pay no attention to the increasingly bad traffic, nor do they notice how hard it seems to find a parking space, until Mike starts giving Joe unsolicited advice on finding one, which is making Joe increasingly irritated at his in-law as well as more frustrated when Mike's suggestion finally pans out. During this time, Joe is getting increasingly hot (which he does when irritated or worse), and he keeps turning up the A/C, but has to stop when the others complain, leaving all of them cool but comfortable except for Joe.

While they have finally found a parking spot, the parking is $50, which Mike doesn't offer to pay for despite them all going to the game for free using Joe's company box seat tickets—increasing Joe's overall irritation level, which is a major related trigger to Joe's Anger. They had to stop for gas on the way to the ballpark which Mike didn't offer to pay for either. Joe is already worried about money in general despite the free tickets, as job cuts at his company have been rumored. It doesn't help that Joe knows that at the game other company employees will be seated nearby also using company tickets, at least one of them a rival of his and who will not hesitate to spread any gossip about Joe and his family the next day in the office. It is well known within Joe's company that office backstabbing is bad in general and gets especially vicious when job cuts are looming. The walk from the parking lot to the stadium is another seemingly the same (actual) context for all the party's participants, but the walk is perceived very differently depending on the individual. For Joe, each person they have to go around, pass, or is in front or behind them is an irritant or worse. Jane is oblivious as she is still catching up with her parents, and they are enjoying the walk as well. Jenny for logistical necessity has to stop using her phone, so the walk is unpleasant for her, though occasionally broken up by seeing others her age. But it is a mile walk, and Joe is already tired from the grass cutting, and Jenny rarely walks that far at one time. For Mike/Mary, the walk is hardly any exercise at all.

Up to this point the system has being periodically monitoring various Anger-related behaviors and associated contexts an calculating current and future risk and historical trend lines, developing a risk score and “velocity” (rate of increase in the risk score), perhaps normalized by a variety of factors (e.g., previous ball game visits, climate situation, who he was with, etc.). Data collection started off using its normal sensors used, sensor collection frequency and volume. By the time the party gets to the stadium the system will have concluded that Mike/Mary have very low risk of Anger or related triggers, and “tune” sensors related to them (or to them only) to the minimum number, frequency, and volume that will allow at least occasional checks on Mike/Mary's mental and physical state. At the other end of the Anger-related spective, the system will have recognized Joe's growing irritation, and projects that it won't take many more Anger-related behaviors and/or contexts for him to reach his Anger activation threshold. As such the system maximizes data collection from all available sensors et. al. on/in/around Joe and his party (as it relates to Joe, e.g., data collection from Mike/Mary's respective devices will be kept to a minimum except when Joe-related data is possible to be collected, such as a setting that starts collecting contextual and Joe-specific information when Mike/Mary's devices are within 15 feet of Joe), as well as sensor collection available within the stadium and relevant data available externally (e.g., weather forecast, competing teams scoreboard (Joe may get angry if his team's main rival is winning their game). The system also begins formulating potential actions to reduce Joe's Anger-related behaviors, such as recommending Joe drinking soft drinks instead of beer, and remind him to watch his actions around his company peers at the game.

Finally, they all arrive at the entrance to the ballpark. At this point Joe is significantly irritated; the rest of the party not-just excited (except for bored Jenny). They all have to walk halfway around the stadium to get to their entrance, only to then find a big line to get into the ballpark. This increases Joe's body temperature, volume and pattern of speech, and overall general irritation with the hassle of just getting to their seats. The system may increase its attempts to calm Joe, perhaps with soothing text messages; it may also start to enlist others in the party, such as warning Jane of Joe's increasing irritability so that she is aware of it and is cognizant of risky contexts and, conversely, opportunities to calm him down, such as suggesting Joe take an extra dose of blood pressure medicine (only after the system does a proforma analysis on Joe's current blood pressure and response to temporary increases in it in contrast to elevated blood pressure possibilities in the current context (put another way: is it better to take extra medicine when it appears Joe is at risk of spiraling out of control, vs. Not taking more medicine and his blood pressure continuing to elevate in risky contexts (e.g., very hot weather).

They find their way to their seats, and Joe has to introduce his family to company associates (and their families) immediately nearby including his rival. The context for Joe instantly switches from an “I'm-finally-here and-I'll-try-to-have-fun-and-relax-at-the-game” context to one of “The-heck-with-the-game-how-do-I-get-through-this-night-without-losing-my job” context. In a few minutes it becomes immediately apparent to Joe that his rival has been talking to his wife about Joe—unflatteringly—though invasive questions being asked. Jane finally becomes aware of the change in Joe's perceived context, through a message sent to her from Joe's system to hers, possibly peer-to-peer). To make things worse, Joe's wife and the rival's wife instantly take a dislike to each other to similar to their husbands (though Jane's is a more visceral, personal dislike, versus Joe's more competitive rival dislike). Joe, while somewhat gratified by Jane's understanding, also is anxious that it might lead to an incident or at least be gossip worthy in the office the next day. Joe is also worried about the impression Jenny is making with her constant focus on her phone, which even Joe thinks can be rude and even silly to focus on when there are at a major league baseball game with great seats. Mike and Mary are furthest away from the other employees and not much of a factor—though the system recognize them as nearby potential support resources that could diffuse a confrontation. If Joe or Jane's anger-related levels reach a certain point for certain contexts (e.g., Joe starting to raise his voice), the system may increase Mike and/or Mary's data collection so that the system has real-time/near real-time data as to Mike/Mary's potential for calming Joe down.

Even before the game begins, Jane is expecting Joe to buy everyone in their party refreshments even though Joe obtained the tickets through his company and their key problems at the moment involve money, Jane generally dislikes baseball (but is happy to go with her parents), the seats will be in the sun most/all of the game and it is already hot and likely to get worse. Joe and Jane both have an alcohol problem for which Joe's main trigger is Anger while Jane's main trigger is Anxiety, and both have related Triggers of Proximity and Smell (Joe with Beer and Jane with Wine), both of which are major issues with being at a professional baseball game, in seats, in the refreshment line, even in the ballrooms. But that's not the end of possible trigger impacting events today: Joe and Mike are rooting for different teams playing today, and Joe generally doesn't get along with his inlaws while Jane is almost pathetically attached to them, and Jenny could care less. Whatever the outcome of the game, they are all going home from the game in Joe's (small) car. But that is not the end of the contextual fun: as mentioned the seats at the game are in a box shared by fellow employees of Joe, Joe knows at least one of the employees attending the game in the same box and does not like him (and they are rivals for a possible promotion, or at least surviving the rumored job cuts), and Jane (Joe's spouse) has not met Joe's co-worker/rival spouse, who appears to be very different in background in in age (e.g., far younger than the rival and Jane). Plus, the fellow employee and his spouse have no children and have made indications in the past they do not care for children, and are eyeing Jenny with disgust mixed with amusement. All of these contextual parts/elements have the potential to be applicable to Joe's Anger trigger(s) or Jane's Anxiety trigger(s) and, in turn, relapsing on alcohol, nor would they be the same depending on whether it is the Anger or Anxiety problem that is at risk, nor would the related triggers (to Anxiety) of the spouse's spending Money on refreshments.

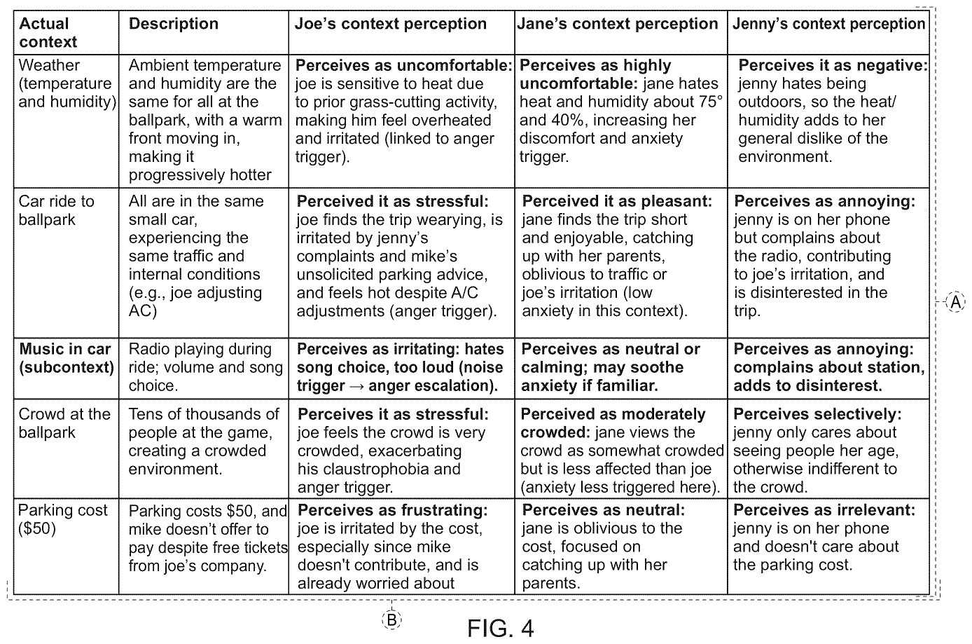

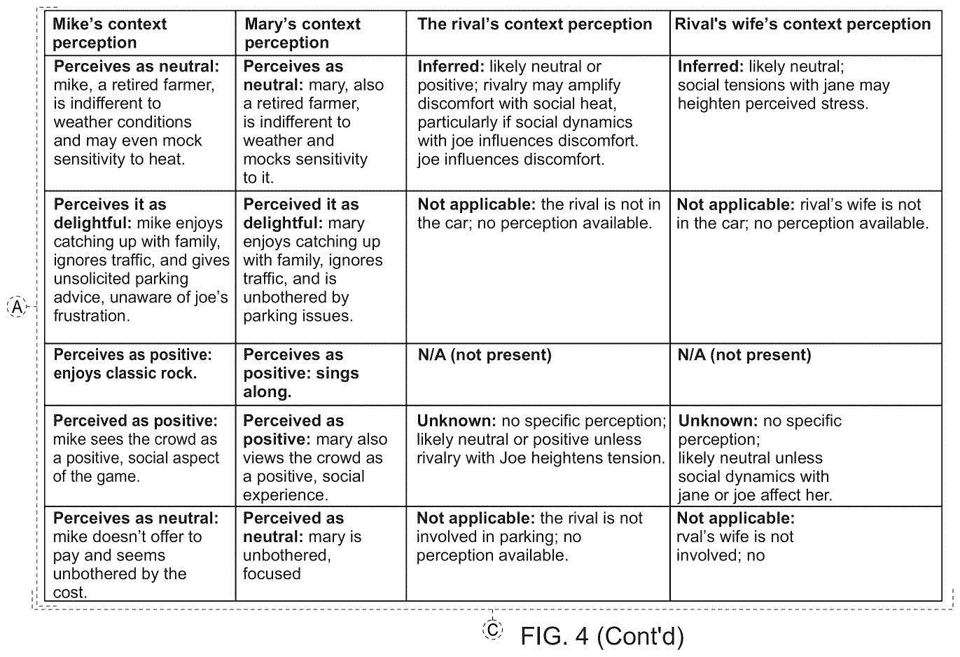

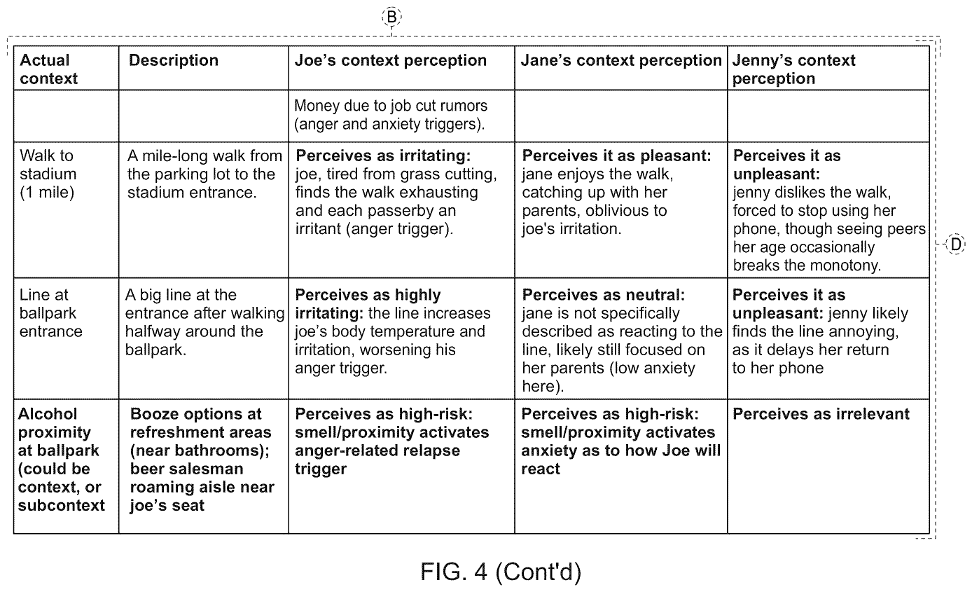

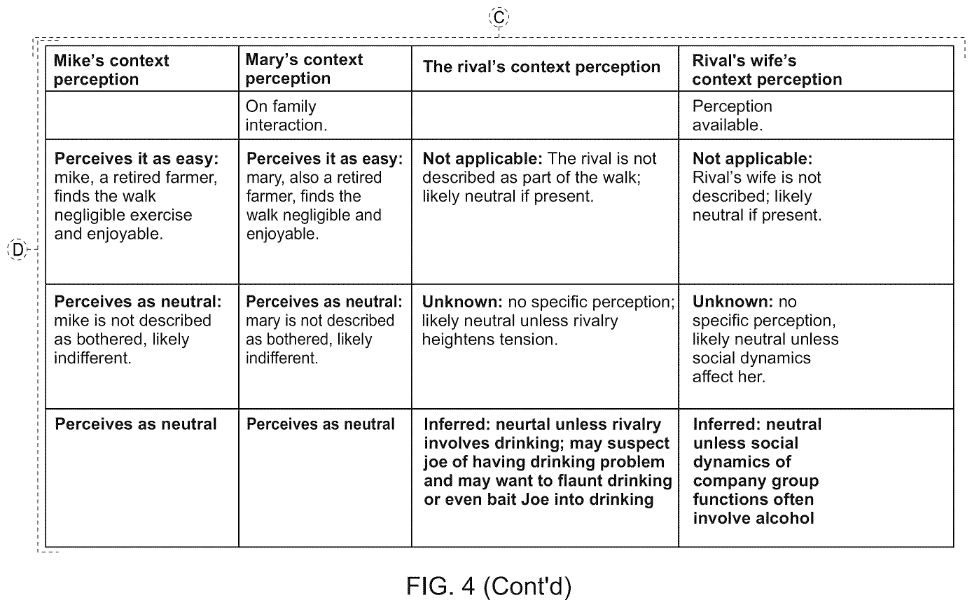

As shown above, in this one go-to-a-ball-game overall context there are literally dozens of contexts within various bigger contexts. Each of these detailed contexts ‘may have a variety of behaviors being exhibited by a variety of people. Some of those behavior/context combinations may result in risk elevation (or decreasing) for particular Triggers for different people. Indeed, there are contexts even within very “small” contexts (radio music playing, traffic conditions, conversation topics, car temperature/AC, etc.), as well as the same physical context (such as the music the car radio is playing) being perceived differently depending on the person (K-Pop music being viewed as obnoxious noise by Joe, while being viewed as comforting background music by Jenny, while being completely ignored by Jane and Mike and Mary as they talk with each other). FIG. 4 includes a table showing some of the contexts-within-contexts, and how “actual” contexts can be perceived differently by different people, particularly when viewed through a trigger and/or behavioral perspective.

FIG. 4 includes just some of the contextual elements that the party is experiencing that day, just for part of the day. Many more contexts-actual and perceived-could be experienced in an overall ballgame-related context, say from early afternoon on gameday Saturday getting ready to leave for the ballgame until about 9 μm when Joe finally gets home, fights with his wife about the interactions of the day (particularly with respect to his rival and his wife), and goes to bed. All sorts of other contexts could also have occurred at any point during the day, including for example being hungry, needing to use restroom, getting important calls during the game, mini-dramas with Jenny with her being on the phone instead of watching the game, etc.

Without yet even considering these contexts, Joe may have a variety of triggers that are particularly bad for him as well as his loved ones. Joe may have an Anger problem, which may lead to him drinking and/or actually possibly result in domestic violence, at least in the form of verbal abuse or at a minimum embarrassing himself and his family. Related triggers that can lead to Anger for Joe is when Joe gets Frustrated, as well as when Joe has difficulties with his spouse. Depending on the particular contexts, the irritation that Joe experienced in the getting to the ballgame overall context could be view as underlying behaviors for Anger, or a related trigger, or both. Another distinct trigger that might lead to substance (ab) use but more generally leads Joe to be unhappy and unpleasant is Anxiety, which has related triggers such as job and/or money problems. While Anxiety is a minor trigger for Joe (by itself it is unlikely to cause relapse), it is the major one for Jane. They could “feed on” each other, such as when Joe sees Jane getting anxious, he gets increasingly angry (or frustrated, leading to anger), which in turn feed Jane's anxiety, which in turn feeds Joes anger—spiraling on each other until it doesn't take much for either or both of them to have a trigger event. Being aware of these kind of co-dependent interactions and contexts could have a major impact on power consumption-requiring (more) frequent, comprehensive data collection not for just Joe and his Anger-related contexts/locations (generally “contexts” unless specified otherwise) and behaviors, but also for Jane and her Anxiety-related contexts and behaviors. Put more generally, a person's trigger is not just dependent upon his triggers, behaviors and contexts, but others as well. Further, the contexts and behaviors that may be applicable to Joe's situation may have nothing to do with Joe's environmental, physical, or mental state, and may vary widely. For example, Jane may be OCD, but only OCD in certain contexts, e.g., OCD at home or at work but not in crowds. Or OCD only when it cold. Further her OCD sensitivity may depend on her hormonal levels, or even what she ate or medications she took that day, and when. Sorting out these complexities, in a practical way that avoids needing to collect as much data as possible, as often as possible, from as many sources as possible, is a major goal of this invention.

Each of these triggers (primary and or related), when reaching a certain level, can “activate” or otherwise reach a point or threshold where “bad” things happen, such as substance (ab) use, violating parole conditions or restraining order, or otherwise make Joe's life and/or his family highly unpleasant or generally just embarrassing. A goal of inventions disclosed in patent(s) and patent application(s) listed above in the Cross-Reference to Related Applications section (and incorporated herein) is to reduce the risk of triggers either from occurring or reaching the point where they cause “real” problems. This includes looking to pre-empt and/or mitigate behaviors that could result in the triggers activating-forms of “early warning” behaviors. Such early warning behaviors can vary greatly and involve many different possibilities in general. But exemplary embodiments disclosed herein are in relation to particular triggers. For example, Joe's speech changing in tone, frequency, word usage, recipients, form (e.g., vocal versus text versus email, etc.) and/or volume, or patterns involving some or all of the above, could be early warning indicators of different Joe triggers-Anger, Anxiety, (Desire to) Escape, Frustration, Money, Noise, Relationships, etc. And because Joe (and every human) exhibits multitudes of behaviors-physical, mental, or both-every day, figuring out which behaviors might be “worthy” early warning behaviors to monitor, for what triggers, can be highly problematic and algorithmically difficult, if not impossible. To do so, exemplary embodiments disclosed herein focus extensively on determining and appropriately considering the context(s) of Joe's various trigger(s) and potential preemptive behaviors. For a given trigger, certain behaviors in one or one set of contexts may indicate a significant risk of a trigger being in danger of activating, but in another context/set of contexts they may not indicate a significant risk. Further, even for the same entity at a same period of time, the relevant contexts may actually be very different depending on the trigger. Generally speaking, the high the risk of an activation, the need for more data, from more sensors, more frequently, with more associated analysis, with higher likelihood of associated actions-all of which will need more power than a “normal” (low/medium) risk situation.

An example of varying power needs—and how they can change (or need to change) dramatically with the use of sophisticated algorithms and capabilities such as artificial intelligence and machine learning as learning about a person progresses—can be shown with Joe's Anger trigger. When setting up the initial monitoring of Joe's Anger problem, it was known that Joe tended to get Anger when he was overheated. Or, put differently, Joe was much less likely to get Angry-no matter what the context—if Joe was not overheated. As such initial data collection and ongoing analysis for Joe's contexts would include ongoing monitoring of Joe's skin and body temperature, primarily via his smart ring and smart watch. But what did not become apparent until the associated AI/machine learning capabilities came into play was that “overheated” was not just a physical thing, e.g., cutting the grass for 2 hours outside in 102 degree weather in the sun with 60% humidity. Overheating, even when measured by Joe's wrist device temperature sensor, could occur when Joe got into arguments. But it was only when these arguments occurred when it was at least 76 degrees with at least 50% humidity, and with a family member or about Joe's job, did a physical reaction kick in and Joe's body temperature rapidly elevate, which, in turn, rapidly turned into changing speech patterns, then various degreees of Anger, then followed by Anger being at a certain level or over a certain threshold for x minutes did a risk of drinking start to exceed key limits. Through these kinds of learnings, Joe's smart rings and smart watches could be configured to only periodically check on skin and body temperature, and his phone focused on a more limited set of key word detection, reducing power consumption relative to what would be needed with ongoing/very frequent monitoring.

Similarly, not all contexts—actual and/or perceived—are equal in terms of power consumption needs. Working backwards from all the contextual elements, only a subset of the contextual elements are likely to be relevant to Anger. And while Joe's body temperature is (now) known as a key physical behavior of Joe related to Anger, since it is detected by using a battery powered ring (or, in the case of being out on parole a specialized ankle bracelet), there are key limits in how much it can be used (e.g., how many readings can be taken) before it is recharged, and/or Joe is in a position to enable the device battery to be recharged. In the meantime, it is critical to not prematurely wear out the device battery charge where the possibilty of “bad” behavior occurring that may indicate a rising level of Anger risk is low. In short, and particularly for battery powered sensors etc. (such as ring, watch, or ankle devices, etc.), there may be in practically only a few dozen (or at best a couple hundred) of temperature readings that can be taken between recharges. So the temperature readings need to be used sparingly, and when most useful-either in early detection of a possible trigger/behavior risk situation, a confirmation of a risk trigger, to collect data in formulating actions to reduce the risk, and/or collecting data to confirm the risk has been avoided/lowered. Full blown, all-sensors-on-deck battle stations with respect to Anger detection may be limited to very specific contexts and/or risk levels (for example, trend analysis showing Joe is one incident from reaching his anger threshold). Monitoring of the impact of actions may also require full sensor utilization as well.

Generally, these methods and systems for managing power consumption only work as well as the associated use case. For example, to ensure the lights are on and the house is warm by the time or arrival at home from work, calibrating (e.g., configuring) the timing of when your home systems power up will balance the tradeoff of making sure the house is “ready to go” for your arrival versus the house being warm/lighted well before arrival is a key tradeoff, one that could be dependent on various dynamic, contextual factors, such as traffic, time of year (e.g., how long the sun is shining and at what angle), weather, if a stop for groceries is planned, whether it is just one person coming home or also people with different lighting/heat needs, etc. These dynamic, contextual factors are not accounted for by conventional systems, such as geofences, time-based light/heat activation (e.g., turn up the heat to 72 degrees every weekday at 5 μm), or other sensor capabilities such as determining/inferring occupancy (which is only good upon arrival at home, e.g., is there anyone in the house that even needs lights?). Additional use case capabilities, such as pre-heating the oven, add additional issues, such as safety. As tempting as it may be to be able pop something in the oven the instant you get home, having unattended high temperature appliance at work is a major safety risk.

Even in the above home scenario, most of the power-consuming components are likely to be wired for electrical power, not battery powered. For such wired situations, the benefits of the invention tend to be focused on improving convenience while reducing the use/cost of energy, wersus focused on energy availability. When the use cases become predominately battery power-intensive, there management of power consumption becomes achieving a balance between minimizing power consumption while getting the use case to work. This challenge magnifies when the components involved, such as a sensor, is a small device with a small battery (and thus relatively small capacity). And thus the sensor's ability to be used is inverse to how, how often, and how long it is used. In other words, the more the sensor is used now, the less likely the sensor may be usable in the future before the sensor needs to be recharged or the battery replaced. Even geofence-oriented use cases such as parolee monitoring have a major recharging issue: the parolee has to recharge the battery while wearing it—an unpleasant necessity and potentially a very complicated logistical one. Various forms of implementation for achieving this balance as envisioned by this invention will be needed, such as:

### Sensors

Sensors (e.g., temperature, humidity, motion, or biometric sensors like blood pressure monitors in wearables) are the frontline data collectors for detecting behaviors (e.g., rising skin temperature as an Anger trigger precursor) and contexts (e.g., environmental heat). Key to managing power will include low-power, autonomous operation with AI-driven selectivity to avoid constant polling. Examples/variations include:

Edge AI-Enabled Sensor Nodes: Here, each sensor could use a microcontroller unit (MCU) with integrated ML accelerators (e.g., tiny ML frameworks like TensorFlow Lite Micro) to perform on-device inference. This allows the sensor to self-regulate power by predicting relevance based on contexts—e.g., reducing sampling rate if no trigger risk is detected via local ML models trained on historical behavior data. Specialized components could include one or more “power-focused cookie(s)” such as a small, non-volatile memory store (e.g., EEPROM) holding contextual state (e.g., last known trigger threshold), enabling quick resume from sleep capabilities without full recalibration.

Anomaly Detection Pipelines: These would involve using unsupervised ML (e.g., autoencoders) to monitor for triggers (e.g., sudden behavior changes like harsh braking detected by accelerometers). Associated architectures may be event-driven, where sensors remain in ultra-low-power mode until a wake-up interrupt (e.g., via GPIO pins) from a contextual cue, then activated briefly for data capture. This optimizes battery-constrained sensors in mobile scenarios.

Dynamic Use Case Implementation Fit Designs: These support use case needs like dynamic calibration (e.g., adjusting metrics/ranges via ML feedback) by embedding RL agents (Reinforcement Learning agents used to optimize power usage across sensors, sensor arrays, devices, systems, and networks by learning policies that balance data utility (e.g., for predicting behaviors and contexts) against energy constraints (e.g., battery life)) that learn from past power usage to fine-tune activation thresholds, ensuring sensors only power up when behavior risk (e.g., Anxiety escalation) exceeds a predicted threshold.

### Sensor Arrays

Sensor arrays (for example, multi-sensor hubs in wearables or vehicle telematics combining GPS, gyroscopes, and microphones) aggregate data for comprehensive context/behavior analysis (e.g., detecting Frustration via speech patterns+motion). Architectures would emphasize fusion and coordination of sensor elements to distribute power load. Examples/variations include:

Sensor Fusion Architectures with ML Orchestration: These might use Kalman filters or Bayesian inference engines (e.g., in a central hub microcontroller) to merge data from array elements, reducing redundant sampling. AI integration: Supervised ML models (e.g., neural networks) predict array-wide power needs based on correlated triggers (e.g., if one sensor detects heat, prioritize others for Anger-related behaviors). Specialized components may include a power management integrated circuit (PMIC) with AI co-processors (e.g., Arm Cortex-M with ML extensions) that acts as a “traffic cop,” dynamically gating power to subsets of the array.

Hierarchical Power States: Arrays could employ fuzzy logic controllers (rule-based AI) to classify contexts (e.g., low-risk “car ride” vs. high-risk “crowded ballpark”) and trigger tiered modes—e.g., primary sensors active for high confidence, secondary for verification. “Power-focused cookies” here could be shared state tokens across array nodes, persisting fusion results to avoid recomputation post-sleep.

Other variations: These would align sensor arrays with risk-tiered usage by using RL to optimize array configurations and/or projecting power scenarios based on fused data for future behaviors.

### Networks

Networks (e.g., mesh or LPWAN like LoRaWAN for connecting sensors/devices) could handle data transmission for system-wide analysis, where power is critical for battery-powered nodes. Architectures may focus on low-latency, efficient protocols with AI for routing and scheduling.

AI-Optimized Low-Power Wide-Area Networks (LPWAN): Possible implementation architectures include NB-IoT or Zigbee with ML-enhanced MAC layers for adaptive duty cycling, e.g., RL agents learn optimal transmission intervals based on network context (e.g., traffic load) and entity behaviors (e.g., infrequent updates in low-risk scenarios). Specialized components could include network gateways with edge ML (e.g., Raspberry Pi with PyTorch) that predict recharge likelihood (e.g., via historical patterns) and adjust node power budgets.

Mesh Network with Contextual Routing: These could include nodes form self-organizing meshes where AI (e.g., graph neural networks) routes data via lowest-power paths, triggered by behaviors (e.g., escalating risk prompts priority queuing). “Power-focused cookies” could be protocol extensions (e.g., in BLE) storing node energy states for collaborative decisions.

Other Variations: These could include predictive power control across distributed entities, using ML to scale usage based on trigger events propagated via the network.

### Devices

Devices (e.g., smartphones, wearables, rings, implants, smart glasses, etc.) could integrate sensors and process local data for immediate behavior predictions. Architectures would focus on prioritizing hybrid edge-cloud processing to offload heavy ML while conserving local power. Examples/variations include:

DVFS-Enabled Devices with RL Policies: These would involve using dynamic voltage and frequency scaling (DVFS) controlled by ML (e.g., RL agents in device OS like Android's Adaptive Battery) to adjust CPU/GPU clocks based on contexts (e.g., downscale during low-risk “unwind” phases). Specialized components: Dedicated AI chips (e.g., Google's Tensor Processing Unit or Qualcomm's AI Engine) for on-device inference of triggers, with “power-focused cookies” as app-level caches storing user profiles for quick personalization.

Adaptive Battery Management Systems (BMS): These would involve devices employing fuzzy logic or supervised ML to monitor battery health and predict usage, triggering modes like “less accurate” sensing (e.g., lower GPS precision) in safe contexts. For wearables, architectures include energy harvesting (e.g., solar/kinetic) integrated with ML forecasting.

Other Variations: These could include supporting future power estimation (claim 19) by device-level ML analyzing behaviors, with actions like UI alerts for risk mitigation while optimizing power.

### Systems

Systems (e.g., overall platforms for behavior modification) would orchestrate all components via cloud/edge hybrids, using AI for global optimization. Examples/variations include:

AIoT (AI+IoT) Hybrid Architectures: Thes would involve Cloud-based ML (e.g., AWS IoT with SageMaker) for training models on aggregated data, pushed to edge devices for inference. RL for system-wide policies, e.g., simulating power scenarios for projected risks. Specialized components could include Central orchestration engines (e.g., Kubernetes for IoT) with anomaly detection to trigger escalations.

Feedback-Loop Systems: These would use time-series forecasting (e.g., LSTM networks) to project recharge and usage, incorporating “power-focused cookies” as distributed ledgers for system state synchronization. In smart environments (e.g., buildings), occupancy-based AI adjusts connected devices.

Other Variations: These would enable end-to-end management, with three-dimensional algorithms processing variables like confidence levels and power sources.

From the perspective of applications, the architectures needed to implement the patent claims for dynamic power management focus on software and algorithmic frameworks that orchestrate the sensors, sensor arrays, devices, systems, and networks to optimize power usage while predicting and managing entity-specific behaviors, contexts, and triggers (e.g., Joe's Anger or Jane's Anxiety). Applications in this context refer to software components running on devices (e.g., smartphones, wearables) or distributed systems (e.g., cloud or edge servers) that process sensor data, apply predictive analytics (AI/ML), and implement actions for behavior modification, all while dynamically managing power. Below, I outline the architectural requirements from the application perspective, incorporating elements like power-focused cookies (lightweight, stateful data structures for energy profiles), specialized power management components, and the reinforcement learning (RL) agents and microcontroller units (MCUs) previously discussed. I then propose a new claim to integrate these application-focused architectures with the existing claims.

### Application Perspective: Architectural Requirements

Applications, whether viewed from a standalone basis or as part of the above components such as devices (generally how this invention categorizes them), in this invention would be responsible for: collecting and processing sensor data to infer current and future contexts/behaviors (e.g., detecting Joe's rising body temperature as an Anger precursor). This would involve using predictive analytics (AI/ML) to assess trigger risks and formulate actions (e.g., sending alerts to mitigate relapse risks), dynamically managing power across components to balance data utility with energy constraints, considering battery life and recharge likelihood, and iImplementing user interfaces (UI) for actions like notifications or support resource activation. The associated architectures must support real-time processing, scalability across heterogeneous devices, and adaptability to dynamic contexts, while minimizing power consumption. Key software architectural considerations include:

Modular Application Frameworks with AI/ML Integration:

These applications must integrate AI/ML models (e.g., RL agents, neural networks) to predict trigger risks and optimize power usage. For example, an app on Joe's smartphone might use a lightweight neural network to predict Anger risk based on sensor inputs (temperature, motion) and adjust sensor polling accordingly.

The architecture may include a modular framework (e.g., Android Jetpack or iOS SwiftUI with MLKit) with components for:

Data Ingestion Module: Collects sensor data (e.g., via APIs for BLE sensors) and preprocesses it (e.g., filtering noise from Joe's heart rate data).

AI/ML Inference Module: Runs RL agents or supervised models (e.g., TensorFlow Lite) to predict trigger risks and power needs. For instance, an RL agent learns to reduce GPS sampling when Joe is in a low-risk context (e.g., at home).

Power Management Module: Interfaces with device OS (e.g., Android's PowerManager) to control sensor/device states (e.g., sleep modes, DVFS). It uses “power-focused cookies” as in-memory or persistent data structures (e.g., JSON objects stored in SQLite) to cache energy profiles, like current battery levels or historical sensor utility.

Action Implementation Module: Executes behavior modification actions, such as sending UI alerts (e.g., a calming text to Joe) or activating support resources (e.g., notifying Jane's parents).

Specialized Components: A dedicated power orchestration library (e.g., a custom SDK) that uses RL to dynamically adjust power settings based on predictions. For example, it might lower the frequency of speech analysis on Joe's phone when his Anger risk is low.

### Edge-Based Application Processing:

These capabilities would minimize latency and cloud dependency, with applications running on-device (e.g., on Joe's wearable or smartphone) with lightweight ML models (e.g., tinyML on MCUs). This would support real-time decisions, like deactivating a humidity sensor when Jane's Anxiety risk is low.

Architecturally, Edge applications may use:

TinyML Frameworks: Examples include TensorFlow Lite Micro or uTensor on Microcontroller Units/MCUs (e.g., Arm Cortex-M) for local inference of trigger risks and power optimization. For example, an app on Joe's ring might predict Anger risk from temperature data and reduce sampling if risk is low.

Event-Driven Processing: Edge applications could use event loops (e.g., Android's WorkManager) to trigger actions only when contextual changes occur (e.g., Joe entering a crowded ballpark). This leverages interrupts from MCUs to wake apps, conserving power.

Power-Focused Cookies: These would be implemented as lightweight key-value stores (e.g., SharedPreferences in Android) to persist app state, like last-known context (e.g., “Joe at ballpark”) or sensor utility scores, enabling quick recovery post-sleep without draining battery.

Specialized Components: These could include an embedded RL agent within the app, running on the MCU's ML accelerator, learns policies to optimize sensor usage (e.g., prioritizing biometric sensors over location when Joe's Anger is escalating).

### Cloud-Edge Hybrid Applications:

These capabilities would include complex analytics or training large ML models, applications offload heavy computations to the cloud (e.g., AWS IoT, Google Cloud AI) while maintaining edge-based inference for real-time power management.

Architectures could include a hybrid setup with:

Edge Layer: Apps on devices (e.g., Joe's phone) handle real-time tasks like sensor data collection and RL-driven power decisions, using MCUs for low-power processing.

Cloud Layer: Trains and updates ML models (e.g., LSTMs for behavior forecasting) using aggregated data, pushing updates to edge apps. For example, a cloud-based model might refine Joe's Anger trigger thresholds based on historical ballpark data.

Federated Learning: To ensure privacy (e.g., protecting Joe's biometric data), applications use federated learning to train models across devices without centralizing sensitive data.

Power-Focused Cookies: Stored in cloud databases (e.g., DynamoDB) for system-wide state synchronization, like tracking recharge likelihood across Joe's devices.

Specialized Components: A cloud-edge orchestration service (e.g., Kubernetes-based IoT platform) that uses RL to distribute power budgets across devices, ensuring system-wide efficiency.

### Context-Aware UI Applications:

Context aware applications deliver behavior modification actions (e.g., alerts, support resource activation) via user interfaces, tailored to contexts and triggers. For example, a calming notification to Joe when his Anger risk rises.

Architecturally these include UI apps (e.g., Android/iOS apps with React Native frontends, Various Apple environments) integrated with:

Context Inference/Determination Engine(s): These would use ML to determine “who, what, when, why, how” contexts (e.g., Joe's stress in a crowded ballpark) and trigger UI actions. Patent(s) and/or patent application(s) listed above in the Cross-Reference to Related Applications section and incoprorated herein address this kind of engine in detail.

Power-Aware Rendering: Would optimize UI power usage by reducing animations or screen refresh rates in low-risk contexts, controlled by RL policies.

Action Feedback Loop: Collects user responses (e.g., Joe dismissing an alert) to refine RL rewards, improving future power decisions.

Specialized Components: A UI power management module that uses DVFS to scale display power based on context urgency, with power-focused cookies caching UI state (e.g., last alert type) for quick rendering.

### Scalable Application Middleware:

These capabilities would coordinate across distributed sensors/devices, applications need middleware for data aggregation, power orchestration, and action synchronization.

Architecturally, this would include Middleware (e.g., MQTT-based brokers like Mosquitto) with:

Message Queuing: Prioritizes high-risk trigger data (e.g., Joe's biometric spikes) for transmission, reducing power for low-priority messages.

RL-Driven Scheduling: Uses RL agents to schedule data processing and action execution, optimizing for battery life across devices.

Power-Focused Cookies: Implemented as distributed metadata (e.g., in Redis) to track system-wide energy states, enabling applications to make coordinated power decisions.

Specialized Components: These could include a power-aware middleware engine that uses graph neural networks to optimize data flows in mesh networks.

Overall, these application architectures support predictive power management by running RL agents to adjust sensor usage based on trigger risks (e.g., Joe's Anger in a hot ballpark). They also support dynamic calibration via app-based ML models that analyze sensor data and adjust power settings for behavior prediction and action implementation.

They also support AI/ML-driven power management with three-dimensional processing (context, behavior, power variables) enabled by modular apps and RL agents, and RL agent execution on MCUs within apps, using power-focused cookies for state persistence.

These use cases and associated implementations will become far more complex in the future, as evidenced by the inventions disclosed in patents and patent applications listed above in the Cross-Reference to Related Applications section and incoprorated herein. As disclosed herein, the inventions focus on behavioral-oriented use cases such as early detection of the Anger trigger (and/or related triggers) and the involved behaviors and associated contexts. As described in patent(s) and/or patent application(s) listed above in the Cross-Reference to Related Applications Section and incoprorated herein, the ability to detect and pre-empt triggers such as Anger, Anxiety, etc., that may lead to even more undesirable events, e.g., parole violation, substance (ab) use, etc., is sensor-intensive. Further, many of these sensors, sensor arrays, devices, applications/systems, and even networks (particularly short-range networks, which can be battery powered in significant part), referred to here generally as “sensors, etc.,” are battery-powered or otherwise have limited ability to (re) charge, thus potentially limiting how they can be used, how often, for how long, and in what power-usage configurations-a problematic, even dangerous problem. For example, a parolee driven by Anger in his past crimes and/or substance use (which led to crime and/or addiction) could theoretically escalate into potentially violence-inducing, Anger triggered behavior in a very short period of time. If key sensors et. al. are not working because of lack of power, potential detection and mitigation may not be possible. Combined with increasing generation of data for all sorts of purposes, from all sorts of sensors et. al. (particularly small, mobile ones), and the need fot that data to be increasingly personal in nature, generates the need for a more sophisticated power management capability as described by this invention.

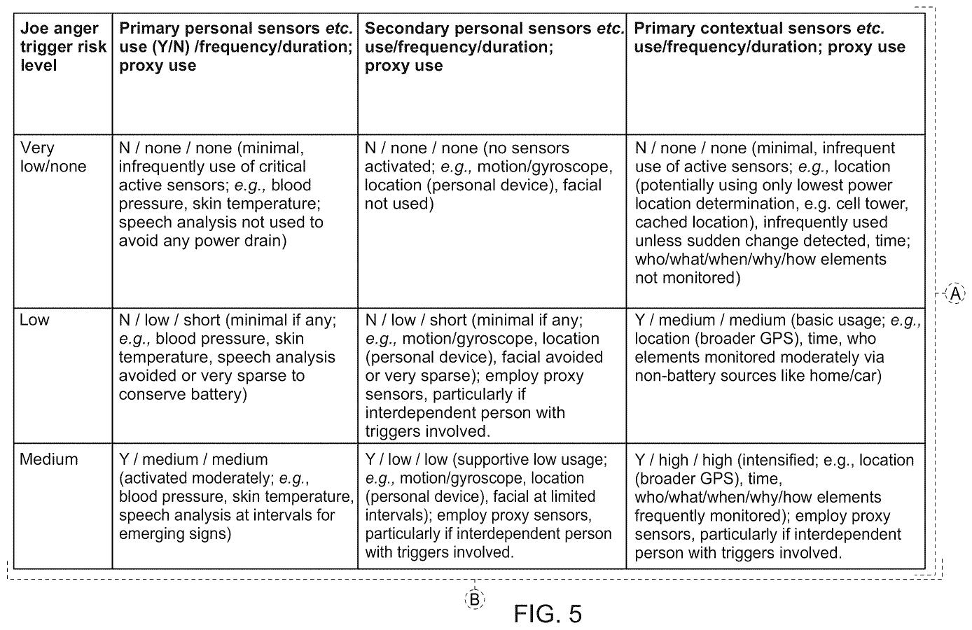

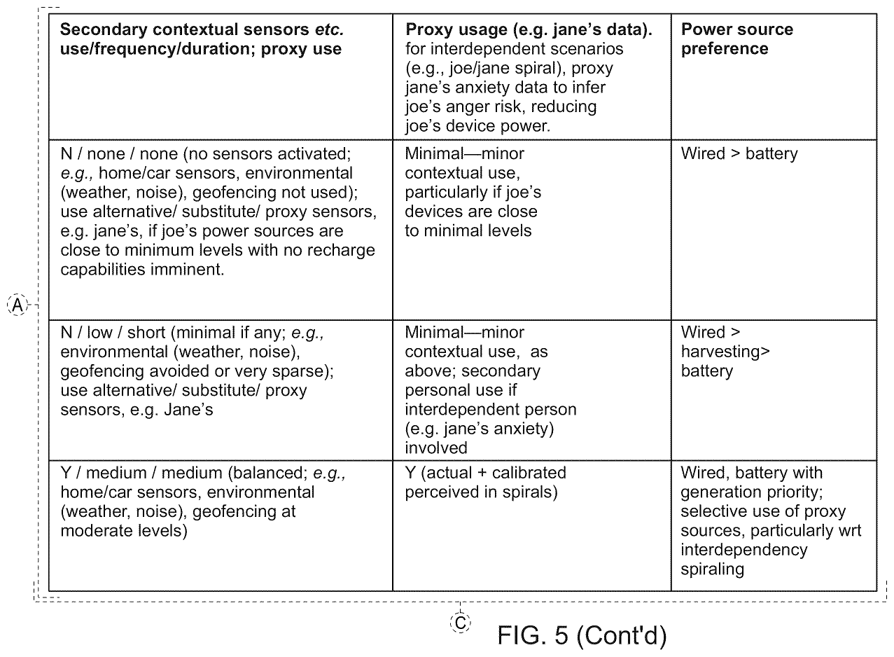

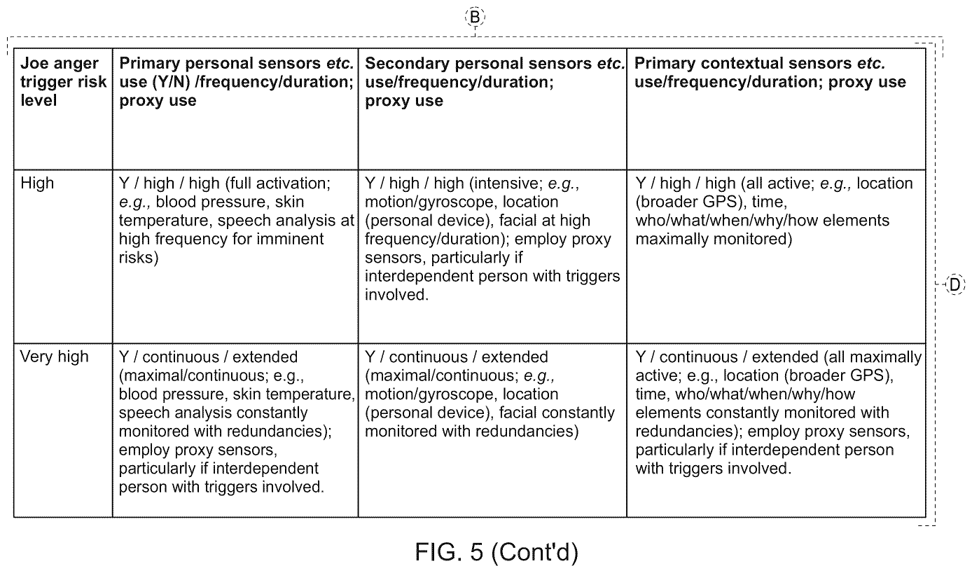

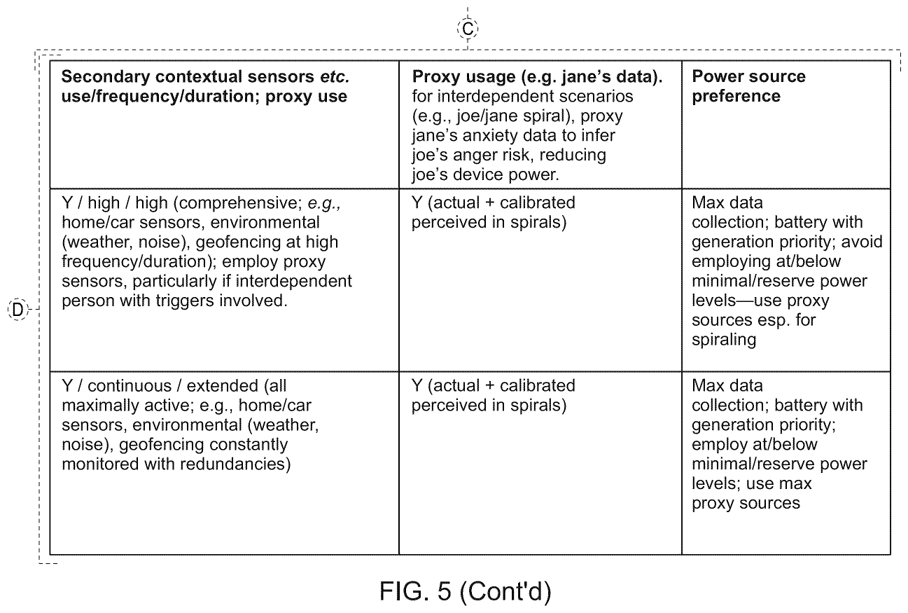

Mapping out and dynamically managing all these power options may be very complex. Just accounting for power management options for a single trigger for a single person (let alone multiple ones) can be highly complex. For example, FIG. 5 includes a table showing example options for managing Joe's sensors etc. for behavior and context tracking for various Joe's Anger risk levels.

As shown in the table of FIG. 5, there could be a variety of power options depending on the trigger, behavior, context, and available sensors, sensor arrays, devices, systems, applications, and networks. A tiering scheme could be employed that seeks to balance use of primary and secondary sensors etc. for various levels of risk. For example, there are overlaps in what kind of sensors/devices capture certain kinds of data, such as both smart rings and smart watches capturing various temperature and blood oxygen levels. In most contexts it will not be necessary to use power to capture data from both devices that can be well represented by one. In such cases, a variety of selection schemes could be used, such as determining (beforehand if possible) which devices have multiple sensors whose data is needed for that particular context(s)/behavior(s) determination. Thus, if a smart ring only captures one type of data, and a smart watch 3 kinds (including the one kind of the smart ring), then it makes sense (possibly) to use the smart watch and take advantage of one data transmission power consumption for all three of the watch sensors. Alternatively, if the key sensor is skin temperature, and both ring and watch provide that, but the ring is fully charged and the watch is getting low on power, and the other two sensor data elements from the watch are “nice to have” and not critical to the determination, then the invention could choose to obtain data from the ring so as to conserve power in the watch for future data collection needs where the watch sensors are primary sensors and particularly critical for high/very high trigger risk situations. This kind of power consumption balancing gets increasingly complex once power recharge opportunities are identified (or not), and more and more sensors etc. are introduced into the context/behavior determination equation. This is especially true if the user being monitored is moving (e.g., contexts are changing rapidly) or otherwise his/her context(s) are very dynamic (moving, but also him/her multitasking, multiple other people coming in/moving out of the contextual picture, etc.

Power consumption and in general context and behavior determination gets even more complex as personalization and other sources of information need to be incorporated (for example, Jane, the ballpark, and anger support resources in the Joe Anger at the ballpark example) and become available, and contexts are increasingly and dynamically identified—and potentially changing very rapidly—combined with ongoing evolution of a person's behavioral traits and contextual habits in general and the need for continual learning increases, and the need to formulate and implement (fast) various actions and to modify actions quickly if the first ones do not work, the ability for “normal” algorithms to handle all of the variables becomes increasingly problematic. Thus the use of AI and machine learning are keys in implementation.

Variations of the above chart may be filled in according to the following. The primary category may include the most comprehensive sensors for high risk, going towards not battery powered for low risk. Examples are blood pressure skin and speech for primary; secondary may include motion/gyroscope/location and facial for secondary. But generally, it is desirable to avoid battery powered for low risk when primary data is obtainable from a car or home type sensors or phones, thereby avoiding battery powered sensors except for high risk or trending towards high risk. For contextual, all sensors may be usable for high risk whereas home/car may be fixed for low risk. For context, generally want to know the where, when, and who the trigger is potentially being triggered by at a minimum (e.g., for every category of risk) with what, how, and why being premium context-related data to know at high risk levels because knowing all those elements will be key in high risk situations but not necessary (and unnecessarily power consuming) at low (er) risk contexts.

Processing of the options may take the form of a kind of three-dimensional processing algorithm aided by AI/ML, which will be able to decide from a host of options (e.g., tiered or hierarchical options, etc.) that includes all the different types of variables, e.g., primary sensors etc., secondary sensors etc., differing priorities depending on trigger behaviors and contexts, frequency of use, scope of use, different combinations, confidence levels, power source, cost, availability, power (e.g., battery) capacity, current and projected level, per use calculation, remaining uses before expected recharge, rechargeable ease/likelihood before battery exhaustion, various power levels possible (e.g., BLE), and other variables. Additional variables might include if a sensor etc. is used for which part of process, e.g., generation, processing, different types of usage, etc. this would be a set of factors related to priority, e.g., its utility. For example, if it is likely that a sensor etc. will be needed for action implementation, battery usage may be conserved for the action implementation versus ongoing monitoring to make sure there is enough power for the most critical use(s) of the sensors etc.

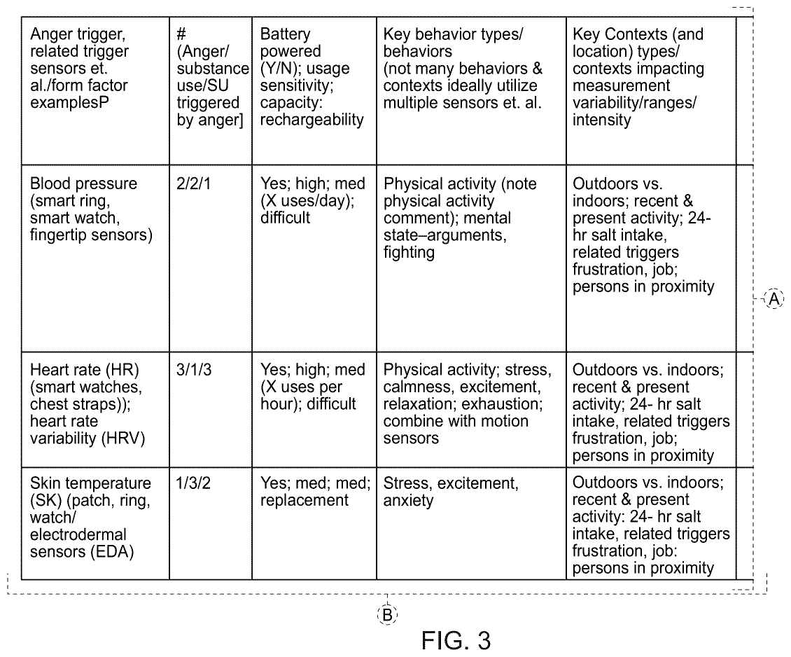

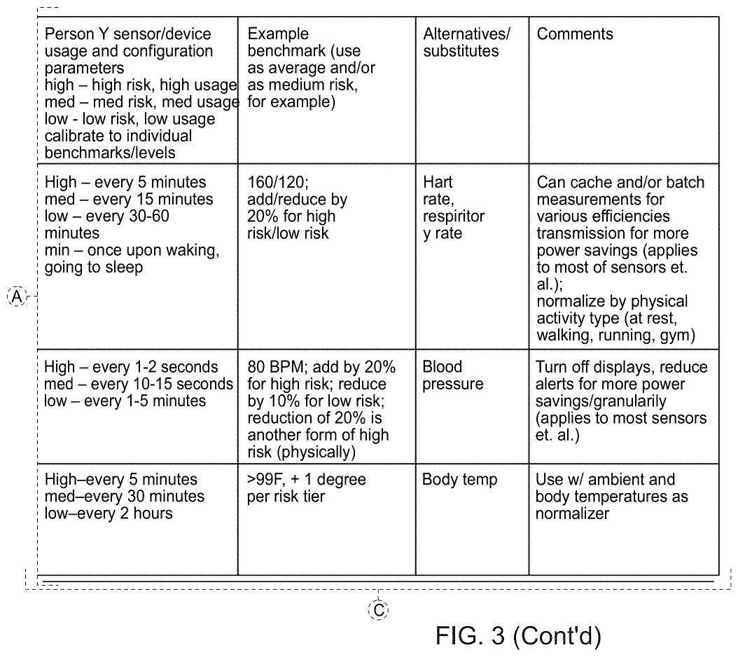

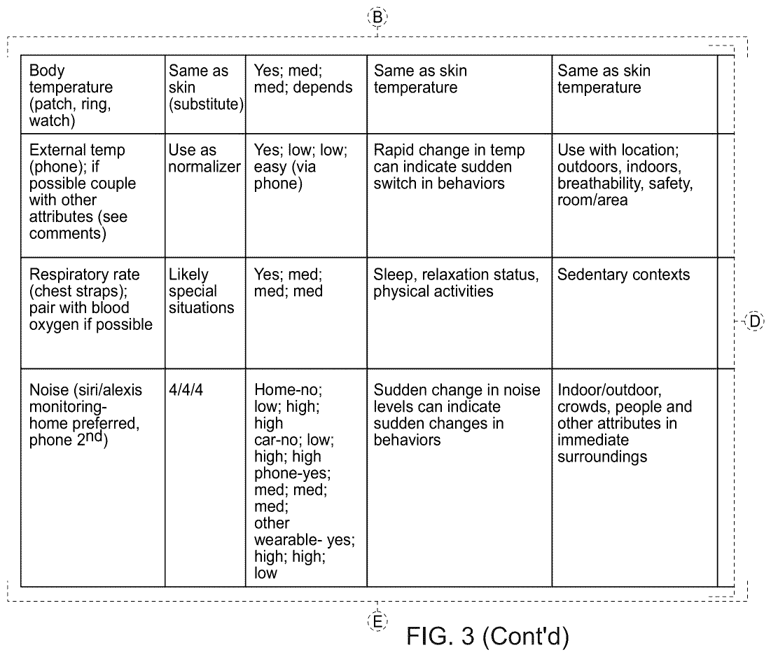

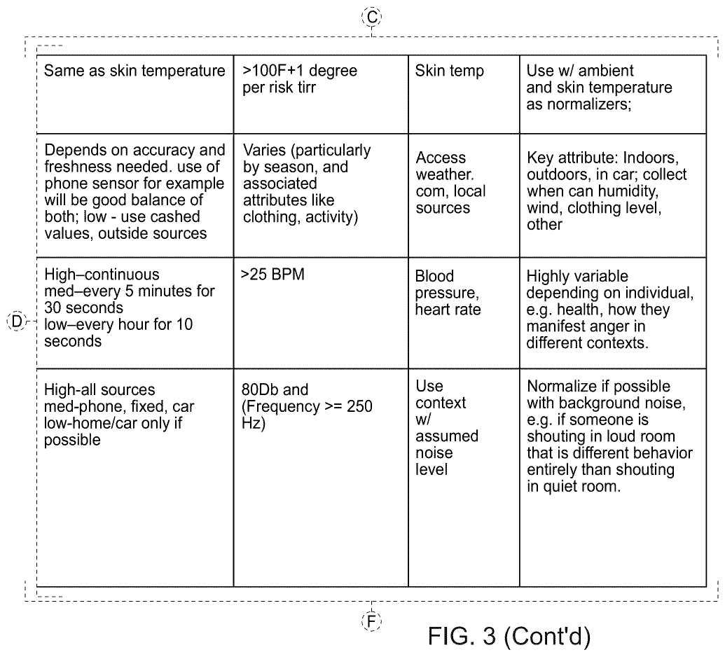

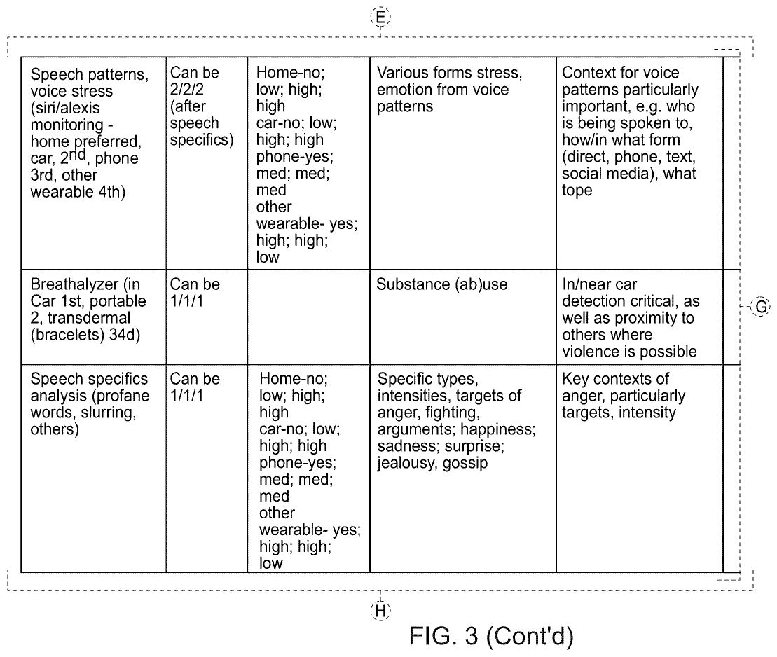

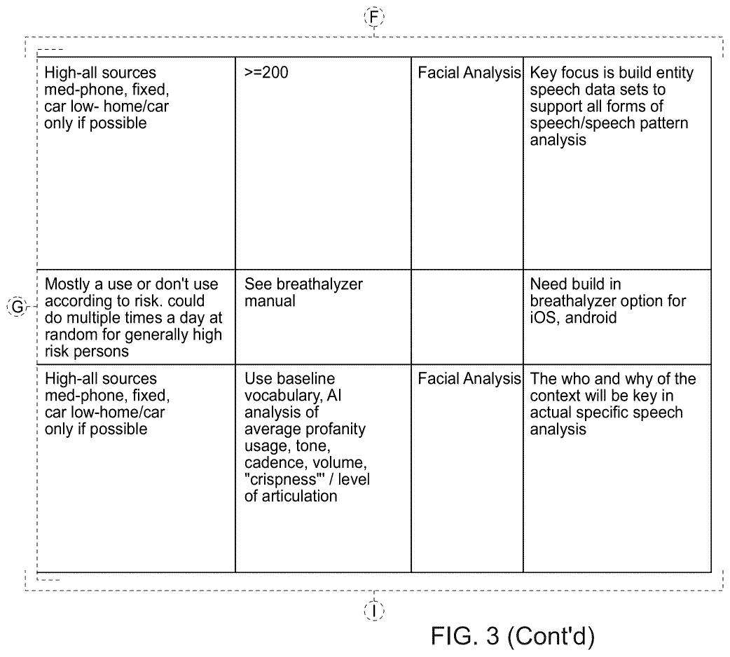

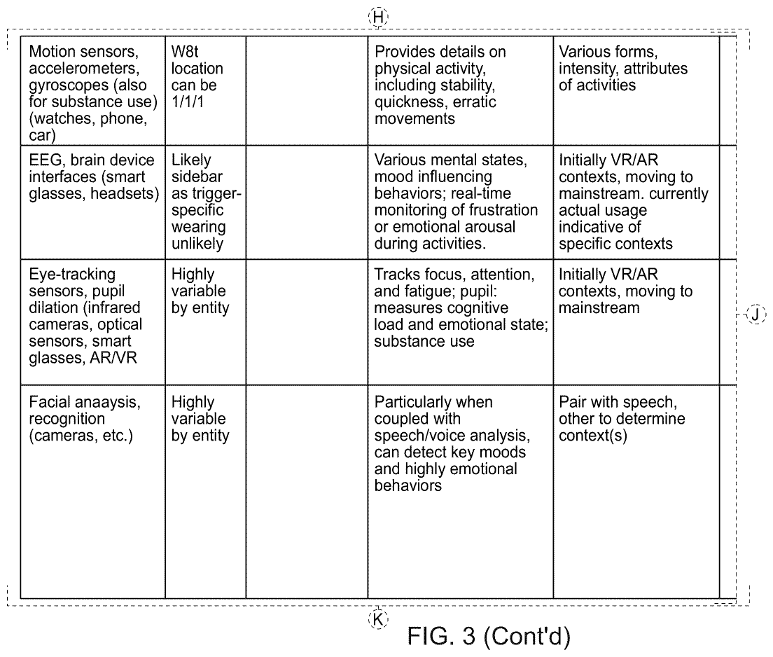

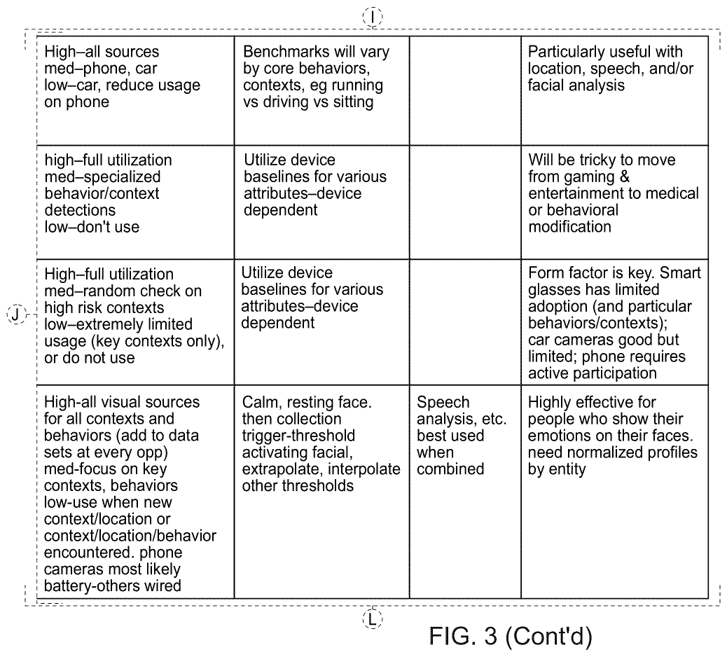

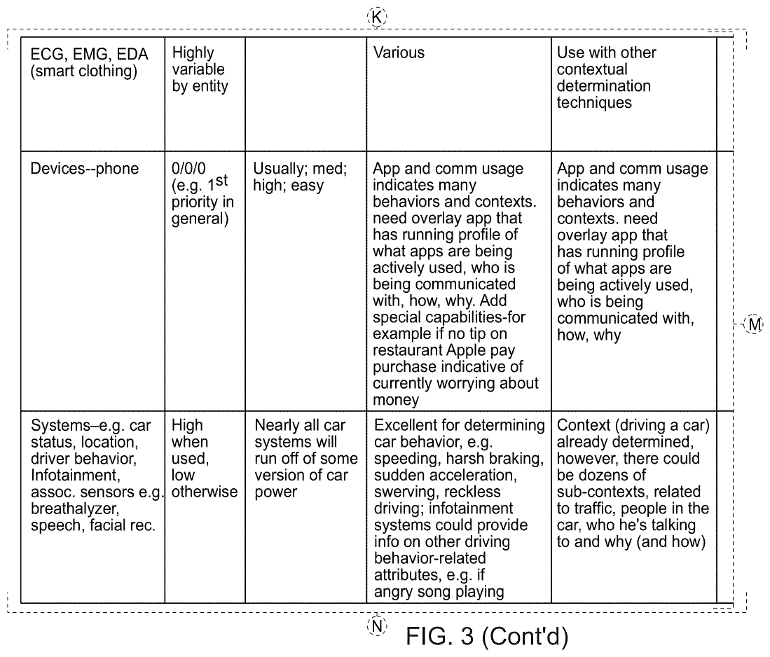

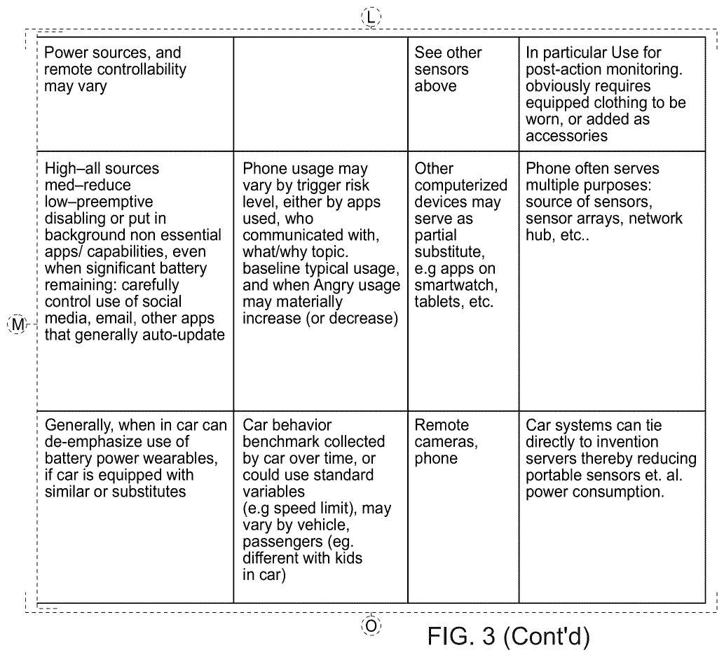

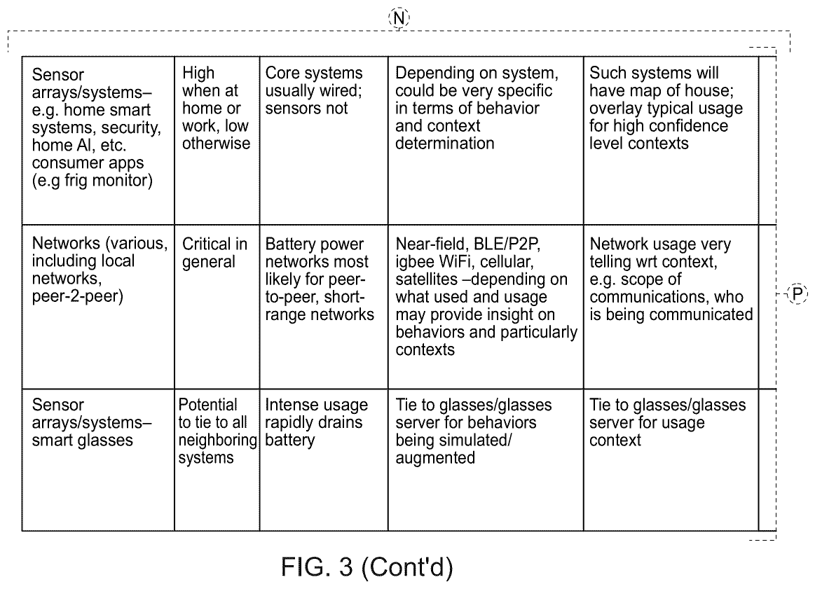

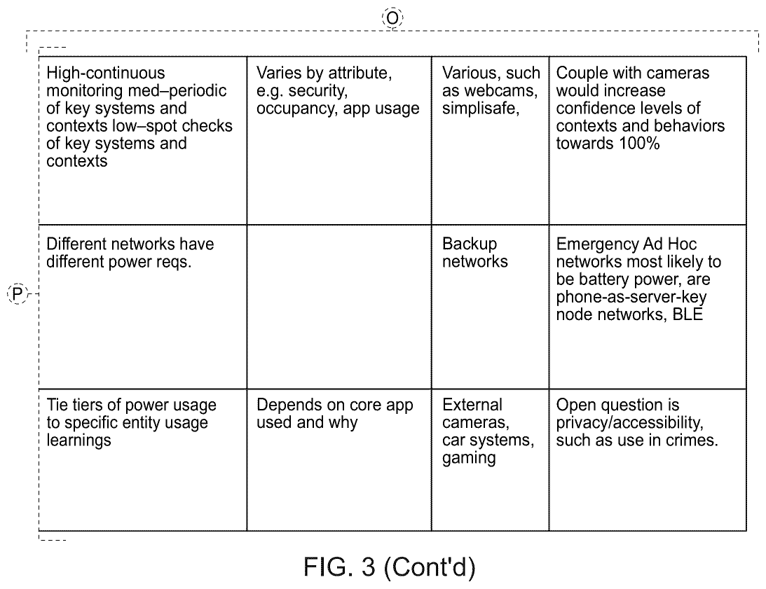

The above chart example for a given sensor/device etc. does not take into account other potentially critical factors, such as the capacity of the component, the current charge, the power “burn” for a given setting(s) for a given component, and the potential for (re) charge in the future. All of these factors can be critical and may be addressed in exemplary embodiments of the present disclosure- and can greatly increase the algorithmic complexity and flexibility needed. See, for example, FIG. 3 that includes a table with examples of power reduction for various sensors etc. for an Anger trigger.

For example, the potential for (re) charge in the future can be extremely important. If for example there is a high likelihood that the component can be recharged in some fashion within the next day and/or immediately after the immediately foreseeable data collection activities, then “in good conscious” the component can be set at its most intensive setting (e.g., used now, at its highest frequency, for its highest duration) for the current/near-term data collection efforts knowing that while it will likely use up most/all of the remaining battery power left to the component, it will be recharged soon.

Unfortunately, it is unlikely that most battery-powered components (except perhaps a person's phone) will frequently be in the position of “highly likely to be recharged in the very near future.” Part of this invention envisions ongoing tracking of recharge stations and even power outlets at or near a location, and making those recharge opportunities as part of the overall analysis of power consumption and recharge opportunities, particularly with respect to context and trigger risk, will be a key capability. For example, if a person has anxiety about their phone going dead on an airplane trip (an increasingly common anxiety-causing concern regardless of context), the invention could proactively alert the user to recharge opportunities from the moment he/she leaves the house to go to the airport to when the person gets on the plan, and even provide information about recharge opportunities on the plane and after landing. This tracking will get increasingly sophisticated as recharging infrastructure is put in place not only for phones but for watches, rings, and even Airtags and similar devices and sensor etc. form factors.

There are multiple ways to encapsulate/categorize the ability for a component to support (or not) highly intensive usage/use cases (note it is possible to have high intensity usage in low intensity use cases and vice versa). One qualitative example could use the following terms (in a sliding scale): Indefinite/Unlimited, e.g., do not have to worry about power for whatever reason (e.g., wired power or certain ability to be immediately recharged), very strong (e.g., large battery capacity, fully recharged at present, easy recharge ability), strong (e.g., reasonable battery capacity, full/nearly full present charge, reasonably likelihood of near-term recharge), medium, low, and scarce (e.g., very limited battery capacity, low present charge, inability to recharge/requires battery replacement/requires component replacement). Note that these terms could be relative to other sensors, etc., to other sensors, etc. of similar types (e.g., Apple AirTags versus Tile batteries, etc.) and/or usage (e.g., small item/person finders) to same component, etc. Additionally, or alternatively, they could be relative to specific use cases, e.g., “strong” relative to Anger behavior and context detection/determination for 2 hours updated every 2 minutes. Additionally, or alternatively, they could be in absolute terms, possibly part of an overall component profile, such as for an Apple AirTag below.

### 1. Battery Capacity

Battery Type: CR2032 lithium coin cell (commonly used in such devices).
Nominal Capacity: ~220 mAh (milliampere-hours).

### 2. Current Power Charge

Current Battery Level: 65% of total capacity.
   Remaining Capacity: 143 mAh (65% of 220 mAh).

### 3. Power Usage per Operation

Idle Mode (No Activity): 5 μA (microamperes)—device in low-energy state, occasionally checking for commands or pings.
Bluetooth Low Energy (BLE) Communication: ~15 μA for passive operations (e.g., occasional updates to the paired phone or network).
Location Update (Using Ultrawide Band or BLE Beacon):
   Typical Consumption: ~8 mAh per location update.
   Includes:
      BLE broadcasting.
      Ultrawideband (UWB) ranging (if applicable).
      Chip activation and processing for a single location broadcast.
Alert Sound Activation (Buzzer): ~1 mAh per 10 seconds of sound emission.

### 4. Estimate of Remaining Operations

With 143 mAh remaining:
   Idle Time: ~1 year (based on typical idle consumption of 5 μA in standby mode).
   Bluetooth Check-ins: Thousands of passive Bluetooth updates (using 15 μA).
   Location Updates: ~17 updates (143 mAh÷8 mAh per update).
   Alert Sounds: ~143 alerts of 10 seconds each.

### 5. Power Consumption Breakdown

Daily Usage Example:
   location updates/day: ~80 mAh per day (8 mAh×10 updates).
   5 buzzer activations (10 seconds each): ~5 mAh (1 mAh×5).
   Passive BLE activity: Negligible (~0.36 mAh/day).

Another aspect of this invention is not only keeping a running “tally” of characterization of the power profile(s) of a given component, such as the qualitative or quantitative examples above, but to do so while minimally using the component itself (e.g., do not use component battery life to determine the component's battery life). Instead, a prediction/projection of the likely battery life is based on historical, current, and likely future usage of the component along with key related parameters such as battery capacity (including maximum current charge capability, not just manufacturer theoretical charge), ability to support various use cases, risk/likelihood of those use cases (particularly high-intensity use cases), recharging ability/likelihood, etc. Those factors could be encapsulated in a variety of ways, including a “strength score” that could be used in determining if/when/how/how long/how frequent the component could be used, and then be “paired” or otherwise associated with a trigger/behavior/context risk level. For example, “Very High” Anger trigger scenarios could use all but “Scarce” power level components.

### Criticality

Even if all power factors for a given use case between components are the same, there are other factors to consider if/how/how much/how often to use a component. In particular, these factors include:
Criticality: Can a trigger, behavior, and/or context determination be done without as current-as-possible/practical reading from this sensor etc.? Cached information, such as last determination/update of contextual element, may work very well (especially if the person is not moving and/or the overal context appears to be relative stable (such as the ballgame Joe is at is in the middle of the 4th inning with his team at bat, making Joe chaning his context significantly in the immediate furture very unlikely.
Replacements: Are there replacements available in general and in practicality? If Joe's context/location data generating sensors etc. are generally low on power, can Jane's sensors etc. or at least a portion of Jane's be used? Typically refers to providing exact same data in different form.
Substitutes: Are there substitutes available in general and in practicality? For example, can Joe's smart ring be used instead of his smart watch? Generally refers to similar data being generated, not necessarily exact.
Proxies: Are “stand ins” for the component? For example, instead of using Joe's phone location (chewing up power with GPS), can Jane's location be used, at least for a certain time period and/or context?
Less Accurate Modes: For example, getting an update on Joe's location doesn't have to use GPS—low power Cell ID could be used. Less accurate but often sufficient for a variety of contextual and behavioral use cases.
Inference—Can a reading from this sensor etc. be inferred, extrapolated, interpolated, or otherwise estimated based on other readings, either from past readings of this sensor, type of sensor, context, or other similar attribute to other scenarios? For example, if it is August in St. Louis, Missouri, and it is 100 degrees and cloudy outside at 4 μm with a storm front approaching, is it necessary to get the most up-to-date humidity sensor reading? Or can it be inferred/estimated (by a part of the system other than the humidity sensor) by using historical information for that date, time, place, current temperature, cloudiness conditions, and projected weather? Odds are very high that given those facts/factors a very good estimate of humidity (to input into an Anger risk determination, for example, e.g., the person exercising/working outside in hot and humid weather raises his/her susceptibility to irriation and anger).

Trigger risk and in turn the appropriate needed intensity of sensors etc. power can vary by many factors. Accordingly, aspects of this invention focus on variations by trigger, behaviors, and/or associated context(s).

Many—even most—triggers will vary by person, even for a specific characterization and usage. For example not all triggers are alike for an addict. Besides having differences in basic impact on the person and other people around the person (such as Anger being more problematic for an addict's children than perhaps Loneliness or Money issues are), the triggers can vary by range of intensity, possible collateral damage (e.g., besides a relapse) and potential solutions/mitigation techniques. Also, for example, besides Anger triggering a relapse, Anger can also contribute to related triggers such as Yelling and Frustration (or Yelling and/or Frustration can lead to Anger) and even violence, whereas Loneliness, by its nature, is less likely to directly impact others. Further, Anger can occur very quickly (e.g., from calm to boiling Anger in 60 seconds), whereas Loneliness by its nature is more likely to occur over a long period of time (e.g., if you are alone for 30 minutes you are less likely to feel lonely than if you are alone for 30 hours). Thus, even if Anger and Loneliness both can be a major trigger for a substance abuse relapse, their collateral impact and other factors such as speed with which they can occur/escalate can be very different, and thus the associated sensors etc. power management “strategy” for that trigger can be very different.

Further, the associated responses—ranging for example from mitigation techniques to alerts to support resources employed to user interfaces used—may vary greatly from one trigger to the next. Anger again is an example of whereas much detail about an escalating Anger risk (for example) may be required to appropriately inform the various engines assessing responses to the risk. A rapidly risking Anger risk may necessitate (from a common sense if not actual risk mitigation standpoint) an alert to the addict's ex-wife (particularly if there are restraining orders or history of domestic violence). Such alerts should not be made lightly, e.g., alerts should be done with as high a confidence level as possible to prevent (potentially catastrophic) false alarms. To avoid false alarms (and worse, miss actual “bad” events) for some people, detecting/determining Anger/Anger risk can “justify” a maximum intensity sensor etc. data collection, processing, and reporting effort (“reporting” encompassing potentially any interaction with other persons, resources, systems, objects, etc., with data collection, processing, and/or reporting being “data effort”). Even for those “high overall impact” triggers, the context(s) involved can matter greatly as to the sensors etc. data effort.

For the example Anger trigger ex-wife scenario above, what the person is doing, when, and how (e.g., examples of context) as well as where (location) associated with the entity with the trigger (such as addict, parolee, quarantine, etc. (“addict” or “parolee” for example)) can make a major difference in data efforts. For example, if the addict is on an airplane going direct from New York to Los Angeles, when an Anger risk spikes (for example, the attendant refuses more alcoholic drinks), the potential collateral impact on other people (excepting other people on the plane) is minimal if the ex-wife etc. is currently at work in Kansas City. Thus, data efforts during the time the addict is “trapped” traveling may be minimized (or at least delayed) versus if the plane trip was from New York to Kansas City. In the latter case, the data efforts would not only not be minimal, but the data efforts would probably be maximized given the destination of the travel is unlikely to be a coincidence.

### Confidence Level

Patents and patent applications listed above in the Cross-Reference to Related Applications section (and incorporated by reference herein) disclose utilizing a risk confidence level as part of the determination/assessment as to whether, and/or to what degree, a trigger risk event or possibility is or might be occurring. Such risk confidence levels can also be a factor in the sensors etc. power management in a variety of ways.

In a simple example, a risk determination engine, in considering and assessing a variety of triggers, behaviors, and contextual factors using sensors etc. data and other factors, could determine there is a low risk of an Anger event occurring. That low risk determination could directly result in a “low” power mode being used for Anger-related sensors etc. But the risk determination engine could also indicate that the risk is contingent upon the context not changing and particularly not changing in a certain way. Accordingly, exemplary embodiments of the invention recognize such contingencies and adapts the sensors etc. to focus on detection of such contextual changes, particularly as they would relate to those changes “feared” by the risk determination engine.

For example, an addict's worry about Money troubles, and its related triggers of Frustration, Anxiety, and even Anger could be viewed as low when the addict is at home after just being paid. But past experience as tracked by the systems/methods of the invention would know that every time the addict goes out to dinner, particularly with his family (when it is expected the addict would have to pay), the addict's pre-occupation with Money and associated feelings (triggers) of Anxiety and Frustration have a tendency to spike (as detected by various configurations of sensors etc.), as does Anger when the addict feels that he is being forced into the dinner. Instead of configuring/calibrating the sensors etc. to detect various levels of Anxiety, Frustration, and/or Anger (many of which have battery-powered personal sensors etc. such as blood pressure and temperature monitoring watches or rings as part of its “strong” detection power management scheme), exemplary embodiments of the invention instead may focus on just detecting any plans of going out to dinner. This could be done just by monitoring the addict's home Alexa device for “going out” or “dinner” or various favorite restaurant names as an early warning detection of the possibility of going out to dinner. Such use of one of those terms could then activate sensors etc. related to car usage for example. If such car use is detected, then there could be a switch or ramp up to other sensors etc. power configurations, including for example polling the addict's blood pressure and/or temperature monitoring watch or ring to see if those values are rising, and how fast, and in terms how the in-process-of-changing context is affecting his Money, Anxiety, Frustration, and/or Anger risk levels. When those risk level(s) reach a certain point, then the system can increase the strength of the power monitoring across all personal and contextual components to maximize data collection for all factors as well as confidence level accuracy. Via this process and system, the power used may be appropriately calibrated for a given risk level and other power configurations may also be appropriately employed, including preemptively, to detect key changes without having to go “all in” on all the potential sensors etc. for those triggers and contexts.

### Behaviors

As the ability to collect data of/from various sensors, sensor arrays, devices, systems, and networks (“sensors”) for varying, increasingly complex use cases become more prevalent, so does the need to appropriately calibrate, and even ration, the power consumed by these mechanisms, particularly mobile mechanisms using battery power.

There are numerous power management methods and mechanisms employed today for electronic devices including:
Sleep Modes—e.g., sensors etc. entering a low-power, idle state, or greatly reduced frequency use when not actively in use, thus conserving energy by turning off or reducing power to various components).
Less Accurate Modes—e.g., for some sensor etc. measurements, such as for some location determination, there is a correlation between greater power consumption and increased accuracy.
Duty Cycling—Alternating between active and inactive (sleep) states at set intervals or based on certain conditions.
Power Gating—Selectively powering off certain components or circuits within a device when they're not needed.
Dynamic Voltage and Frequency Scaling (DVFS)—Adjusting the voltage and frequency of a device's processor based on current workload demands).
Energy Harvesting—Using alternative power sources, such as solar, thermal, or vibration energy, to recharge or supplement the battery.
Low-Power Wireless Communication Protocols—Optimizing communication protocols (like Bluetooth Low Energy, Zigbee, LoRa, and NB-IoT) to minimize power usage during data transmission.
Event-Triggered Power Management—Using sensors or other triggers to activate the device only when certain events or thresholds are detected (e.g., motion or temperature change).
Battery Management Systems (BMS)—Systems that monitor battery health, voltage, and charge/discharge cycles to optimize performance and longevity.
Adaptive Power Scaling—Dynamically adjusting power allocation based on real-time needs and usage patterns.
Low-Power Components and Circuit Design—Using energy-efficient components and designing circuits that consume minimal power.

These techniques are mostly commonly used individually, sometimes in pairs, and/or are generally applicable to whole class of sensors. For example (for the latter), small sensors with batteries typically have as a basic design requirement using low-power components and designing circuits. For the former (energy harvesting), these devices typically have to have dedicated or readily available connections to be able to harvest the power, like solar panels, or (for electric vehicles) using various driving use cases to recharge the battery during use.

Historically, mobile device power management has been a mix of using low-power wireless communications protocols, sleep modes and duty cycling (which tend to be included in such protocols, like Bluetooth Low Energy), and in particular event-triggered power management. In such event-based systems related to location, the baseline/default usage would do a location determination only periodically and in long intervals (e.g., 15 minutes or much longer, or in the case of tracking/navigation-type apps every 2 minutes or so), then, upon detection of movement (typically via motion sensor, but can be done “the hard way” by comparing the locations between 2 consecutive location data points to see if movement occurred), greatly increasing the frequency of location data collection, say to every 5 seconds or so (depending on the application), until lack of movement is detected. Adaptive power scaling is a more specialized version of such event-based systems.

Historically, these methods have worked reasonably well, as most use cases, especially mobile device/battery powered ones), are typically not designed for active, intensive, (near) full-time usage. Exceptions that require near continual, frequent tracking, like GPS ankle bracelets for parolees, try to compensate for this requirement by having large, lithium-type batteries, as well as various procedures and incentives that parolees are required to follow to ensure the battery never dies (like, if your device dies, you will go back to jail). But what these power management techniques lack is adaptation to a person's context, particularly with respect to particular behaviors and especially particularly with respect to avoiding “bad” behaviors that can vary by trigger and context.

There are a variety of methods, systems, and apparatus (“capabilities”) enabled by exemplary embodiments of this invention for managing power across components, sensors, sensor arrays, devices, systems, and networks (“components”). One way to characterize these capabilities is to group them as to whether one or more of the sensors etc. is involved in some form in one or more of the following stages or steps including data generation, data collection, and data processing.

Data generation refers to the core activity(ies) associated with a particular sensor etc. Often (but not always) refers to the “raw data” purpose of the sensor et. al. For example, a location sensor/device could generate a latitude and longitude for a given device/person at a given date and time. Later processing could result in that latitude/longitude being translated to a street address.

There are various ways to decrease power consumption from a sensor etc. data collection depending on context. For example, if there are no indications that a sensor etc. context has somehow changed, such as a motion sensor activation, then there may be little need to update a location (and in the process use more power to do for example than a GPS location update or especially a Cell ID-based location update). Instead, the last known location could be used (potentially available in a memory cache). Another way is to look at historical location information for certain contexts, such as (via a server) looking at historical location and location changes at 10 am on Wednesdays during non-holiday work weeks when no meetings are scheduled on the person's calendar. If the last known location (say at 9 am) shows the person in his office on a workday Wednesday,

Regarding the impact on power usage, battery powered components will be a significant part of sensors etc. Decreases in power usage can include not using a sensor etc., reducing its frequency of use, reducing its scope of use, reducing its accuracy, and using substitutes or alternatives. Data can be cached and/or batched. And transmission amounts and frequency can be reduced.

Data collection refers to the collection of sensors etc. data/values that are used for detection/determination of behavior, triggers, context, and/or context and location. For example, one or more wrist device body temperature sensor readings are data element(s) that can be collected. Different alternatives and/or substitutes for certain kinds of data can be used, as can certain combinations of different sensors etc. collection take the place of higher volumes (and power use) of data from one/one set of sensors etc. to optimize for behavior prediction and action, the system prioritizes data with high utility for risk assessment while minimizing power draw. Further, local data collection, such as sending information from sensors in watches to phones can be reduced in amount and/or frequency, and communications protocols such as BLE can be used, including their low(est) power modes, to further reduce communications-related battery drain on sensor, sensor form factor (e.g., watch), and paired device (e.g., phone), as well as of course any data sent from phone to (other) edge computing devices, servers, etc.

Modifying (including adding and deleting) data collection can be done in a variety of ways via the invention. Individual sensors etc. can be added or deleted, and/or their configuration modified to, for example, change how frequently the data is collected. Combinations of individual sensors etc. can also be changed.

Data processing refers to the processing of collected data, for a variety of purposes including information/other data creation, measurement, and/or determination. For example, formulating a trend or average value for a given time period of a person's body temperature would be an example of processed data. Such processing could be done for example on the wrist device, phone, edge computing device, local server, remote server, etc. It can even be done on other people's devices, such as phones, in the form of crowdsourced distributed processing of data. Depending on the sensors etc. and where the processing is done (and how), delaying, reducing, batching, or otherwise curtailing and/or utilizing more efficient forms of processing can reduce power consumption of the various sensors etc.

### Data Usage

Data usage includes data reporting, action formulation, action implementation, action monitoring, and learning.

In exemplary embodiments, data reporting covers a broad range of communications about, from, and/or to entities and/or system components such as agents, engines, and user interfaces, including but not limited to status updates, notifications, alerts, and action-related communications. The behavioral modification nature of exemplary embodiments of the invention disclosed herein and the inventions disclosed the patents and patent applications listed above in the Cross-Reference to Related Application section (and incorporated by reference herein) have as a key part extensive use of various forms of status updates, notifications, alerts, and other communications between entities and/or systems for a variety of purposes. Nearly all of these take power with the exception of a dead man's communications, e.g., the absence of communications is in itself a form of communications such as if I do not call by 9 μm contact the police. Indeed, this is an alternative/substitute possible for some forms of the use of this invention and related inventions. Thus, curtailing these communications, either in occurrence (at all), frequency, form, and/or volume are ways of reducing power consumption depending on sensors etc., triggers, behaviors, and/or contexts. Also, the interfaces used (particularly user interfaces) can greatly impact power consumption of some devices. As an example, a graphical map showing a support person's position relative to an addict at risk of relapse can be more power consuming than just a text to the support person about where the addict is.

Detecting/determining/predicting high risk of trigger activations and associated consequences (e.g., substance (ab) use, parole violation, quarantine violation, or just general stopping “bad” behavior) is using the above data collection, processing, and reporting is only one part of this invention and related family-preempting, or at least mitigating, trigger risks. Another key part is action formulation, which may be based on current, historical, and/or predicted trigger risk(s), behavior(s), and associated context(s), as well as information about the impact (or lack thereof) of various action(s) related to the entity(ies) involved and/or trigger(s), behavior(s), and associated context(s) or context(s) and location(s) (“context(s)/location(s)”), action(s) of various forms, including but not limited to action(s) recommended or implemented electronically via the entity(ies) sensors etc. and/or 3^{rd} party systems, as well as user interface(s) and/or involving support resources and/or associated capabilities, to reduce the trigger risk in some form or, if “bad behavior” has actually started, mitigating that bad behavior such that it ends, diminishes, and/or its impact on the entity(ies) and/or associated “collateral” (e.g., family, friends, acquaintances, coworkers, followers, or in general some potentially affected party(s).

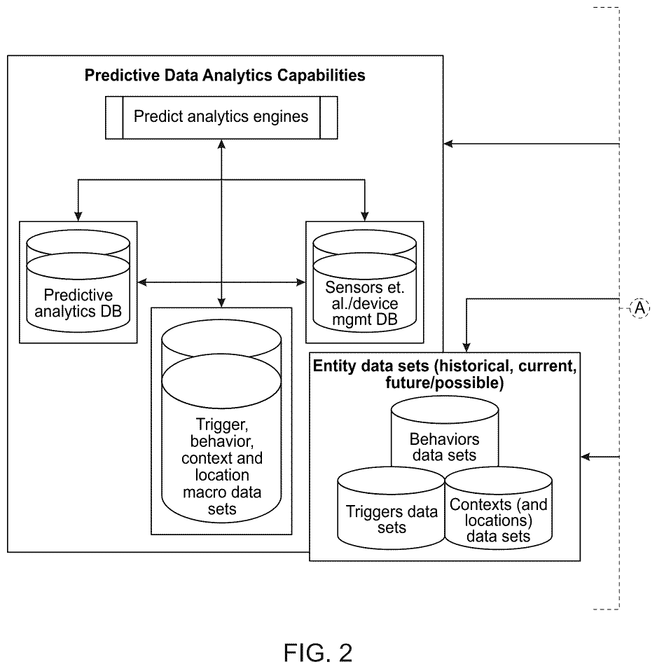

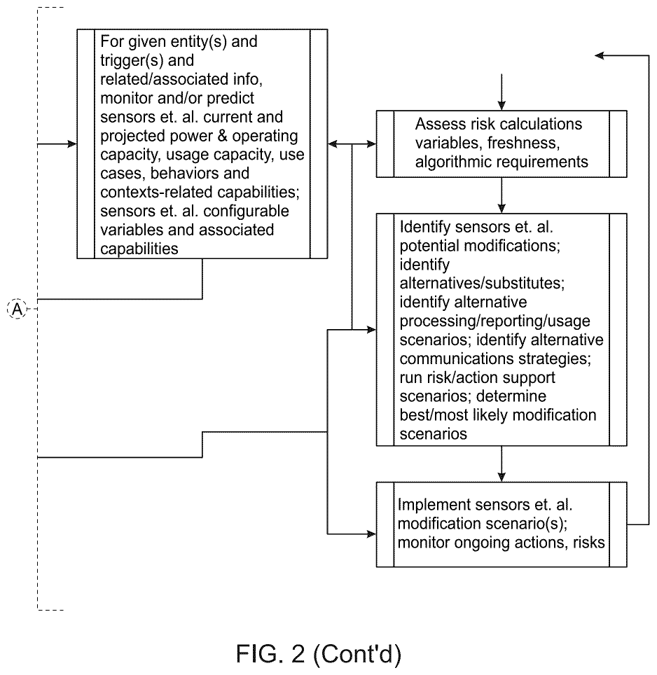

Regarding the impact on power usage, action formulation will often (but not always) be formulated using powered sensors etc. For example, networks between sensors, arrays, devices, etc. and systems, etc. that do actual formulation may be down thereby necessitating more local formulation efforts. In addition, many aspects of this invention are extremely power intensive especially those designs utilizing artificial intelligence (AI)/machine learning (ML). Reducing the scope of data set utilization and associated processing (e.g., data cleaning, etc.) is a power reduction strategy here, potentially aided by the use of motivation/morals/ethics compasses, as well as reduced and/or more targeted utilization of various processing engines, such as shown in FIG. 2. In the process of formulating various possible actions, the latest data from at least a subset of sensor e.g., will be needed in the formulation of possible actions and assessment of their potential impact. A simple example is location. It may not be the most effective possible action to formulate an action that relies on a certain location, only for that location to have changed between when the risk was identified and when the action is formulated, or implemented (e.g., it may take some time between action formulation and action implementation. For example, if an action is predicated on in person support for an addict at the risk of relapse, the action's potential effectiveness will need to take into account that it may be 20 minutes before the support person can meet up with the addict, in a context/location

After action(s) are formulated, the actions must be implemented. This will nearly always involve significant communications to various people, processes, things, and associated sensors etc. Generally, while the actions to pre-empt/mitigate undesirable behavior will need to be done expeditiously, that does not mean they all have to be done immediately. For example, if power usage is charged at demand/peak rates at certain times, it may make sense in some implementations or portions thereof to delay and/or scale back communications instead of assuming the default of some for all communications, as intensive as possible, in high volumes, as soon as possible.

Action monitoring (e.g., determining if and to what degree the action(s) formulated and implemented to for example preempt/mitigate certain behaviors/contexts to avoid trigger(s) activations) will usually require additional data collection and processing from sensors etc. A power reduction strategy may include having maximum data collected/processed immediately after action implementation. Then, as risk is reduced (e.g., actions are shown effective) reducing monitoring as expeditiously as practical.

As noted above, Machine Learning (ML) and more broadly Artificial Intelligence (AI), can be extremely power consuming. As such, ML/AI is ideally powered by wired/non-battery sources, or at a minimum battery sources that can be readily recharged. But that may not always be possible, for example in remote mobile environments without ready easy-to-use power sources. While learning aspects of this invention and related inventions is an important element of the inventions' success, the nature of at least some learnings is not only do they not have to be done real time but they can be delayed for substantial periods of time depending particularly on triggers, behaviors, and contexts.

For all of these categories, there are other factors that influence power usage, such as confidence level. For many embodiments, more data, more often, as recently as possible, as accurate as possible is the nirvana in terms of subsequent confidence in the data sets being used and the associated processing, actions, etc. This can take numerous forms, but one form is assessing the confidence level of the accuracy and/or effectiveness of a data element or set. Some or all of the categories above can be calibrated or otherwise tied to the use of various confidence levels, with (generally speaking) the higher the confidence level for a trigger/behavior/context data set for example, the more power that would be expected to be consumed throughout the generation/collection/processing/data usage processes.

Exemplary embodiments may include an individual analysis engine/construct for each trigger and a related trigger(s) analysis engine. For example, a system may include an Anger Trigger Analysis Engine, a Related Triggers Analysis Engine, and/or a Motivations Analysis Engine that may influence other engine(s). Other example trigger analysis engines include a Substance (Ab) Use Inference Engine, a Motivation (Dis) Incentive Analysis Engine, a Support Resource Management Engine, a Contextual Analysis Engine, a Risk Determination Engine, an Action/Support Resources/User Interface (UI) Engine, a Learning Engine, etc.

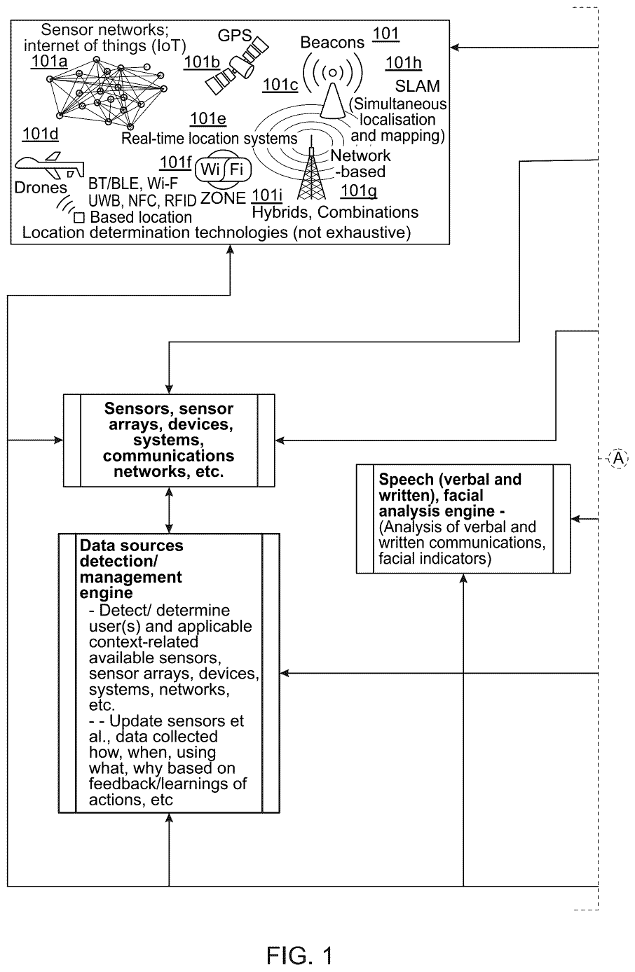

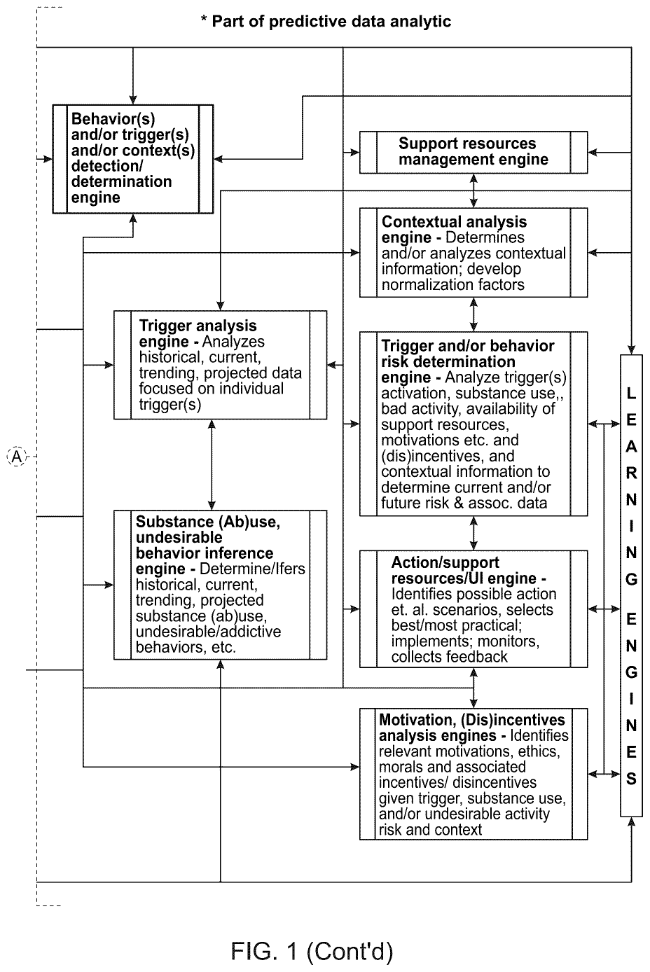

For example, FIG. 1 illustrates an example system according to an exemplary embodiment including sensors, sensor arrays, devices, systems, communication networks, etc. that are in communication with (e.g., a mesh network, etc.) multiple engines and multiple location determination technologies or sources 101. The multiple engines may include, but are not limited to, a Data Source(s) Detection/Management Engine, a Speech (verbal and written), Facial Analysis Engine, a Behavior(s) and/or Trigger(s) and/or Context(s) Detection/Determination Engine, a Trigger Analysis Engine, a Substance (Ab) Use Inference Engine, a Motivation (Dis) Incentive Analysis Engine, a Support Resource Management Engine, a Contextual Analysis Engine, a Trigger and/or Behavior Risk Determination Engine, an Action/Support Resources/User Interface (UI) Engine, and one or more Learning Engines. In the exemplary embodiment shown in FIG. 1, arrows generally indicate that the sensors, sensor arrays, devices, systems, communication networks, etc. are in direct communication with the engines and also with the multiple location determination technologies or sources 101. Arrows also generally indicates that the engines are in direct communication with each other engine and that the engines are in direct communication with multiple location determination technologies or sources 101. Alternative embodiments may be configured differently, e.g., without direct communication and/or with indirect communication between one or more of the engines, one or more of the sensors, sensor arrays, devices, systems, communication networks, etc. and/or one or more of the multiple location determination technologies or sources 101, etc.

As shown in FIG. 1, the Data Source(s) Detection/Management Engine may be configured to be operable to detect/determine user(s) and applicable context-related available sensors, sensor arrays, devices, systems, networks, etc. The Data Source(s) Detection/Management Engine may also be configured to update sensors etc., data collected, how, when, using what, why based on feedback/learnings of actions, etc. The Speech (verbal and written), Facial Analysis Engine may be configured to be operable for analysis of verbal and written communications and facial indicators. The Trigger Analysis Engine may be configured to be operable to analyze historical, current, trending, projected data focused on individual trigger(s). The Substance (Ab) Use Inference Engine may be configured to be operable to determine/infer historical, current, trending, projected substance (ab) use, undesirable/addictive behaviors, etc. The Motivation (Dis) Incentive Analysis Engine may be configured to be operable to identify relevant motivations, ethics, morals and associated incentives/disincentives given trigger, substance use, and/or undesirable activity risk and context. The Contextual Analysis Engine may be configured to be operable to determine and/or analyze contextual information and/or to develop normalization factors. The Trigger and/or Behavior Risk Determination Engine may be configured to be operable to analyze trigger(s) activation, substance use, bad activity, availability of support resources, motivations, etc. and (dis) incentives, and contextual Information to determine current and/or future risk and associated data. The Action/Support Resources/User Interface (UI) Engine may be configured to be operable to identify possible action et. al. scenarios, select best/most practical, implement, monitor, and collect feedback.

As further shown in FIG. 1, the multiple location determination technologies or sources 101 may include, but are not limited to, sensor networks (e.g., Internet of Things (IoT) 101a, etc.), GPS/Assisted GPS 101b, cell tower identification 101g, cell tower triangulation (TDOA, AFLT), beacons 101c, Radio Frequency fingerprinting, Real-Time Location Services (RTLS) 101e, Wi-Fi based location systems 101f, Radio Frequency Identification (RFID) based location systems and similar systems, drones 101d, crowdsourcing, hybrids 101i, simultaneous localization and mapping (SLAM) 101h, and/or combinations of these or other location determination systems. These location determination systems may be on, worn or carried by, used by, embedded in, or nearby of an addict(s), other person(s), entity(ies), and/or group(s) to determine approximate location.

FIG. 2 illustrates an example system according to an exemplary embodiment in process for achieving power savings. For all of the categories shown in FIG. 2, there are at least some exemplary embodiments that would include, at least in part, reduction of power needed and/or used by their components/component parts due to decreased (or no) usage of memory, storage, processor(s) and/or controllers, communications (with other components or even internal to a component), peripherals and accessories, motherboards and chipsets, cooling and/or power supply systems, e.g., less power consumed by components necessitates less power used by the actual power supply (including batteries) as well as cooling capabilities (e.g., less power generated/consumed means less need to dissipate heat from that power generation/usage). More specifically as related to this invention, these would involve various permutations of sensors etc. and their usage in relation to specifics related to an entity(ies) trigger(s), behavior(s), and context(s).

FIG. 3 includes a table with examples of power reduction for various sensors etc. for an Anger trigger. Such power reduction strategies will likely vary, perhaps greatly, depending on specifics of entity/person involved, the available sensors etc., and by triggers, behaviors and contexts.

Configuring these various sensors etc., including their various components/component parts can be done. Other considerations includes that recharging (over time) often reduces life of battery and generation/power sourcing. A longer term factor is the practical reality that the more a battery is used, the less effective the battery becomes over time, particularly what the maximum charge possible is relative to its just-from-the-factory 100% charge. There are ways of recharging without effectively not using the sensors etc., such as using a phone while it is plugged in as a simple example. But there are other ways emerging, such as use of portable chargers that can be magnetically attached to a device while only mildly inhibiting its ability to be used.

A related set of embodiments involves the data generation, collection, and processing of initial data sets involving an entity such as individual with a drinking problem triggered by Anger, with key related triggers of Frustration and Noise. Some, even many, individuals with Anger and/or substance use problems may have a good idea of what causes them to drink and/or get angry, but there may be little information about the upstream behaviors that might lead to Anger and/or substance use, nor may there be little to no information about associated contexts where upstream behaviors may occur. In other cases there may not be any information on triggers, or at least useable information (e.g., “stress” might be viewed as trigger, but more information is needed). Relying on data obtained in “normal everyday living” will likely take weeks or even months—a major commercial practicality problem (e.g., no one wants to wait months for their behavioral modification purchase to start to become effective-they want it NOW).

Instead, as much data about the entity's triggers, behaviors, and contexts (or contexts and locations) will need to be developed as quickly as possible. This will require data to be generated/collected/processed from numerous sources and/or via numerous methods and techniques, including historical, current, real-time, and predicted/future:
Contact info (For “Who” and “How” (contactable)
Schedule (historical, current, and future contextual, behavior information)
Car systems/application
Home systems/applications (including access to Siri/Alexis capabilities)
Google (searches, Timeline, etc.), on all devices and systems (home and portable/mobile)

In many respects, the above information is very similar to the data/information collected in criminal forensics investigations, such as assaults or homicides, or requirements for parole. An example of parole conditions is seen below:
Graham was known to also be active to federal probation (case 4:16-cr-00538-JSW). A query of federal probation records indicated the Special Conditions of Graham's supervised release included the requirement that Graham submit to a search of his person, residence, office, vehicle, electronic devices and their data, and any property under his control by any law enforcement officer, with or without suspicion. Graham advised SA Carlson that he did not have a cellular telephone. SA Carlson then obtained Graham's cellular telephone number from US Probation, which was 510-899-0299 and called the number. A cellular telephone on a stool next to the couch in the living room began ringing. Graham then responded that this was not his cellular telephone, “but he used it.”

Indeed, the above is indicative of the extensive nature of the data that needs to be collected, at least in some circumstances: not just personal to the entity, but extending to all the other possible contextual elements in the entity's life: who the entity interacts with, how, about what, when, and why, as well as location (where).

Reflecting the sensitive nature of such data, great lengths should be taken to protect—both privacy and security==such information, starting with (in most cases) the entity whose data is collected having the first level of control over if, what, and how such data is collected, and for what and how it is used. Also, such data should be heavily encrypted and/or otherwise have top quality cybersecurity mechanisms applied to such data. Patent(s) and patent application(s) listed above in the Cross-Reference to Related Applications section (and incorporated herein) disclose examples of such privacy and security protections.

In use cases envisions in the various patents and patent applications listed above in the Cross-Reference to Related Application section (and incorporated by reference herein), conventional power management techniques that have historically been used may be insufficient. Use case categories (e.g., addiction monitoring, parolee tracking, quarantine management, digital warfare, etc.) may require the possibility of near 24/7 usage or at least 24/7 potential to be used. Further, some individual use cases, such as the Anger trigger, tend to not happen very often, but when they do they escalate very rapidly, and the window for mitigating such incidents tends to be very narrow time-wise. Further, such trigger events are not simple, such as in-motion yes/no, but instead require multiple sensors/values to calculate/estimate/determine if, when, and to what degree the trigger is occurring. Adding to the mix is that most trigger detection mechanisms are highly customized and can even vary (often greatly) by the context involved. For example, if ambient temperature is a contributor to say the Anger trigger (e.g., the person is more likely to get mad when they are overheated), the need to collect ambient and personal body temperature may vary greatly if they are outside sitting in the hot sun at a ball game. There is thus a need for much more dynamic, personalized power management than exists today. In addition, there exists fundamentally conflicting requirements of 1) trying to conserve battery power in sensor usage, while 2) simultaneously needing to collect as much information as possible to detect trigger events as soon as they start to occur or even before. In addition, many sensors may be in forms/form factors such that any appreciable usage and/or increase in frequency/intensity of use may rapidly consume battery power such that they quickly become depleted before or while they are most needed to address a high-risk trigger event.

As recognized herein, there is thus a need to dynamically adjust the power configurations of sensors etc. used or potentially used in the collection, processing, and use of sensor data used in context and behavior determination-past, present, and future-using prediction capabilities about those triggers, behaviors, and contexts to maximize or at least improve the likelihood that power for sensors etc. will be available when it is most needed especially in already-triggered or high-risk (and increasing) trigger situations.

Utilizing location-based events (e.g., entering or leaving a geofence) to adjust sensor settings may include location-only power adjustments that have the (significant) potential for “misreading” the power requirements.

A prerequisite to most common trigger-related power management scenarios is in understanding the “portfolio” of possible sensors etc. that may be employed in collecting, processing, and utilizing trigger, behavior, and associated context or context/location information. To begin with, this requires a robust understanding of the devices and systems an entity has at his/her disposal such as what kind and of what sensors can the entity's phone connect to or deploy itself within the confines of the phone. But other devices will be needed or even required for certain types of use cases, e.g., for entities with substance (ab) use issues or on parole. Aspects of this invention address this.

The term “calibration” in this invention is used more broadly than is traditionally used in electronics, e.g., to adjust a piece of electronic equipment to make sure the electronic equipment is accurately reflecting what it is sensing, such as calibrating a scale to read zero when there is no weight on it. Instead, calibration as used herein includes adjusting the selection of, frequency of data collection of, metrics and/or ranges of values associated with and/or being measured for, the sensors etc. involved or potentially involved in the uses, use cases, operating, planning for, or otherwise involving location, context, triggers, and/or behaviors. Similarly, configuration or adjusting of settings of sensors etc. not only includes adding/changing/deleting individual settings on or in sensors etc., but it also includes involving all the sensors, sensor arrays, devices, systems, and/or networks as well as associated applications potentially and/or actively using such sensors etc.

While many methods are based on “demand,” and “when needed,” anticipating, predicting, or forecasting demand can be problematic. In contrast to a utility knowing that it is going to be 105 degrees tomorrow afternoon with a predictable temperature ramp up and downs and planning their power generation for their 100,000 customers accordingly, other uses/uses cases are much less predictable. For example, use cases that use a wide variety of mobile devices, sensors, sensor arrays, systems, and networks, (“sensors”) and are targeted to an individual potential usage of those sensors in a wide variety of, often unpredictable behaviors and associated contexts. Further, some use cases for a given individual can be vastly different between sensors, behaviors, contexts, and individuals. Even more problematic, the ability to recharge these sensors can be logistically difficult (even sometimes requiring battery replacement), as well as problematic with respect to the availability and motivation of an individual to recharge such sensors, e.g., GPS Ankle Bracelet tracking for parolees as disclosed in patents and patent applications listed above in the Cross-Reference to Related Application section (and incorporated by reference herein).

Disclosed herein are exemplary systems and methods focused on future power management, and particularly on the use of triggers, behaviors, and contexts for dynamic power management based on triggers, behaviors, and contexts. Exemplary embodiments may include changing power configurations in sensors etc. (e.g., sensors, sensor arrays, devices, systems, networks, and/or component(s) thereof, etc.) based on a trigger(s) that the system/method is focused on is asynchronous and/or distinct from actual power usage by sensors etc. When focused on sensors etc. for a trigger(s), the interest or focus is high potential (e.g., high risk) context(s) coupled with trigger(s), as well as behaviors.

As an example, consider a context of it being a hot day. Combine with further context and behavior of coming home from work, and there is a system used to proactively turn on A/C when you come within a certain geofence distance of your home. It would know based on past experience that 76 degrees is a preferred temperature when you are at work, but 72 degrees when at home. The system then changes the AC accordingly. But unlike this conventional geofencing system, exemplary embodiments disclosed herein are configured to look at much more detailed (or different) contexts of what you are doing around the house (once you get home). Instead of a “triggerless” use case such as the coming home/A/C change above, exemplary embodiments disclosed herein are configured to focus on triggers, specifically preempting trigger “activation” (such as Anger), and for that focus on to what degree/how your various behavior(s) and associated context(s) (such as cutting the grass behavior in the context of being outside at 2 μm in West Texas in August using exercise-intensive machinery) could have on your Anger trigger, which is known to get increasingly at risk the hotter you get, as well as related trigger of Frustration when the lawnmower keeps stalling and your wife keeps asking you when you are going to get done so you can go to the ballgame (see elaborate use case described herein). Nor does art take into considerations other behaviors/contexts that occurred before the grass cutting use case that may raise or lower Anger risk (even before you start cutting the grass), such as you having a good night's sleep in bed before you cut the grass (behavior being good sleep/context being sleeping and in your own bed-lowering Anger risks for contexts and behaviors that occur within the next say 4 hours, or however long a good mood from good sleep lasts for you), or you got into a fight with your wife about cutting the grass (behavior/context that increases Anger risk). So, given these very different behavior/contexts) about which you may have little to no real historical information about its impact on the anger trigger other than general guidance about not liking being hot (or at least having a shorter fuse when hot) you like cutting grass OK as long as it's not hot and/or there are no lawnmower mechanical issues, and fighting with your wife may possibly elevate anger risk, but it could also not depending on topic and context, and how good a mood you were before the hot grass cutting and argument with your wife, an exemplary system disclosed herein may be configured to make different decisions about sensor etc. operational usage/power usage, such as not collecting temperature and blood pressure data through your (battery powered) personal devices while you are cutting the grass, or perhaps just one when its detected you have come back inside and presumably stopped cutting grass versus collecting a lot of Anger behavior-related data (like body temperature, blood pressure, and doing speech analysis of any conversation/yelling you might be having with your wife) after the grass-cutting and/or fight with your wife, e.g., you are upset having to cut the grass just before you have to pick up your in-laws and go to a ballgame that you do not want to go to for a variety of reasons (see ballgame use case described herein).

An Anger cup or glass analysis may provide further illustration. For example, you may finally be triggered (e.g., start drinking) when the liquid in the glass goes over the top. You generally have some amount of liquid in the glass at all times, from life's general stress and issues. But you start the day generally half full (and perhaps ¾ full if you got a bad night sleep), then other stressful events and issues start to happen, filling the Anger glass closer and closer to the top. Generally speaking, the closer to the top of the Anger glass you get (with the increasing volume being a direct analogy to risk level, and the rim of the glass being the activation threshold/level), the more and more frequently you will want to use sensors etc. to keep an eye on the risk level particularly if there are different action thresholds that are themselves “activated.” For example, when the Anger class is three-fourths full, gentle texts may be sent to you to calm down and perhaps start polling nearby/context-worthy support resources (e.g., for a fight with your girlfriend bring in your best friend, with your sister bring in your Mom) regarding availability. When the Anger glass is seven-eighths full, start the process of alerting the support resource and suggesting potential actions (e.g., you are at Starbucks on 34^{th} street-you (friend) can be there in 20 minutes based on where you are now). When the Anger glass is nine-tenths full (particularly if the filling up is occurring fast), start preemptively preparing 3^{rd} party interface actions, e.g., sending alerts to key support context-worthy resources, disabling car ignitions, alerting ex-wife, etc. As these various actions are undertaken, the system continues to monitor their impact (via frequent use of sensors etc.). If the Anger glass level stabilizes (and in particular if it starts to drop), then the system can potentially “stand down” the most intensive use/frequency of sensors etc. except for potentially leading edge/early warning sign measurements (varies by person/context, but for example body temperature is a good one).

Conversely, when your Anger glass is literally half full and there is no likelihood of a sudden “glass-filling event” on the horizon (e.g., a meeting with your boss in 2 hours to talk about your job performance), then the system can “stand down” the sensors etc. usage to some relatively minimal level, e.g., perhaps a location check every 20 minutes compared with known contexts with that location coupled with a temperature check every hour, which would provide the necessary “checking in” functionality of what's going on in your life with minimal sensors etc. power usage. With the boss meeting scenario noted above, the sensors etc. usage may be increased to maximum during the meeting, then if the Anger risk is still low (glass say only five-eighths full), the sensor etc. usage may be ramped back down. Also, note that a single location can be coupled with numerous contexts. For example, “being at 123 main street” might mean you are home, it does not provide truly meaningful context information, like you are taking care of your kids while working from home, working out in home gym, cutting grass, etc.

One way of reducing power consumption is instead of focusing fully on both context (and location) and behaviors, focus on either one or the other, or “a little” of both. Monitoring your schedule (which may be easily done using only phone power) would be a good way of doing low power context monitoring, perhaps supplemented with strategic use of location to see if/where/when “bad” locations may indicate a change in schedule or a schedule event context that is not going to be in a “safe space.” Alternatively, the focus may instead be on behavior, specifically phone Siri monitoring for profanity, or the car's telematics systems to monitor for bad driving (e.g., speeding, sudden acceleration, harsh braking are relatively easily obtained elements) with the added benefit that by just detecting the car's ignition there is immediately new information on context (and behavior to some degree, e.g., you are going somewhere) without using any wearable battery-powered sensors, etc.

As recognized herein, aspects of the present invention focus on “wired” power consumption, e.g., where you supposedly do not have to worry about sensors etc. running out of power. But as seen with all AI data centers and associated power needs, AI—if left to its own devices—can consume huge amounts of power. Accordingly, it would be advantageous to have a way to manage wired power consumption and in turn, the power generation that will be needed.

While aspects of the present invention focus on managing power needs associated with battery-powers sensors etc., the present invention is not so limited. Exemplary embodiments disclosed herein can enable better power management for any and all types of power consumption, including that powered by “wired” power sources and other power sources that have if not a continuous supply or at least a reliable (re) supply.

With the advent of Artificial Intelligence (AI) and Machine Learning (ML), one only needs to take a look at the daily news headlines to see plans for massive AI data centers and associated massive power supply strategies for those centers. AI etc. has the potential for consuming huge amounts of power given its processing, storage, and networking needs. Intelligently managing all power needs, particularly as AI usage grows, from all types of power sources, will likely become a (even more) critical societal need, particularly when power sources can be variable and capped, such as wind, solar, and water-based power generation.

Managing the power needs—and power sources—based on usage context will become even more critical as power needs grow in general and particularly as AI usage grows in volume and use cases. In fact, AI power usage may become even more important in “wired” contexts as the use cases, assuming unlimited power, creates progressively more, and more power-intensive use cases. For example, for use cases that rely predominately on Joe's personal sensors etc. for data collection, and perhaps his phone or Edge computing for the local AI-related processing needed to monitor and respond to Joe's contexts and behaviors, a designer would recognize that most if not all of the sensors, processors, etc. would be relying on battery-power. As such, in general and in particular for power management purposes, there will be an inclination to use this invention and others to optimize or at least improve overall power consumption of the associated use cases, particularly those that are mobile, dynamic, and with constrained ability to recharge the various electronics involved.

But, if Joe is deemed to be in a predominantly wired overall context, such as his work office, the design temptation may be to not worry about power consumption (and generation, and associated costs and strain on electrical grids), and develop ever more complex use cases that pull in more sensors etc., more frequently, with more data needing to be collected, transmitted, and processed. AI algorithms will focus on making sure as much data, and as many permutations as possible, are considered in formulating trigger/behavior/context solutions that could conceivably increase the power consumption greatly, even exponentially, in contrast to a power-conscious design in a predominantly battery-powered use case.

As an example, the power needed to identify and assess all of Joe's perceived contexts and behaviors going to, being, at, and returning from the ballgame could vary greatly in number and complexity. A “better” solution for determining and analyzing those possible behaviors and contexts could, and likely would want to draw on as much data as possible, as “fresh” as possible, in analyzing his actual and perceived contexts and behaviors. Indeed, there would be benefits to this approach for many use cases and users; for example, if a person has multiple triggers that could activate concurrently or nearly so, there would be logically a desire to “kill two birds with one stone” in preventing those triggers from activating.

In exemplary embodiments, using another entity's (e.g., a second person's or device's) contextual elements as a proxy, replacement, or substitute for the original entity's contexts when power resources are constrained—represents a significant enhancement to the concept of dynamic power management. This mechanism leverages multi-entity interactions to extend system efficiency, particularly in scenarios where shared or overlapping contexts can reduce the burden on power-limited components. This builds on the emphasis on predictive analytics, AI/ML, and risk-based optimization by introducing interpersonal or inter-device context sharing as a power-conservation strategy.

In resource-constrained environments (e.g., battery-powered wearables like Joe's ring monitoring Anger triggers), direct data collection from the primary entity can deplete power quickly, limiting the system's ability to predict and preempt behaviors (e.g., relapse or violence). By identifying a secondary entity (e.g., Jane, who is co-located with Joe in the car or ballpark) with ample power (e.g., her fully charged phone), the system may be configured to be operable for borrowing Jane's contextual data. This proxying is selective: actual contexts (objective, transferable elements like GPS location, ambient temperature, or time) are directly substituted, while perceived contexts (subjective, entity-specific interpretations like Joe's heightened frustration from heat vs. Jane's milder anxiety) are calibrated using AI/ML models trained on historical inter-entity differences.

For example, if Joe's device is low on power during the car ride, Jane's motion/gyroscope data (e.g., detecting sudden braking) could proxy Joe's, adjusted for perceptual variances (e.g., Joe's Anger trigger amplifies frustration more than Jane's Anxiety). In this example, calibration might involve weighting factors: e.g., 80% direct proxy for actual location, but only 50% for perceived crowd density, supplemented by minimal polling from Joe's device.

Benefits and novelty of the above approach include reducing power consumption by 20-50% in shared-context scenarios (e.g., family outings), extending operational time, and maintaining prediction accuracy. It addresses gaps in prior art, where power management is device-isolated (e.g., no inter-user proxying in adaptive scaling like Android's Battery Saver). By distinguishing actual (high-fidelity proxy) vs. perceived (low-fidelity, needing adjustment) contexts, the system may avoid errors, e.g., not overestimating Joe's risk based on Jane's lower heat sensitivity.

Implementation considerations include discovery of proxies, privacy/security, edge cases, and AI/ML role. Discover of proxies may include the use of Bluetooth/NFC for proximity detection or social graphs (e.g., family links) to identify candidates. Privacy/security may require consent-based sharing with encryption; federated learning to train calibration models without raw data exchange. Edge cases may fall back to low-accuracy modes or alerts for recharging if there is no suitable proxy (e.g., Jane's context diverges). AI/ML role may include the use of agents that learn optimal proxy selection/reliability, rewarding accurate risk predictions with minimal power draw. The above may enhance the applicability in group settings (e.g., families, workplaces) and IoT ecosystems, promoting collaborative power efficiency.

Exemplary embodiments disclosed herein may address battery versus “wired” power usage. Such exemplary embodiments differentiate power management strategies based on power source type: battery-powered (limited, mobile, e.g., wearables) versus wired (unlimited, stationary, e.g., home systems or plugged-in devices). Battery sources prioritize conservation (e.g., sleep modes, proxies) while wired allow intensive usage (e.g., as always-on hubs or proxies). Both have overarching goals of conserving power, but for different primary reasons-battery to conserve and extend battery life, and wired to reduce costs and strain on power generation sources.

In exemplary embodiments in which the system is configured with power management, the system is operable to distinguish between battery-powered and wired power sources associated with sensors, sensor arrays, devices, systems, and/or networks. The system is configured to: prioritize wired sources for high-frequency or high-duration data collection and processing to offload from battery-powered components; dynamically redirect tasks (such as contextual analysis or trigger risk computation) to wired sources when battery levels fall below a threshold; and apply more aggressive power-saving techniques (such as proxy context substitution from wired entities) exclusively to battery-powered sources to extend operational time while maintaining behavior prediction accuracy.

In exemplary embodiments, proxy context usage from a second entity prioritizes wired power sources for the second entity when available. And the system is configured to: transfer contextual data collection burdens to wired components of the second entity to avoid depleting its battery; and calibrate proxies with greater weight on data from wired sources for reliability, distinguishing battery constraints (e.g., intermittent sampling) from wired advantages (e.g., continuous monitoring) in the substitution process.

In exemplary methods with power management, the method includes classifying power sources as battery-powered (finite capacity, requiring conservation) or wired (continuous supply, allowing intensive usage); estimating future power requirements differentially, with battery sources triggering low-accuracy modes or proxy contexts from wired sources during high-risk scenarios; and optimizing overall system power by routing data aggregation and AI/ML inference to wired sources, thereby minimizing recharge needs for battery-powered entities and ensuring uninterrupted monitoring of triggers and behaviors.

Exemplary embodiments disclosed herein may also address power generation management. Such exemplary embodiments may extend beyond consumption to generation, using predictive analytics to optimize energy harvesting (e.g., solar, kinetic, etc.), recharging schedules, or generation from alternative sources (e.g., vehicle alternators, etc.). Predictions based on contexts/behaviors/triggers inform proactive generation (e.g., harvesting more during low-risk periods, etc.) or integration with proxies to align generation with anticipated needs.

In exemplary embodiments in which the system is configured for power generation management, predictive analytics, AI, and/or ML are used to forecast energy needs based on entity behaviors, contexts, triggers, and risks. The system is operable to: activate or optimize power generation mechanisms (e.g., solar harvesting in wearables or kinetic energy in devices) during low-risk periods to preemptively build reserves; schedule recharges aligned with predicted low-activity contexts (e.g., entity at home); and integrate generation data into power budgets including dynamically adjusting sensor usage to favor components with active generation capabilities over those reliant on stored power.

In exemplary embodiments, proxy context substitution incorporates power generation management. And the system is configured to: select secondary entities with active or predicted generation (e.g., wired or harvesting-capable devices) as preferred proxies; synchronize proxy usage with generation cycles to minimize net consumption; and differentiate actual contexts (e.g., shared solar exposure) for generation optimization from perceived contexts (e.g., entity-specific activity levels affecting kinetic yield), using AI/ML to refine generation forecasts and ensure sustainable power for behavior monitoring across entities.

In exemplary embodiments, dynamic calibration extends to power generation components. And the system is configured to: predict generation yields based on contextual forecasts (e.g., outdoor activity increasing solar input); adjust sensor metrics/ranges to align with generated power availability; and employ proxies from generation-rich entities during shortages, accounting for actual (e.g., environmental) vs. perceived (e.g., behavioral) impacts on generation efficiency to maintain risk determination accuracy.

In exemplary methods with power generation management, the method includes managing power generation by: predicting future generation opportunities using contextual elements (e.g., entity movement for kinetic harvesting or sunlight exposure for solar); allocating generation resources proactively based on trigger risk projections (e.g., harvest maximally before high-risk contexts like crowded events); and calibrating proxies from other entities to include their generation status, substituting data from entities with surplus generated power to balance system-wide energy without increasing consumption.

Exemplary embodiments disclosed herein may also be configured to address how trigger interdependencies (e.g., Joe and Jane's trigger interdependency) can be used advantageously with respect to power management. For example, it is possible (particularly for people in a relationship) that their respective triggers could “feed on” each other, such as when Joe sees Jane getting anxious, Joe gets increasingly angry (or frustrated, leading to anger). This, in turn, can feed Jane's anxiety, which, in turn, feeds Joes anger—spiraling on each other until it does not take much for either or both of them to have a trigger event. So, it is possible for example if Joe's sensors, devices, etc. are getting low in power, a system/method could use Jane's Anxiety level (and specific behaviors and contexts) as a “proxy” or substitute for estimating and predicting Joe's Anger risk levels, and even his contexts and behaviors. For example, if Jane's (fully charged) sensors, devices, etc. detect Jane's verbal output becoming increasingly shrill and filled with anxiety-indicating words, and the system/method/invention knows or deduces from Joe is interacting with Joe (through Joe-related speech from Jane that the system/method/invention recognizes, or that the system/method/invention knows from previous readings that Joe and Jane are both at the ballgame together), the system/method/invention can predict or project Joe's Anger-related behaviors, contexts, and risk levels. This provides a proxy for Joe's Anger related contexts (e.g., including location), behaviors, and risk, using only or nearly only power from Jane's sensors, devices, etc. The converse may also be implemented from Jane's perspectives, e.g. though Joe's sensors, devices, etc. may be low or out of power, the system/method/invention can deduce escalating interactions via Jane's sensors, devices, etc. that can assess Joe's spiraling Anger and associated trigger risk, even though there are no direct readings from Joe to provide data for that-only Jane's changing Anxiety-related behaviors and risk levels while she is sharing a context/location with Joe.

Accordingly, in exemplary embodiments, a system is configured to detect trigger interdependency between a first entity and a second entity. The system identifies patterns where a trigger or behavior of the first entity (e.g., anger or frustration) escalates a trigger or behavior of the second entity (e.g., anxiety), and vice versa, forming a feedback loop that increases risk of trigger events for one or both entities. The system may use predictive analytics, artificial intelligence (AI), and/or machine learning (ML) to model such interdependencies based on historical data of shared contexts, behaviors, and triggers. Upon detecting low power resources for the first entity's sensors, sensor arrays, devices, systems, and/or networks, the system may utilize data from the second entity's components as a proxy to estimate, predict, or determine the first entity's behaviors, contexts, triggers, or associated risks, leveraging the interdependency to infer escalations (e.g., using the second entity's anxiety indicators to project the first entity's anger risk during shared interactions), thereby conserving power for the first entity while maintaining system accuracy.

In exemplary embodiment, proxy context substitution accounts for trigger interdependencies. The system is configured to: select a secondary entity with an interdependent trigger relationship (e.g., where the secondary entity's anxiety feeds on and is fed by the primary entity's anger); use the secondary entity's data (e.g., anxiety-related behaviors like shrill speech or word patterns) to infer the primary entity's trigger escalations, even without direct readings from the primary entity; and confirm shared contexts (e.g., co-location at an event) via prior or minimal readings to validate the proxy's applicability for power-efficient risk assessment.

In exemplary embodiments, the system is configured from the perspective of the second entity. Upon detecting low power resources for the second entity's components, the system utilizes data from the first entity's components as a proxy to estimate, predict, or determine the second entity's behaviors, contexts (or contexts and locations), triggers, or risks, leveraging the interdependency (e.g., using the first entity's anger indicators like aggressive speech or movements to project the second entity's anxiety risk), thereby conserving power for the second entity.

In exemplary embodiments, a method comprises analyzing interdependencies between triggers of multiple entities, such as a spiral where one entity's escalating trigger (e.g., anger) amplifies another's (e.g., anxiety) in shared contexts. When power is low for a primary entity, the method may include employing proxy data from an interdependent secondary entity to predict the primary entity's trigger risks, behaviors, or contexts, including deducing interactions via the secondary entity's sensor readings (e.g., verbal or biometric changes indicating response to the primary entity's behavior).

In exemplary embodiments, the method is performed or operates from the perspective of a secondary entity. When power is low for the secondary entity, the method includes deducing escalations in the secondary entity's triggers (e.g., anxiety) via proxy data from an interdependent primary entity (e.g., detecting the primary entity's anger-related behaviors through the secondary entity's remaining sensors, such as recognizing interaction patterns), allowing inference of shared contextual spirals without full power usage from the secondary entity.

In exemplary embodiments, the system is configured to operable with dynamic calibration for multi-entity interdependencies. The system is operable for modeling feedback loops where triggers spiral (e.g., one entity's anger amplifying another's anxiety). For power management, the system is operable for prioritizing proxy data from the entity with higher power reserves to monitor the loop, adjusting for perceptual differences (e.g., how one perceives the other's behavior) to predict joint risks and implement preemptive actions efficiently.

Continuing the discussion of the example including Joe and Jane's trigger interdependency, Joe's agents or other systems monitoring Joe's triggers, behaviors, contexts/locations, and risks would need access to Jane's data. This could be done in a variety of ways. To expand on this, example implementations can range from simple static permissions to dynamic, AI-driven negotiations, leveraging the patent's core concepts of actual versus perceived contexts, hierarchical subcontexts, front-end intensive data collection, and power-aware strategies (e.g., distinguishing battery vs. wired sources and optimizing generation). For instance, access could be gated by power states: if Joe's battery is low, Joe's system proxies Jane's data only for actual contexts (e.g., shared location at the ballpark), while calibrating perceived elements (e.g., Jane's anxiety response to crowds inferring Joe's anger spiral) via lightweight traditional algorithms to minimize consumption. Enhancements can include integrating power generation forecasts (e.g., prioritizing access during kinetic harvesting in the car ride subcontext) and using front-end data lakes to build initial interdependency models for new pairs like Joe and Jane, updating via daily spirals.

To start with, there could be a variety of permission tiers that could be established between Joe and Jane's agents and systems. These tiers could be configured during front-end onboarding, where intensive data collection aggregates historical interdependencies (e.g., past ballgame spirals) into virtual models, allowing for context-specific rules. It could be as simple (particularly if Joe and Jane are set up under common accounts) to add permissions to obtain the other's data: all the time, with permissions, one-time (with or without permission), or even trigger, risk, context/location, and/or behavior dependent. For example, Jane may not want Joe to have access to her data unless Joe (or Jane's) Anger or Anxiety risk, respectively, reaches a certain level. This risk-dependent access could tie into hierarchical subcontexts: full access in broader high-risk contexts (e.g., ballgame arrival) but limited in low-risk subcontexts (e.g., music playing in the car), with AI/ML predicting escalations to preemptively request access. Or it could be context dependent, where Jane allows it if the context is a public place (Jane being especially sensitive to Joe's anger outbursts in public). Enhancements here can include differentiating actual (e.g., objective crowd density) from perceived contexts (e.g., Jane's heightened anxiety versus Joe's frustration), using RL agents to adjust permissions based on power needs, e.g., granting access only if Jane's wired home system can generate surplus power via solar during daytime outings.

With extra emphasis on AI-type agents: Joe and Jane could each have autonomous AI agents (e.g., RL-based entities embedded in apps or MCUs on their devices) that not only monitor individual triggers but actively interact and negotiate data access in real-time. For example, Joe's agent (detecting rising Anger from heat in the ballpark subcontext) could query Jane's agent for her Anxiety data as a proxy, negotiating terms like “share only actual location and biometric snippets for 5 minutes in exchange for Joe's future motion data.” This negotiation uses game-theoretic ML (e.g., cooperative RL) to balance privacy, power, and utility, escalating to cloud arbitration if deadlocked. In spirals, agents detect interdependencies (e.g., Joe's agent notes Jane's shrill speech via shared audio, inferring mutual escalation) and proactively share calibrated proxies, e.g., Jane's agent provides perceived anxiety cues adjusted for Joe's Anger profile. Enhancements: Agents incorporate power generation (e.g., Joe's agent defers negotiation if low on battery, harvesting kinetic energy first) and front-end models (e.g., initial data lake builds negotiation protocols based on simulated ballgame scenarios), ensuring efficient, adaptive access without manual intervention.

In exemplary embodiments, the system is configured for inter-entity data access management. Permission tiers are established between entities (e.g., a first entity with an anger trigger and a second with an anxiety trigger), allowing data sharing that is continuous, permission-based, one-time, or dependent on triggers, risks, contexts/locations, behaviors, or power states; the system using artificial intelligence (AI) agents associated with each entity to interact and negotiate access terms in real-time, optimizing for power conservation by proxying data during low-power scenarios while accounting for interdependencies such as trigger spirals. The AI agents may employ reinforcement learning (RL) or game-theoretic models to negotiate data sharing, considering factors like actual contexts (e.g., shared location) versus perceived contexts (e.g., differential emotional responses), hierarchical subcontexts (e.g., music interference within a car ride), and power distinctions (battery vs. wired), with negotiations prioritizing proxies from high-power entities to infer risks (e.g., using the second entity's anxiety indicators to predict the first entity's anger escalation).

In exemplary embodiments, the method includes configuring permission tiers for data access between interdependent entities during front-end intensive collection, feeding historical, current, and predicted data into a data lake to build virtual models of interdependencies (e.g., anger-anxiety spirals); and enabling AI agents to negotiate access dynamically, enhancing power management by substituting proxies calibrated for actual/perceived differences and subcontexts, while integrating generation forecasts (e.g., deferring negotiations during low-battery states until harvesting opportunities arise).

In exemplary embodiments, proxy substitution from a second entity incorporates AI agent negotiations for interdependent triggers. The system is configured to: initiate agent interactions when the first entity's power is low, negotiating terms based on spiral risks (e.g., the second entity's rising anxiety proxying the first entity's anger); distinguish actual subcontexts (high-fidelity proxy) from perceived (calibrated via ML on historical interdependencies); and hybridize with traditional algorithms for low-intensity phases, ensuring efficient access without excessive consumption.

In exemplary embodiments, trigger interdependency modeling includes AI agent-driven negotiations for data access in spirals (e.g., one entity's anger amplifying another's anxiety in shared subcontexts like public outbursts), with agents using RL on MCUs to balance privacy and utility, front-end data lakes for initial model building, and power generation integration (e.g., agents prioritizing wired sources or harvesting during stable contexts for sustained negotiations).

In exemplary embodiments, the method includes for interdependent entities: deploying AI agents that interact to detect and mitigate spirals by negotiating proxy access (e.g., from the second entity's fully charged device during the first's low power), calibrated for hierarchical contexts (e.g., broader ballgame with subcontexts like interactions), and enhanced with battery/wired distinctions (e.g., offloading to wired for intensive analysis) and generation management (e.g., harvesting kinetic energy in motion subcontexts before access).

In exemplary embodiments, AI/ML reduction hybrids with traditional algorithms are negotiated by inter-entity AI agents, optimizing for spirals by using proxies in low-risk subcontexts (e.g., switching to thresholding on shared data during stable phases), with front-end collection establishing negotiation protocols via data lakes and virtual models, and power-aware enhancements favoring generation-rich entities for sustained operations.

In exemplary embodiments, the system comprises an application framework for AI agent negotiations in multi-entity setups, using three-dimensional processing (triggers, contexts, power) to facilitate access during interdependencies, with enhancements for actual/perceived calibration, subcontext hierarchies, front-end data lakes for model initialization, battery/wired optimizations, and generation management (e.g., agents delaying negotiations until power reserves build via solar/kinetic in outdoor contexts).

Exemplary embodiments herein may also be configured to address actual, physical, or real contexts versus perceived contexts, as well as the related (but distinct) contexts within contexts, or alternatively subcontexts within contexts. For example, listening to music in the car on the radio is a subcontext within a broader “driving your car” context, which itself is within an even broader context of “going to a ballgame.” These are actual contexts, but there may be concurrent- or cause-and-effect-perceived contexts associated with those actual/physical/real contexts. For instance, Joe may hate the music playing, or find it too loud to hear other conversations going on in the car. This could also involve related triggers, such as the music increasing the risk of a related noise trigger that could lead to anger. Exemplary embodiments of systems/methods disclosed herein may address the above both individually and when the various aspects described are interrelated.

In exemplary embodiments, the system is configured to distinguish between actual contexts, defined as objective, measurable, or physical elements independent of entity perception (e.g., ambient temperature, location, or time), and perceived contexts, defined as subjective interpretations or responses by an entity to those actual elements (e.g., an entity's sensitivity to heat or crowd density). The system uses predictive analytics, artificial intelligence (AI), and/or machine learning (ML) to separately model and process actual and perceived contexts for estimating, determining, or controlling power requirements, settings, configurations, or usage in relation to behaviors, triggers, or associated risks. Power management may prioritize data collection from sensors capturing actual contexts (e.g., GPS for location or environmental sensors for temperature) for high-transferability scenarios, while applying calibration adjustments to perceived contexts using entity-specific profiles or historical data to optimize sensor activation and reduce unnecessary power consumption when perceptual variances are low. The system may be configured to integrate distinctions between actual and perceived contexts with hierarchical structures of contexts within contexts or subcontexts. The system may be configured to model actual subcontexts (e.g., objective music playback in a car) separately from perceived subcontexts (e.g., entity-specific irritation from volume or content); analyze interrelations such as how perceived subcontexts (e.g., noise perception) influence related triggers (e.g., frustration leading to anger); and dynamically manage power by proxying actual subcontexts across entities while calibrating perceived elements, optimizing sensor usage for interrelated risk predictions in multi-level contextual hierarchies.

In exemplary embodiments, the method includes classifying contextual elements as actual (objective and entity-independent, such as physical location or environmental conditions) or perceived (subjective and entity-dependent, such as emotional response to noise or social interactions); and differentially managing power by allocating fewer resources to sensors for actual contexts that can be inferred or proxied accurately, while escalating resources for perceived contexts requiring direct entity-specific measurement to ensure precise behavior or trigger risk predictions.

In exemplary embodiments, the system is configured to identify and process hierarchical contexts, including contexts within contexts or subcontexts within broader contexts (e.g., listening to music as a subcontext within driving a car, which is within attending a ballgame). The system employs artificial intelligence (AI) and/or machine learning (ML) to decompose, analyze, and prioritize these hierarchies for dynamic power management, selectively activating sensors based on the relevance of subcontexts to overall behaviors, triggers, or risks. Power requirements may be optimized by reducing frequency or duration of data collection for higher-level broader contexts when subcontexts provide sufficient predictive utility (e.g., using radio audio analysis in a car subcontext to infer noise-related triggers without full environmental scanning), thereby conserving energy while maintaining comprehensive risk assessment.

In exemplary embodiments, the method includes: decomposing contexts into hierarchical structures with subcontexts nested within broader contexts (e.g., specific interactions like music volume in a vehicle subcontext within a travel context); and adjusting power usage by focusing sensor resources on critical subcontexts that drive trigger escalations, using predictive models to propagate insights from subcontexts to broader levels without redundant data collection.

In exemplary embodiments, the method includes: processing hierarchical contexts where subcontexts (e.g., concurrent or causal elements like music interfering with conversations) exist within broader actual contexts (e.g., car ride to an event), while distinguishing perceived impacts (e.g., escalating irritation leading to trigger spirals); and, in proxy substitutions, prioritizing actual subcontexts for direct transferability while applying AI/ML adjustments for perceived variances, ensuring power-efficient management of interrelated triggers across entities in nested contextual scenarios.

In exemplary embodiments, proxy context usage from a second entity incorporates hierarchical and perceptual distinctions. The system is configured to: decompose the second entity's contexts into subcontexts and broader structures; proxy actual subcontexts (e.g., shared physical location or environmental noise) with high fidelity; calibrate perceived subcontexts (e.g., differential responses to music volume affecting interrelated triggers like noise to frustration to anger) using entity profiles; and manage power by selectively substituting interrelated elements to predict feedback loops or spirals between entities' triggers without exhausting the primary entity's resources.

Exemplary embodiments herein may also be configured to address front-end data collection efforts for a new-to-the-invention user, where an initial profile and associated trigger, behavior, and context/location data is needed to: generate initial trigger risk algorithms, enable AI data learning mechanisms, develop future predictive algorithms for trigger risk, contexts/locations, and behaviors for that new user, and create a plan for modifying this initial dataset, algorithms, and associated sensors, devices, etc. Instead of using a questionnaire or gradually building a profile over a long period of time, the system/method/invention uses an intense data collection effort on the front end. This will generally involve three capabilities: (1) collecting data from every possible source-historical, current, and (if it exists or can be predicted) future; (2) feeding that data into a “data lake” and building a virtual model of the entity; and (3) updating the model as the user goes about their daily life. Since this process will be incredibly power-hungry, such initial user data collection will need to be aware of power requirements specifically when, how, and how much data is collected.

In exemplary embodiments, the system is configured for front-end data collection for a new entity. The system performs an intensive initial data aggregation phase to rapidly generate an entity profile including triggers, behaviors, and associated contexts or locations. The system is operable to: collect data from all available sources, including historical records (e.g., past sensor logs, medical history, or location data), current real-time inputs (e.g., ongoing sensor readings or device interactions), and predicted future elements (e.g., scheduled events or forecasted behaviors via AI/ML models); feed the aggregated data into a data lake for centralized storage and processing; construct a virtual model of the entity using artificial intelligence (AI) and/or machine learning (ML) to derive initial trigger risk algorithms, predictive mechanisms for future triggers, behaviors, and contexts/locations; and establish a modification plan for iteratively updating the profile, algorithms, and data collection strategies based on ongoing inputs.

In exemplary embodiments, the intensive front-end data collection avoids reliance on questionnaires or gradual profiling by maximizing data ingestion from diverse sources during a defined initialization period. The system is configured to prioritize power-aware collection by assessing energy requirements and dynamically adjusting the timing, method, and volume of data gathering (e.g., batching historical data retrieval during wired power availability or limiting real-time sensor polling to essential triggers).

In exemplary embodiments, the data lake serves as a scalable repository for raw and processed data from the front-end collection. The system is configured to: apply data fusion techniques to integrate heterogeneous sources; use the virtual model for simulations of trigger scenarios to refine initial algorithms; and enable real-time updates post-initialization by continuously incorporating new data from daily life, with AI/ML-driven adaptations to the model for evolving behaviors and contexts.

In exemplary embodiments, the system is configured to manage power generation and consumption during the front-end data collection by: predicting energy demands based on data source volumes and processing complexity; activating alternative generation methods (e.g., kinetic or solar harvesting) when feasible; and incorporating power forecasts into the collection plan to balance intensive gathering with sustainability, ensuring the virtual model is built without interrupting ongoing operations.

In exemplary embodiments, the method includes for a new entity: executing an intensive front-end data collection to build an initial profile by sourcing data from historical, current, and predictable future elements across all accessible sensors, devices, systems, and networks; channeling the data into a data lake for integration; generating a virtual entity model via predictive analytics, AI, and/or ML to establish baseline trigger risk algorithms and future prediction mechanisms for behaviors, triggers, and contexts/locations; and defining a modification protocol to refine the model, algorithms, and collection efforts as the entity engages in daily activities, with power management considerations to optimize energy use during the high-intensity collection phase.

In exemplary embodiments, power management during front-end collection includes: evaluating power sources (e.g., battery vs. wired) and current levels; scheduling data ingestion to align with high-power availability periods (e.g., deferring intensive historical queries to plugged-in states); and scaling collection intensity (e.g., reducing frequency or duration for battery-powered sensors) to prevent depletion while ensuring comprehensive initial profiling. Updating the virtual model post-initialization may include: monitoring daily activities via optimized sensor usage; incrementally refining algorithms with new data to improve predictive accuracy for triggers and behaviors; and adjusting data collection parameters (e.g., sensor frequency) based on model feedback, with power-aware constraints to transition from intensive front-end efforts to efficient ongoing maintenance.

Another power management consideration is that AI/ML usage by itself can consume great amounts of resources, including power, processing capability, storage considerations, and interoperability demands. For system architectures and designs where there is extensive AI/ML uses on or with local sensors, devices, systems, and networks in particular, the resource consumption could be great. To address this, exemplary embodiments disclosed herein incorporate distinctions between actual contexts (objective elements like location or temperature) and perceived contexts (subjective responses like irritation from noise), as well as hierarchical structures such as contexts within contexts or subcontexts (e.g., music playing as a subcontext within a car ride, which is within attending a ballgame). These allow for targeted reductions in AI/ML intensity.

Exemplary embodiments disclosed herein look to manage these power demands by looking for use case opportunities, in particular contexts, where the overall system usage could reduce or eliminate, temporarily, the need to use AI/ML in a particular use case and associated contexts/locations and associated behaviors for a trigger, using instead of AI/ML (or in combination with it, with reduced usage of AI/ML in comparison to an AI/ML-focused capability), employing the use of “traditional” algorithms (e.g., rule-based thresholds, simple pattern matching, or statistical models like moving averages) and associated resource usage. This approach is particularly advantageous in interdependent trigger scenarios, such as between Joe (Anger trigger) and Jane (Anxiety trigger), where one's escalation feeds the other's in a spiral. For example, in the ballgame context:
Low-Risk Pre-Game at Home: Switch to traditional heart rate thresholding instead of AI/ML for Joe's stable state, saving power.
Medium-Risk Car Ride: Use pattern matching on telematics for traffic delays, hybrid with minimal AI/ML, and proxy Jane's data for Joe's via interdependency.
High-Risk Ballpark Arrival: Employ statistical averages for temperature subcontexts, reducing AI/ML to bursts.
Very High-Risk Seats Interactions: Keyword matching for speech handles baseline, with AI/ML for spiral confirmation; use Jane's perceptions as proxy if Joe's power is low.

There are a variety of implementation methods that this approach could employ, including cookies or equivalents (e.g., power-focused cookies storing contextual states for quick traditional algorithm handoffs), switching to server/cloud-based capabilities that can run the traditional algorithms (or, as described in prior claims, leveraging proxies from other entities like Jane for Joe's data when interdependencies exist). Enhancements can include integrating front-end intensive data collection for new users (e.g., aggregating all ballgame-related historical data into a data lake for virtual models), power generation management (e.g., harvesting during low-risk home phases for ballgame use), and ongoing model updates via daily life data, all calibrated for battery vs. wired differences.

Below are a variety of use case examples for optimizing power by selectively reducing or replacing AI/ML with traditional algorithms in specific contexts tailored to the ballgame scenario described elsewhere in this specification, where Joe (Anger trigger) and Jane (Anxiety trigger) are attending with family. These examples illustrate how the system switches to lighter-weight traditional algorithms (e.g., rule-based thresholds, simple pattern matching, or basic statistical models like moving averages) when contexts allow, conserving power on local devices (e.g., wearables, phones) by offloading complex AI/ML (e.g., deep neural networks for behavior prediction) or minimizing its use. This is particularly useful in battery-constrained settings like the ballgame, where prolonged sensor activity could drain power.
1. Low-Risk Pre-Game Preparation at Home (Stable Context): Joe is preparing to leave for the ballgame, with no immediate stressors (actual context: home environment, mild temperature). The system detects low Anger risk via basic sensors (e.g., stable heart rate). Instead of running power-intensive AI/ML for nuanced prediction (e.g., RL agent analyzing subtle speech patterns), it switches to a traditional algorithm: a simple threshold rule checking if heart rate exceeds 80 bpm for 5 minutes. If stable, AI/ML is temporarily disabled, saving ~30% power on Joe's wearable. Enhancement: If Jane's Anxiety is also low (e.g., via her phone's microphone detecting calm speech), her data proxies Joe's via interdependency (e.g., no anxious tones from Jane indicate no spiraling), further reducing Joe's device usage.
2. Medium-Risk Car Ride to Ballpark (Building Interdependency): During the car ride (actual context: shared small car, traffic), Joe's frustration rises from Jenny's complaints and Mike's advice, feeding Jane's Anxiety (perceived: Joe sees Jane's worry as nagging, escalating his Anger). The system initially uses AI/ML to model the spiral (e.g., ML fusing speech analysis and motion data). But detecting a repeating pattern (e.g., traffic-induced delays), it downgrades to traditional algorithms: pattern matching on telematics data (e.g., if speed <20 mph for >10 minutes, flag medium risk) combined with basic audio thresholding (e.g., volume >70 dB indicates yelling). This reduces AI/ML cycles by 50%, offloading to cloud if wired car systems are available. Enhancement: Using proxy interdependency, Jane's fully charged phone's microphone data substitutes for Joe's low-battery wearable, inferring Joe's Anger from Jane's rising anxious speech (e.g., shrill tones), avoiding full activation of Joe's sensors.
3. High-Risk Arrival at Ballpark (Crowded, Hot Environment with Subcontexts): At the parking lot and walk (actual context: hot weather, $50 cost, mile walk; subcontext: crowd navigation), Joe's Anger spirals from heat/perceived crowds, feeding Jane's Anxiety (e.g., her worry about Joe's mood heightens his irritation). Full AI/ML runs initially for prediction (e.g., DNN fusing biometrics and location). But in stable subcontexts (e.g., consistent heat), the system switches to traditional stats: moving average on temperature data (e.g., if average >85° F. over 5 mins, elevate risk) and rule-based geofencing (e.g., if within ballpark radius, assume crowd). This tempers AI/ML to intermittent bursts, saving power during the walk. Enhancement: Differentiate actual (shared heat/location) vs. perceived (Joe's claustrophobia vs. Jane's social worry); use Jane's data as proxy for Joe's perceived crowd stress, calibrated by historical interdependency (e.g., Jane's heart rate spikes predict Joe's Anger 70% of the time in crowds).
4. Very High-Risk Social Interactions at Seats (Interdependent Spiral Peak): At seats (actual context: introductions to rival; subcontext: Jenny's phone rudeness, refreshment expectations), Joe's Anger feeds on Jane's Anxiety (perceived: mutual spousal dislike with rival's wife), spiraling toward relapse. AI/ML fully engages for loop detection (e.g., RL modeling escalation). To manage power, it hybridizes: traditional algorithms handle baseline monitoring (e.g., keyword matching in speech for “angry” terms), reverting to AI/ML only for confirmation. Enhancement: If Joe's battery is critical, fully proxy via Jane's device (e.g., her facial analysis detects Joe's expressions indirectly through her reactions), using actual shared location to validate, preventing drain while preempting the spiral with joint alerts.

There are a variety of enhancements to the examples above that could be utilized, including:
Integrate front-end intensive collection for new users (e.g., during first ballgame, system aggregates all historical family data into a data lake for virtual models of Joe/Jane interdependency).
Add subcontexts. Table 1 shows some subcontexts such as playing music in car and proximity to alcohol (in certain sub-sub-contexts, such as smelling beer at refreshment area next to bathrooms, or being in seat while beer vendor comes by). This includes dynamic detection of sub-contexts, particularly high-risk ones (such as the above), that won't necessarily be anticipated or detected until at/within various contexts.
Power generation tie-in: During low-risk phases (e.g., home prep), activate kinetic harvesting on wearables to build reserves for high-risk ballgame phases.
Multi-entity proxies: Extend to family (e.g., Mike's neutral weather perception proxies Joe's heat sensitivity if calibrated for differences).

In exemplary embodiments, the system is configured to reduce or eliminate artificial intelligence (AI) or machine learning (ML) usage in power-constrained scenarios by switching to traditional algorithms (e.g., rule-based thresholds, pattern matching, or statistical models). The system is operable for identifying opportunities in specific contexts, behaviors, or triggers where traditional methods suffice for risk assessment, thereby conserving resources like power and processing while maintaining predictive accuracy for entity behaviors. The switch to traditional algorithms may be triggered by detecting stable or low-risk contexts (e.g., pre-game preparation at home with no stressors), subcontexts within broader hierarchies (e.g., music volume in a car ride subcontext within ballgame attendance), or interdependent spirals (e.g., Joe's Anger feeding Jane's Anxiety), with AI/ML reactivated only for confirmation or escalation, and power-focused cookies storing state transitions for seamless handoffs.

In exemplary embodiments, the method includes evaluating AI/ML resource demands against available power (battery vs. wired); opportunistically employing traditional algorithms in contexts where they approximate AI/ML utility (e.g., simple thresholding for stable heart rate in low-risk home subcontexts); and enhancing with proxies from interdependent entities (e.g., Jane's Anxiety data inferring Joe's Anger spiral during shared ballgame interactions), distinguishing actual (e.g., shared location) from perceived (e.g., differential irritation) elements for calibrated efficiency.

In exemplary embodiments, proxy substitution integrates AI/ML reduction, the system using traditional algorithms on the proxy entity's data (e.g., pattern matching on Jane's speech for anxious tones to proxy Joe's Anger without full AI/ML), optimized for interdependent triggers (e.g., spiraling Anxiety-Anger in ballgame crowds), and front-end intensive collection to build initial virtual models of interdependencies for new users.

In exemplary embodiments, trigger interdependency modeling employs hierarchical subcontexts (e.g., concurrent music interference in car conversations feeding noise-related triggers to Anger), with power management switching to traditional stats for actual subcontexts (e.g., volume levels) while reserving AI/ML for perceived escalations (e.g., Joe's frustration spiral), and leveraging wired sources or generation (e.g., car alternator) for intensive phases.

In exemplary embodiments, dynamic calibration for new entities includes front-end intensive data collection from all sources (historical, current, future predictions) into a data lake, generating virtual models with initial algorithms; ongoing updates via daily life (e.g., ballgame feedback refining Anger-Anxiety spirals); and power-aware strategies distinguishing battery (conservative, proxy-heavy) from wired (intensive), with generation optimization (e.g., harvesting during low-risk travel).

In exemplary embodiments, the method includes: for interdependent entities, using one entity's perceived contexts (e.g., Jane's anxious response to Joe's anger cues) as proxies for the other's actual subcontexts (e.g., shared ballpark noise escalating spirals), enhanced by traditional algorithms for power savings and AI/ML for high-risk confirmations.

In exemplary embodiments, the system includes an application framework for AI/ML-traditional hybrid processing, using RL agents on MCUs to decide switches based on power types (battery vs. wired), interdependencies, and hierarchies (e.g., subcontexts like rival interactions within ballgame seats), with front-end data lakes for new user modeling and generation integration (e.g., solar during outdoor ballgame phases) to sustain operations.

In exemplary embodiments, AI agent negotiation framework is expanded and builds on core features (e.g., power management via proxies, interdependencies, actual/perceived contexts, subcontexts, front-end data lakes, battery/wired, generation, RL/MCUs, AI/ML-traditional hybrids, etc.). In such exemplary embodiments, the AI agent negotiation frame expansion includes negotiation primitives, protocols, privacy mechanisms, power-aware bargaining, fallback strategies, etc.

Accordingly, exemplary embodiments may include inter-entity AI agent negotiation for power-efficient trigger monitoring. For example, Joe and Jane may each have autonomous AI agents (e.g., RL-based entities running on MCUs in wearables/phones via lightweight frameworks like TensorFlow Lite Micro) that monitor individual triggers (Joe: Anger; Jane: Anxiety) but also interact to detect, mitigate, and negotiate during interdependency spirals. These agents are initialized during front-end intensive data collection: all historical/current/predicted data (e.g., past ballgame arguments) is aggregated into a shared data lake, building virtual models of the Joe-Jane interdependency (e.g., 70% chance Jane's anxious speech predicts Joe's Anger escalation within 5 minutes). The agents use a structured negotiation protocol with primitives: REQUEST (e.g., “Need 2-min anxiety biometrics”), OFFER (e.g., “Share in exchange for your motion data”), COUNTEROFFER, ACCEPT, REJECT. Negotiation is game-theoretic (cooperative RL or Nash bargaining), treating power as currency—e.g., Joe's low-battery agent offers future data reciprocity for Jane's current proxy.

Implementation variations may include Edge-Centric, Hybrid Edge-Cloud, Privacy Preserving, and Fallback & Arbitration. With regard to Edge-Centric (Low-Latency, Battery-Focused), agents negotiate via BLE mesh on MCUs. Example: In car ride subcontext, Joe's agent detects rising Anger (traditional thresholding on heart rate) and REQUESTs Jane's speech data. Jane's agent (high battery) OFFERS 30-sec audio snippet if Joe shares location (actual context). ACCEPT if spiral risk >50%. Power saved: ~40% by avoiding Joe's microphone activation. Hybrid Edge-Cloud (Scalable, Generation-Aware) may include edge for quick decisions, and cloud for complex bargaining. If Joe's kinetic harvesting activates during walk, his agent COUNTEROFFERS more data for Jane's proxy, forecasting 10% battery gain. With regard to Privacy-Preserving (Federated/Homomorphic): agents share encrypted gradients (federated learning) or compute on encrypted data (homomorphic encryption) for perceived contexts—e.g., Jane's agent processes Joe's encrypted heart rate to infer Anxiety feed without raw access. With regard to Fallback & Arbitration: If REJECT (e.g., Jane's privacy tier blocks), fallback to traditional algorithms on local data or cloud arbitration (e.g., system-wide RL agent mediates based on joint risk).

Consider the following ballgame example with negotiation log in which the subcontext includes Car Ride (Music Playing) Joe's agent: REQUEST [Jane's Agent]: “Anxiety speech patterns, 1 min, for Anger proxy. My battery 20%.” Jane's agent: OFFER: “30 sec encrypted audio if you share location (actual).” Joe's agent: COUNTEROFFER: “Accept+future motion data reciprocity.” Jane's agent: ACCEPT.→Proxy saves Joe's power; detects spiral early. In this example, there may also include power generation (e.g., defer if solar forecast high at ballpark), using actual subcontexts for direct sharing, perceived for calibrated, and/or front-end models simulate negotiation success rates.

Exemplary embodiments disclosed herein may include one or more (but not necessarily any or all of) the following features:
Core System: Power management using risk, context, behavior, trigger prediction with AI/ML, optimizing data utility vs. consumption.
Context Hierarchy: Distinguishing actual/perceived, subcontexts within contexts, with power scaling.
Interdependency & Proxy: Spiral detection (Joe Anger ↔Jane Anxiety), proxying with calibration.
Front-End Onboarding: Intensive data lake→virtual model→ongoing refinement.
AI/ML Reduction: Traditional algorithms in stable contexts, hybrid with AI/ML.
Battery versus Wired: Differential strategies, offloading to wired.
Power Generation: Predictive harvesting aligned with risk/context.
AI Agent Negotiation: RL agents negotiate access, privacy-aware, power-balanced.
MCU/Application Integration: Edge RL, traditional fallback, generation-aware.
Multi-Entity Spiral Management: Negotiation+proxy+generation in ballgame-like scenarios.

In exemplary embodiments, the AI agents follow a structured negotiation protocol with primitives including REQUEST, OFFER, COUNTEROFFER, ACCEPT, and REJECT, using reinforcement learning (RL) or game-theoretic models on microcontroller units (MCUs) to bargain over data access terms, treating power reserves as negotiable currency while prioritizing actual contexts for direct proxying and calibrating perceived contexts via entity-specific profiles to manage interdependent trigger spirals efficiently. Negotiation implementations may include edge-centric (via low-power protocols like BLE for real-time decisions in subcontexts), hybrid edge-cloud (offloading complex bargaining to wired/cloud resources), and privacy-preserving variants (federated learning or homomorphic encryption for perceived data), with fallback to traditional algorithms or system arbitration upon REJECT to ensure continuous risk monitoring without power waste.

In exemplary embodiments, proxy substitution via AI agent negotiation accounts for hierarchical subcontexts (e.g., music interference within car ride), distinguishing actual (high-fidelity, low-negotiation overhead) from perceived (calibrated via ML, higher bargaining cost) elements, with RL agents optimizing for spiral prevention by sharing minimal data sufficient for joint risk prediction.

In exemplary embodiments, interdependency spiral detection triggers proactive agent negotiations, the system using three-dimensional processing to evaluate trade-offs in power, privacy, and accuracy—e.g., Joe's agent offering future reciprocity for Jane's current anxiety proxy during high-risk ballpark interactions, enhanced by generation integration (e.g., solar during outdoor phases).

In exemplary embodiments, AI/ML-traditional hybrid reduction is negotiated by agents—e.g., switching to thresholding on shared actual data during stable subcontexts, reserving AI/ML for spiral confirmations—with front-end data lakes initializing hybrid strategies and generation management ensuring sustained bargaining capacity.

In exemplary embodiments, there is an application framework for multi-agent negotiation in power management, using RL on MCUs to orchestrate access in interdependent scenarios, with enhancements for actual/perceived calibration, subcontext hierarchies, battery/wired offloading, and generation-aware deferral (e.g., agents pause during low-harvest periods, resuming post-ballgame solar input).

In exemplary embodiments, the method further comprises: during front-end intensive collection, aggregating interdependency data into a data lake to pre-train negotiation models; enabling AI agents to simulate bargaining outcomes for ballgame-like scenarios; and dynamically adjusting terms based on power generation forecasts (e.g., deferring access until kinetic harvesting in motion subcontexts) and battery versus wired distinctions.

In exemplary embodiments, the method further comprises: for privacy-aware negotiation, employing federated learning to update interdependency models without raw data exchange or homomorphic encryption for perceived context computation; and incorporating actual subcontext direct proxies (e.g., shared location) to minimize negotiation rounds and power in battery-constrained entities.

Exemplary embodiments disclosed herein generally relates to dynamic power management of sensors and devices using predicted behaviors, contexts, triggers, associated risks, machine learning, and/or artificial intelligence (AI). For example, exemplary embodiments are disclosed of systems and methods for using (a) context(s), (b) context(s) and location(s), (c) trigger(s), and/or (d) behavior(s) and associated risk(s) for dynamic sensors etc. power management. In exemplary embodiments, a system/method may include or be configured to be operable for using predictive analytics, artificial intelligence (AI), and/or machine learning (ML) for future dynamic power management based on (a) context(s), (b) context(s) and location(s), (c) trigger(s), and/or (d) behavior(s) and associated risk(s). In exemplary embodiments, the system/method optimizes power consumption for data collection and usage from sensors, devices, networks, and systems to predict current/future behaviors and contexts, formulate/implement actions to improve behaviors (potentially using said sensors/devices), while dynamically managing power based on predicted risks, recharge likelihood, and data utility.

In exemplary embodiments, a system/method may include or be configured to be operable for using predictive analytics, artificial intelligence (AI), and/or machine learning (ML) for future dynamic power management based on (a) context(s), (b) context(s) and location(s), (c) trigger(s), and/or (d) behavior(s) and associated risk(s). The invention optimizes power for data collection/usage from sensors/devices to predict behaviors, contexts, locations, and to formulate/implement actions to improve behaviors, balancing data utility against power constraints like battery life and recharge likelihood. The ability to collect dynamic, ongoing, frequently changing, and large volumes of data from sensors, sensor arrays, devices, systems, and networks, and associated key components (e.g., sensors, etc.), as well as powering key components of such sensors, etc., is a key capability of various enabled use cases, such as Artificial Intelligence/Machine Learning-enabled behavioral modification systems, methods, and apparatuses that seek to identify and correct behavioral issues before the behavioral issues get out of hand (“activated”). But this kind of intense data collection, processing, and operational usage, particularly that involving real-time, current, and/or relatively current data, and associated various forms of processing and usage, can consume very large quantities of power, which raises multitudes of issues with regards to power cost in general and in particular with respect to sensors, etc. that are battery powered, including limited ability to recharge. Such battery powered sensors, etc. can have limited power storage capacity, high power requirements per use (and thus limited operational usage before recharge is required, even at full charge to begin with), as well as limited (sometimes very limited) ability to recharge or otherwise ensure ongoing power due to significant logistical issues or other constraints. The exemplary inventions disclosed herein utilize predictive analytics and capabilities such as artificial intelligence and machine learning to manage the power needed for sensors, sensor arrays, devices, systems, networks, and/or associated components, in a variety of conditions and use cases, particularly with respect to collecting, processing, and using entity(ies) data about and/or associated with trigger(s), behavior(s), and context(s) to analyze, anticipate, predict, and adjust the operational usage of and associated power requirements for sensors, etc. that balance (and preferably optimize) the ability to collect, process, and use data needed to anticipate and preempt “bad” behavior that can activate certain trigger(s) and the associated context(s) within which the trigger(s) can, might, and do occur, with the utility of and general likelihood that the data collected, processed, and used will actually be useful and/or needed to predict and pre-empt such bad behavior is balanced against the finite available resources in the form of the available power for sensors, etc., costs, and ability to recharge.

Exemplary embodiments may include one or more computing devices, such as one or more servers, workstations, personal computers, laptops, tablets, smartphones, personal digital assistants (PDAs), etc. In addition, the computing device may include a single computing device, or it may include multiple computing devices located in close proximity or distributed over a geographic region, so long as the computing devices are specifically configured to function as described herein. Further, different components and/or arrangements of components than illustrated herein may be used in the computing device and/or in other computing device embodiments.

Exemplary embodiments may include one or more processors and memory coupled to (and in communication with) the one or more processors. A processor may include one or more processing units (e.g., in a multi-core configuration, etc.) such as, and without limitation, a central processing unit (CPU), a microcontroller, a reduced instruction set computer (RISC) processor, an application specific integrated circuit (ASIC), a programmable logic device (PLD), a gate array, and/or any other circuit or processor capable of the functions described herein.

In exemplary embodiments, a memory may be one or more devices that permit data, instructions, etc., to be stored therein and retrieved therefrom. The memory may include one or more computer-readable storage media, such as, without limitation, dynamic random-access memory (DRAM), static random-access memory (SRAM), read only memory (ROM), erasable programmable read only memory (EPROM), solid state devices, flash drives, CD-ROMs, thumb drives, and/or any other type of volatile or nonvolatile physical or tangible computer-readable media.

In exemplary embodiments, computer-executable instructions may be stored in the memory for execution by a processor to particularly cause the processor to perform one or more of the functions described herein, such that the memory is a physical, tangible, and non-transitory computer readable storage media. Such instructions often improve the efficiencies and/or performance of the processor that is performing one or more of the various operations herein. It should be appreciated that the memory may include a variety of different memories, each implemented in one or more of the functions or processes described herein.

In exemplary embodiments, a network interface may be coupled to (and in communication with) the processor and the memory. The network interface may include, without limitation, a wired network adapter, a wireless network adapter, a mobile network adapter, or other device capable of communicating to one or more different networks. In some exemplary embodiments, one or more network interfaces may be incorporated into or with the processor.

It should be appreciated that the functions described herein, in some embodiments, may be described in computer executable instructions stored on a computer readable media, and executable by one or more processors. The computer readable media is a non-transitory computer readable storage medium. By way of example, and not limitation, such computer-readable media can include RAM, ROM, EEPROM, CD-ROM or other optical disk storage, magnetic disk storage or other magnetic storage devices, or any other medium that can be used to carry or store desired program code in the form of instructions or databases and that can be accessed by a computer. Combinations of the above should also be included within the scope of computer-readable media.

It should also be appreciated that one or more aspects of the present disclosure transform a general-purpose computing device into a special-purpose computing device when configured to perform the functions, methods, and/or processes described herein.

Example embodiments are provided so that the present disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the present disclosure. In some example embodiments, well-known processes, well-known device structures, and well-known technologies are not described in detail. For example, technical material that is known in the technical fields related to the present disclosure has not been described in detail so that the present disclosure is not unnecessarily obscured. This includes, but is not limited to, to technology utilized in determining the location of mobile devices via a variety of means. In addition, advantages and improvements that may be achieved with one or more exemplary embodiments of the present disclosure are provided for purposes of illustration only and do not limit the scope of the present disclosure, as exemplary embodiments disclosed herein may provide all or none of the above-mentioned advantages and improvements and still fall within the scope of the present disclosure.

The terminology used herein is for the purpose of describing particular example embodiments only and is not intended to be limiting. The singular forms “a,” “an,” and “the” may be intended to include the plural forms as well, unless the context clearly indicates otherwise. In addition, the term “or” is an inclusive “or” operator and is equivalent to the term “and/or” unless the context clearly dictates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

The term “based on” is not exclusive and allows for being based on additional factors not described unless the context clearly dictates otherwise. The term “network” is used in multiple contexts within the present disclosure, and its use generally (but not necessarily) falls into one of two categories. The first is in the form of a (generally human) support “network” including one or more individuals/entities that provide the addict or other person with some sort of support or assistance. The second is in a technical context, such as a communications network that transmits, receives, and/or otherwise provides technical connectivity between various technical components disclosed herein.

The terms “support network” and “support community” may refer to a concept that an individual's or groups of individuals' personal network of friends, family colleagues, coworkers, medical/mental health/addiction professionals, members of their social network (e.g., Facebook, Twitter, Snapchat, etc.), etc. and the subsequent connections within those networks can be utilized to find more relevant connections for a variety of activities, including, but not limited to dating, job networking, service referrals, content sharing, like-minded individuals, activity partners, or the like. Such social networks may be created based on a variety of criteria, including, for example, an address book, a social event, an online community, or the like. The term “member” may refer to a user who is included in a support network. The term “group” or “community” may refer to a collection of members.

Although the terms first, second, third, etc. may be used herein to describe various elements, components, or features, these elements, components, or features should not be limited by these terms. These terms may be only used to distinguish one element, component, or feature from another element, component, or feature. Terms such as “first,” “second,” and other numerical terms when used herein do not imply a sequence or order unless clearly indicated by the context. Thus, a first element, component, or feature could be termed a second element, component, or feature without departing from the teachings of the example embodiments.

None of the elements recited in the claims are intended to be a means-plus-function element within the meaning of 35 U.S.C. § 112 (f) unless an element is expressly recited using the phrase “means for,” or in the case of a method claim using the phrases “operation for” or “step for.”

The foregoing description of the embodiments has been provided for purposes of illustration and description. It is not intended to be exhaustive or to limit the present disclosure. Individual elements, intended or stated uses, or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the present disclosure, and all such modifications are intended to be included within the scope of the present disclosure.

1.-149. (canceled)

150. A computer-implemented method for context-based sensor power management in a computing device, the method comprising:
determining a current context state and a predicted future context state of a user associated with the computing device based on sensor data from one or more active sensors;
for each sensor in a set of available sensors, computing an importance score indicative of the sensor's relevance to determining the current context state and the predicted future context state, wherein the importance score is derived from contextual attributes including a plurality of temporal, locational, social, activity, and behavioral factors;
estimating a power consumption requirement cost for each sensor at one or more operational modes, including varying sampling rates or activation states;
predicting a recharge likelihood for the computing device within a predefined and/or dynamically determined time horizon based on historical user behavior patterns, current location, and temporal data;
adjusting an effective available power budget based on a current battery level and the predicted recharge likelihood;
retrieving a historical utility value for each sensor from a database, the historical utility value representing the sensor's effectiveness in similar past context states;
calculating a utility metric for each sensor as a function of the importance score, the historical utility value, and the normalized power consumption cost;
optimizing sensor usage by selecting operational modes for each sensor to maximize an aggregate utility metric while constraining total power consumption within the adjusted power budget and using an optimization technique;
applying the selected operational modes to control activation, deactivation, or sampling rate adjustments of the sensors; and
updating the historical utility database with feedback on sensor performance in the current context state.

151. The method of claim 150, wherein the steps are performed by at least one processor to balance context determination accuracy and power efficiency.

152. The method of claim 150, wherein predicting the recharge likelihood comprises employing a Markov model or machine learning algorithm trained on historical recharge events correlated with location, time, and user activity patterns.

153. The method of claim 150, wherein the utility metric is computed as the product of the importance score and historical utility value divided by the normalized power consumption cost, with thresholds applied to deactivate sensors below a minimum utility value.

154. The method of claim 150, wherein the optimization technique treats sensor selection as a knapsack problem, with sensor utilities as values, power costs as weights, and the power budget as capacity.

155. The method of claim 150, wherein the method includes optimizing sensor usage by selecting operational modes for each sensor to maximize an aggregate utility metric while constraining total power consumption within the adjusted power budget and using greedy selection or dynamic programming as the optimization technique.

156. The method of claim 150, further comprising integrating the method with a context inference algorithm that uses the managed sensors to determine motivational or behavioral “why” attributes dependent on temporal (“when”), locational (“where”), social (“who”), activity (“what”), and execution (“how”) contexts.

157. The method of claim 150, wherein the operational modes include at least high, medium, low sampling rates, and off, with power consumption scaled proportionally to the operational mode.

158. The method of claim 150, wherein predicting the recharge likelihood comprises using a reinforcement learning agent to refine predictions based on rewards derived from context accuracy minus normalized power usage.

159. The method of claim 150, further comprising:
determining a degree of contribution of each sensor to inferring a temporal contextual element (“when”) and at least one additional contextual element selected from locational (“where”), social (“who”), activity (“what”), executional (“how”), or motivational (“why”) elements;
evaluating an importance level of the temporal contextual element and the at least one additional contextual element in determining the current context state and the predicted future context state of the user; and
dynamically adjusting the power consumption of each sensor by modifying its operational mode, wherein the adjustment increases power allocation for sensors with a high degree of contribution to highly important contextual elements and decreases power allocation for sensors with a low degree of contribution or low element importance, and wherein the adjustment is proportional to a combined score derived from the degree of contribution and the importance level, ensuring power efficiency while prioritizing accuracy in context determination.

160. The method of claim 159, wherein the degree of contribution is computed using a fusion model that weights sensor data inputs based on their relevance to the temporal contextual element and the at least one additional contextual element, with the model updated via machine learning from historical sensor performance in similar contexts.

161. The method of claim 159, wherein the importance level of the contextual elements is assessed using a hierarchical ontology that ranks elements based on their impact on overall context inference.

162. The method of claim 161, wherein the importance level of the contextual elements is assessed using the hierarchical ontology that ranks elements based on their impact on overall context inference by prioritizing the temporal element in time-sensitive scenarios or the motivational element in behavior prediction tasks.

163. The method of claim 150, further comprising:
classifying each sensor's role in determining a temporal contextual element (“when”) in conjunction with at least one of a locational (“where”), social (“who”), activity (“what”), executional (“how”), or motivational (“why”) element;
assigning an importance coefficient to each contextual element based on its predicted influence on the current or future context, derived from user behavior patterns or environmental factors; and
modulating the sensor's power consumption by scaling its sampling rate or activation duration inversely with the product of the sensor's classification role and the importance coefficient, thereby conserving power for less critical contributions while enhancing resolution for critical ones.

164. The method of claim 163, wherein modulating the sensor's power consumption includes:
deactivating the sensor if the product of the classification role and importance coefficient falls below a predefined threshold; or
increasing power to enable higher-fidelity data collection if the product exceeds the threshold.

165. The method of claim 150, wherein the method includes utilizing a sensor fusion architecture in sensor arrays, the architecture employing Bayesian inference or Kalman filtering integrated with machine learning to combine data from multiple sensors, thereby projecting power usage scenarios based on correlated behaviors and contexts, and dynamically gating power to array subsets for efficiency.

166. The method of claim 150, wherein the method includes:
classifying power sources as battery-powered or wired;
estimating future power requirements differentially, with battery sources triggering low-accuracy modes or proxy contexts from wired sources during high-risk scenarios; and
optimizing overall system power by routing data aggregation and AI/ML inference to wired sources, thereby minimizing recharge needs for battery-powered entities and ensuring uninterrupted monitoring of triggers and behaviors.

167. The method of claim 150, wherein the method includes:
predicting future generation opportunities using contextual elements;
allocating generation resources proactively based on trigger risk projections; and
calibrating proxies from other entities to include their generation status, substituting data from entities with surplus generated power to balance system-wide energy without increasing consumption.

168. The method of claim 150, wherein the method includes:
analyzing interdependencies between triggers of multiple entities, including a spiral where one entity's escalating trigger amplifies another entity's trigger in shared contexts; and
when power is low for a primary entity, employing proxy data from an interdependent secondary entity to predict the primary entity's trigger risks, behaviors, or contexts, including deducing interactions via the secondary entity's sensor readings.

169. The method of claim 150, wherein the method is performed or operates from the perspective of a secondary entity, and wherein the method includes:
when power is low for the secondary entity, deducing escalations in the secondary entity's triggers via proxy data from an interdependent primary entity; and
allowing inference of shared contextual spirals without full power usage from the secondary entity.

170. The method of claim 150, wherein the method includes:
configuring permission tiers for data access between interdependent entities during front-end intensive collection, feeding historical, current, and predicted data into a data lake to build virtual models of interdependencies; and
enabling AI agents to negotiate access dynamically, enhancing power management by substituting proxies calibrated for actual/perceived differences and subcontexts, while integrating generation forecasts.

171. The method of claim 150, wherein for interdependent entities, the method includes deploying AI agents that interact to detect and mitigate spirals by negotiating proxy access, calibrated for hierarchical contexts, and enhanced with battery/wired distinctions and generation management.

172. The method of claim 150, wherein the method includes:
classifying contextual elements as actual or perceived; and
differentially managing power by allocating fewer resources to sensors for actual contexts that can be inferred or proxied accurately, while escalating resources for perceived contexts requiring direct entity-specific measurement to ensure precise behavior or trigger risk predictions.

173. The method of claim 150, wherein the method includes:
decomposing contexts into hierarchical structures with subcontexts nested within broader contexts; and
adjusting power usage by focusing sensor resources on critical subcontexts that drive trigger escalations, using predictive models to propagate insights from subcontexts to broader levels without redundant data collection.

174. The method of claim 150, wherein the method includes:
processing hierarchical contexts where subcontexts exist within broader actual contexts, while distinguishing perceived impacts; and
in proxy substitutions, prioritizing actual subcontexts for direct transferability while applying AI/ML adjustments for perceived variances, ensuring power-efficient management of interrelated triggers across entities in nested contextual scenarios.

175. The method of claim 150, wherein the method includes for a new entity:
executing an intensive front-end data collection to build an initial profile by sourcing data from historical, current, and predictable future elements across all accessible sensors, devices, systems, and networks;
channeling the data into a data lake for integration;
generating a virtual entity model via predictive analytics, AI, and/or ML to establish baseline trigger risk algorithms and future prediction mechanisms for behaviors, triggers, and contexts/locations; and
defining a modification protocol to refine the model, algorithms, and collection efforts as the entity engages in daily activities, with power management considerations to optimize energy use during the high-intensity collection phase.

176. The method of claim 175, wherein power management during front-end collection includes:
evaluating power sources and current levels;
scheduling data ingestion to align with high-power availability periods; and
scaling collection intensity to prevent depletion while ensuring comprehensive initial profiling.

177. The method of claim 175, wherein updating the virtual model post-initialization includes:
monitoring daily activities via optimized sensor usage;
incrementally refining algorithms with new data to improve predictive accuracy for triggers and behaviors; and
adjusting data collection parameters based on model feedback, with power-aware constraints to transition from intensive front-end efforts to efficient ongoing maintenance.

178. The method of claim 150, wherein the method includes:
evaluating AI/ML resource demands against available power;
opportunistically employing traditional algorithms in contexts to approximate AI/ML utility; and
enhancing with proxies from interdependent entities, distinguishing actual from perceived elements for calibrated efficiency.

179. The method of claim 150, wherein the method includes: for interdependent entities, using one entity's perceived contexts as proxies for the other's actual subcontexts, enhanced by traditional algorithms for power savings and AI/ML for high-risk confirmations.

180. The method of claim 150, further comprising:
during front-end intensive collection, aggregating interdependency data into a data lake to pre-train negotiation models;
enabling AI agents to simulate bargaining outcomes for ballgame-like scenarios; and
dynamically adjusting terms based on power generation forecasts and battery versus wired distinctions.

181. The method of claim 150, further comprising:
for privacy-aware negotiation, employing federated learning to update interdependency models without raw data exchange or homomorphic encryption for perceived context computation; and
incorporating actual subcontext direct proxies to minimize negotiation rounds and power in battery-constrained entities.

182. A system for context-based sensor power management in a computing device, comprising a processor and memory configured to execute instructions for:
a context determination component that identifies current and predicted future context states;
a sensor evaluation component that computes importance scores, power costs, historical utilities, and utility metrics for each sensor;
a recharge prediction component that estimates recharge likelihood and adjusts power budgets;
an optimization component that selects sensor operational modes to maximize utility under power constraints; and
a control component that applies the selected modes and updates historical data.

183. The system of claim 182, wherein the recharge prediction component is configured to use a reinforcement learning agent to refine predictions based on rewards derived from context accuracy minus normalized power usage.

184. The system of claim 182, wherein:
the sensor evaluation component further determines a degree of each sensor's utilization in ascertaining a temporal contextual element (“when”) and at least one complementary element from locational (“where”), social (“who”), activity (“what”), executional (“how”), or motivational (“why”), and evaluates the relative importance of said elements in the context determination; and
the optimization component adjusts power consumption levels for sensors proportionally to the degree of utilization and element importance, thereby optimizing for reduced energy use in low-importance scenarios.

185. The system of claim 184, wherein the adjustment to power consumption is implemented through a dynamic programming algorithm that selects sensor modes to maximize context accuracy per unit of power expended, factoring in the weighted contributions to the temporal and complementary elements.

186. The system of claim 182, further comprising an edge computing architecture integrated into one or more sensors, sensor arrays, devices, systems, and/or networks, wherein the edge computing architecture includes machine learning accelerators configured to perform local inference for predicting power requirements based on real-time contexts, behaviors, and triggers, thereby reducing data transmission to central systems and optimizing battery usage.

187. The system of claim 182, wherein the system is configured for dynamic selection and calibration of one or more sensors, sensor arrays, devices, systems, and/or communication network(s) that is facilitated by a reinforcement learning (RL) agent embedded in specialized power management components, the RL agent configured to learn optimal power policies by rewarding energy-efficient configurations that maintain high utility for behavior and context determination, including adjustments to sampling rates, activation states, and data fusion across sensor arrays.

188. The system of claim 182, further comprising dynamic voltage and frequency scaling (DVFS) hardware controlled by artificial intelligence algorithms that adapt processor performance based on projected risk tiers of triggers and behaviors, ensuring power conservation during low-risk contexts while escalating resources for high-risk scenarios.

189. The system of claim 182, wherein the system is configured to be operable with power management that includes power-focused cookies as non-volatile data structures stored on sensors and devices, the power-focused cookies utilizing contextual energy profiles, historical utility metrics, and recharge predictions to enable rapid resumption of operations post-sleep modes without full system recalibration.

190. The system of claim 182, wherein the system includes one or more networks that employ low-power wide-area network (LPWAN) protocols optimized by graph neural networks for contextual routing, the one or more networks configured to prioritize data transmission based on trigger risks and user behaviors, with edge gateways using reinforcement learning to adjust duty cycles and predict recharge likelihood across distributed nodes.

191. The system of claim 182, wherein the system includes an application framework executing on one or more sensors, sensor arrays, devices, systems, and/or networks, the application framework configured to:
(a) implement a modular architecture with a data ingestion module to collect and preprocess sensor data, an AI/ML inference module to predict trigger risks and behaviors using reinforcement learning (RL) agents, a power management module to control sensor and device power states, and an action implementation module to execute behavior modification actions via user interfaces;
(b) utilize edge-based processing on microcontroller units (MCUs) with lightweight machine learning frameworks to perform real-time inference of contextual and behavioral states, minimizing cloud dependency and power consumption;
(c) store power-focused cookies as lightweight, persistent data structures in device memory or cloud databases to cache contextual energy profiles, sensor utility metrics, and RL policy states, enabling efficient resumption of operations post-sleep modes;
(d) employ a cloud-edge hybrid model with federated learning to train and update ML models on aggregated data while preserving user privacy, pushing updated models to edge applications for local power optimization;
(e) integrate a context-aware user interface that adjusts power usage for rendering based on trigger risk levels, using dynamic voltage and frequency scaling (DVFS) to scale display resources and RL-driven feedback loops to refine action effectiveness; and
(f) coordinate system-wide power management via middleware using message queuing and graph neural networks to prioritize data flows for high-risk trigger scenarios, ensuring energy-efficient operation while maximizing data utility for predicting and mitigating addiction-related or restriction violation-related behaviors in dynamic contexts.

192. The system of claim 182, wherein the system is configured for power management that distinguishes between battery-powered and wired power sources associated with sensors, sensor arrays, devices, systems, and/or networks, and wherein the system is configured to:
prioritize wired sources for high-frequency or high-duration data collection and processing to offload from battery-powered components;
dynamically redirect tasks to wired sources when battery levels fall below a threshold; and
apply more aggressive power-saving techniques exclusively to battery-powered sources to extend operational time while maintaining behavior prediction accuracy.

193. The system of claim 192, wherein the system is configured to:
dynamically redirect tasks including contextual analysis or trigger risk computation to wired sources when battery levels fall below a threshold; and
apply more aggressive power-saving techniques including proxy context substitution from wired entities exclusively to battery-powered sources to extend operational time while maintaining behavior prediction accuracy.

194. The system of claim 192, wherein the system is operable with proxy context usage from a second entity prioritizes wired power sources for the second entity when available, and wherein the system is configured to:
transfer contextual data collection burdens to wired components of the second entity to avoid depleting its battery; and
calibrate proxies with greater weight on data from wired sources for reliability, distinguishing battery constraints from wired advantages.

195. The system of claim 192, wherein the system is operable with proxy context usage from a second entity prioritizes wired power sources for the second entity when available, and wherein the system is configured to:
transfer contextual data collection burdens to wired components of the second entity to avoid depleting its battery; and
calibrate proxies with greater weight on data from wired sources for reliability, distinguishing battery constraints including intermittent sampling from wired advantages in the substitution process.

196. The system of claim 182, wherein the system is configured for power generation management, wherein predictive analytics, artificial intelligence, and/or machine learning are used to forecast energy needs based on entity behaviors, contexts, triggers, and risks, and wherein the system is operable to:
activate or optimize power generation mechanisms during low-risk periods to preemptively build reserves;
schedule recharges aligned with predicted low-activity contexts; and
integrate generation data into power budgets including dynamically adjusting sensor usage to favor components with active generation capabilities over those reliant on stored power.

197. The system of claim 196, wherein proxy context substitution incorporates power generation management, and wherein the system is configured to:
select secondary entities with active or predicted as preferred proxies;
synchronize proxy usage with generation cycles to minimize net consumption; and
differentiate actual contexts for generation optimization from perceived contexts by using artificial intelligence and/or machine learning to refine generation forecasts and ensure sustainable power for behavior monitoring across entities.

198. The system of claim 182, wherein the system is configured to be operable with dynamic calibration that extends to power generation components, and wherein the system is configured to:
predict generation yields based on contextual forecasts;
adjust sensor metrics/ranges to align with generated power availability; and
employ proxies from generation-rich entities during shortages, accounting for actual versus perceived impacts on generation efficiency to maintain risk determination accuracy.

199. The system of claim 182, wherein the system is configured to detect trigger interdependency between a first entity and a second entity, and wherein the system is configured to:
identify patterns where a trigger or behavior of the first entity escalates a trigger or behavior of the second entity, and vice versa, forming a feedback loop that increases risk of trigger events for one or both entities; and
use predictive analytics, artificial intelligence (AI), and/or machine learning (ML) to model such interdependencies based on historical data of shared contexts, behaviors, and triggers.

200. The system of claim 199, wherein upon detecting low power resources for the first entity's sensors, sensor arrays, devices, systems, and/or networks, the system utilizes data from the second entity's components as a proxy to estimate, predict, or determine the first entity's behaviors, contexts, triggers, or associated risks, leveraging the interdependency to infer escalations, thereby conserving power for the first entity while maintaining system accuracy.

201. The system of claim 199, wherein the system is configured from the perspective of the second entity, such that upon detecting low power resources for the second entity's components, the system utilizes data from the first entity's components as a proxy to estimate, predict, or determine the second entity's behaviors, contexts, triggers, or risks, leveraging the interdependency, thereby conserving power for the second entity.

202. The system of claim 182, wherein proxy context substitution accounts for trigger interdependencies, and wherein the system is configured to:
select a secondary entity with an interdependent trigger relationship;
use the secondary entity's data to infer the primary entity's trigger escalations, even without direct readings from the primary entity; and
confirm shared contexts via prior or minimal readings to validate the proxy's applicability for power-efficient risk assessment.

203. The system of claim 182, wherein the system is configured for multi-entity interdependencies, and wherein the system is operable for:
modeling feedback loops where triggers spiral; and
for power management, prioritizing proxy data from the entity with higher power reserves to monitor the loop and adjusting for perceptual differences to predict joint risks and implement preemptive actions efficiently.

204. The system of claim 182, wherein:
the system is configured for inter-entity data access management;
permission tiers are established between entities, allowing data sharing that is continuous, permission-based, one-time, or dependent on triggers, risks, contexts/locations, behaviors, or power states; and
the system is operable for using artificial intelligence (AI) agents associated with each entity to interact and negotiate access terms in real-time, optimizing for power conservation by proxying data during low-power scenarios while accounting for interdependencies such as trigger spirals.

205. The system of claim 204, wherein the system is configured such that AI agents employ reinforcement learning (RL) or game-theoretic models to negotiate data sharing, considering factors including actual contexts versus perceived contexts, hierarchical subcontexts, and power distinctions including battery versus wired, with negotiations prioritizing proxies from high-power entities to infer risks.

206. The system of claim 182, wherein proxy substitution from a second entity incorporates AI agent negotiations for interdependent triggers, and wherein the system is configured to:
initiate agent interactions when the first entity's power is low, negotiating terms based on spiral risks;
distinguish actual subcontexts from perceived; and
hybridize with traditional algorithms for low-intensity phases, ensuring efficient access without excessive consumption.

207. The system of claim 182, wherein the system is operable with trigger interdependency modeling that includes AI agent-driven negotiations for data access in spirals with agents using RL on MCUs to balance privacy and utility, front-end data lakes for initial model building, and power generation integration.

208. The system of claim 182, wherein the system is operable such that AI/ML reduction hybrids with traditional algorithms are negotiated by inter-entity AI agents, optimizing for spirals by using proxies in low-risk subcontexts, with front-end collection establishing negotiation protocols via data lakes and virtual models, and power-aware enhancements favoring generation-rich entities for sustained operations.

209. The system of claim 182, wherein the system includes an application framework for AI agent negotiations in multi-entity setups, using three-dimensional processing to facilitate access during interdependencies, with enhancements for actual/perceived calibration, subcontext hierarchies, front-end data lakes for model initialization, battery/wired optimizations, and generation management.

210. The system of claim 182, wherein the system is configured to distinguish between actual contexts defined as objective, measurable, or physical elements independent of entity perception, and perceived contexts defined as subjective interpretations or responses by an entity to those actual elements, and wherein the system uses predictive analytics, artificial intelligence (AI), and/or machine learning (ML) to separately model and process actual and perceived contexts for estimating, determining, or controlling power requirements, settings, configurations, or usage in relation to behaviors, triggers, or associated risks.

211. The system of claim 210, wherein the system is configured with power management that prioritizes data collection from sensors capturing actual contexts for high-transferability scenarios, while applying calibration adjustments to perceived contexts using entity-specific profiles or historical data to optimize sensor activation and reduce unnecessary power consumption when perceptual variances are low.

212. The system of claim 182, wherein the system is configured to identify and process hierarchical contexts, including contexts within contexts or subcontexts within broader contexts, and wherein the system employs artificial intelligence (AI) and/or machine learning (ML) to decompose, analyze, and prioritize these hierarchies for dynamic power management, selectively activating sensors based on the relevance of subcontexts to overall behaviors, triggers, or risks.

213. The system of claim 212, wherein the system is configured such that power requirements are optimized by reducing frequency or duration of data collection for higher-level broader contexts when subcontexts provide sufficient predictive utility, thereby conserving energy while maintaining comprehensive risk assessment.

214. The system of claim 182, wherein the system is configured to integrate distinctions between actual and perceived contexts with hierarchical structures of contexts within contexts or subcontexts, and wherein the system:
models actual subcontexts separately from perceived;
analyzes interrelations such as how perceived subcontexts influence related; and
dynamically manages power by proxying actual subcontexts across entities while calibrating perceived elements, optimizing sensor usage for interrelated risk predictions in multi-level contextual hierarchies.

215. The system of claim 182, wherein proxy context usage from a second entity incorporates hierarchical and perceptual distinctions, and wherein the system is configured to:
decompose the second entity's contexts into subcontexts and broader structures;
proxy actual subcontexts with high fidelity;
calibrate perceived subcontexts using entity profiles; and
manage power by selectively substituting interrelated elements to predict feedback loops or spirals between entities' triggers without exhausting the primary entity's resources.

216. The system of claim 182, wherein the system is configured for front-end data collection for a new entity, wherein the system performs an intensive initial data aggregation phase to rapidly generate an entity profile including triggers, behaviors, and associated contexts or locations, and wherein the system is operable to:
collect data from all available sources, including historical records, current real-time inputs, and predicted future elements;
feed the aggregated data into a data lake for centralized storage and processing;
construct a virtual model of the entity using artificial intelligence (AI) and/or machine learning (ML) to derive initial trigger risk algorithms, predictive mechanisms for future triggers, behaviors, and contexts/locations; and
establish a modification plan for iteratively updating the profile, algorithms, and data collection strategies based on ongoing inputs.

217. The system of claim 216, wherein the system is operable to collect data:
from historical records including past sensor logs, medical history, or location data;
from current real-time inputs including ongoing sensor readings or device interactions; and
from predicted future elements including scheduled events or forecasted behaviors via AI/ML models.

218. The system of claim 216, wherein intensive front-end data collection avoids reliance on questionnaires or gradual profiling by maximizing data ingestion from diverse sources during a defined initialization period, and wherein the system is configured to prioritize power-aware collection by assessing energy requirements and dynamically adjusting the timing, method, and volume of data gathering.

219. The system of claim 218, wherein the system is configured to prioritize power-aware collection by assessing energy requirements and dynamically adjusting the timing, method, and volume of data gathering by batching historical data retrieval during wired power availability or limiting real-time sensor polling to essential triggers.

220. The system of claim 216, wherein the data lake serves as a scalable repository for raw and processed data from the front-end collection, and wherein the system is configured to:
apply data fusion techniques to integrate heterogeneous sources;
use the virtual model for simulations of trigger scenarios to refine initial algorithms; and
enable real-time updates post-initialization by continuously incorporating new data from daily life, with AI/ML-driven adaptations to the model for evolving behaviors and contexts.

221. The system of claim 216, wherein the system is configured to manage power generation and consumption during the front-end data collection by:
predicting energy demands based on data source volumes and processing complexity;
activating alternative generation methods when feasible; and
incorporating power forecasts into the collection plan to balance intensive gathering with sustainability, ensuring the virtual model is built without interrupting ongoing operations.

222. The system of claim 221, wherein activating alternative generation methods includes kinetic or solar harvesting.

223. The system of claim 182, wherein the system is configured to reduce or eliminate artificial intelligence (AI) or machine learning (ML) usage in power-constrained scenarios by switching to traditional algorithms, and wherein the system is operable for identifying opportunities in specific contexts, behaviors, or triggers where traditional methods suffice for risk assessment, thereby conserving resources like power and processing while maintaining predictive accuracy for entity behaviors.

224. The system of claim 223, wherein the switch to traditional algorithms is triggered by detecting stable or low-risk contexts, subcontexts within broader hierarchies, or interdependent spirals, with AI/ML reactivated only for confirmation or escalation, and power-focused cookies storing state transitions for seamless handoffs.

225. The system of claim 182, wherein the system is operable with proxy substitution that integrates AI/ML reduction, using traditional algorithms on the proxy entity's data, optimized for interdependent triggers, and front-end intensive collection to build initial virtual models of interdependencies for new users.

226. The system of claim 182, wherein the system includes trigger interdependency modeling that employs hierarchical subcontexts, with power management switching to traditional stats for actual subcontexts while reserving AI/ML for perceived escalations, and leveraging wired sources or generation for intensive phases.

227. The system of claim 182, wherein the system is operable with dynamic calibration for new entities that includes:
front-end intensive data collection from all sources into a data lake;
generating virtual models with initial algorithms;
ongoing updates via daily life; and
power-aware strategies distinguishing battery from wired, with generation optimization.

228. The system of claim 182, wherein the system includes an application framework for AI/ML-traditional hybrid processing, using RL agents on MCUs to decide switches based on power types (battery vs. wired), interdependencies, and hierarchies, with front-end data lakes for new user modeling and generation integration to sustain operations.

229. The system of claim 182, wherein the system includes AI agents that follow a structured negotiation protocol with primitives including REQUEST, OFFER, COUNTEROFFER, ACCEPT, and REJECT, using reinforcement learning (RL) or game-theoretic models on microcontroller units (MCUs) to bargain over data access terms, treating power reserves as negotiable currency while prioritizing actual contexts for direct proxying and calibrating perceived contexts via entity-specific profiles to manage interdependent trigger spirals efficiently.

230. The system of claim 229, wherein negotiation implementations include edge-centric, hybrid edge-cloud, and privacy-preserving variants, with fallback to traditional algorithms or system arbitration upon REJECT to ensure continuous risk monitoring without power waste.

231. The system of claim 182, wherein proxy substitution via AI agent negotiation accounts for hierarchical subcontexts, distinguishing actual from perceived elements, with RL agents optimizing for spiral prevention by sharing minimal data sufficient for joint risk prediction.

232. The system of claim 182, wherein interdependency spiral detection triggers proactive agent negotiations, the system using three-dimensional processing to evaluate trade-offs in power, privacy, and accuracy.

233. The system of claim 182, wherein AI/ML-traditional hybrid reduction is negotiated by agents with front-end data lakes initializing hybrid strategies and generation management ensuring sustained bargaining capacity.

234. The system of claim 182, wherein the system includes an application framework for multi-agent negotiation in power management, using RL on MCUs to orchestrate access in interdependent scenarios, with enhancements for actual/perceived calibration, subcontext hierarchies, battery/wired offloading, and generation-aware deferral.

235. A non-transitory computer-readable medium storing instructions that, when executed by a processor, cause the processor to perform operations for context-based sensor power management, the operations comprising:
identifying, for each sensor, a contribution metric representing the extent to which the sensor aids in determining a temporal contextual element (“when”) and at least one other element selected from locational (“where”), social (“who”), activity (“what”), executional (“how”), or motivational (“why”);
assessing an importance metric for each involved contextual element based on its role in current and predicted future context inference;
computing a power adjustment factor as a function of the contribution metric and importance metric;
altering the power consumption of the sensor in accordance with the power adjustment factor; and
periodically recalibrating the metrics using feedback from context inference outcomes to refine future power management decisions.

236. The non-transitory computer-readable medium of claim 235, wherein the power consumption of the sensor is altered in accordance with the power adjustment factor by varying sampling frequencies or duty cycles.

237. The non-transitory computer-readable medium of claim 235, wherein the power adjustment factor is calculated using a Bayesian inference model that incorporates uncertainties in sensor data and contextual predictions to probabilistically scale power usage.

238. The non-transitory computer-readable medium of claim 235, wherein the operations further include grouping sensors by their primary contextual elements and applying batch power adjustments to groups where the temporal element is combined with low-importance complementary elements, thereby achieving aggregated energy savings.
